(19) United States
(12) Patent Application Publication
(10) Pub. No.: US 2024/0343926 A1
(43) Pub. Date: Oct. 17, 2024

(54) COLORED RESIN COMPOSITION, COLORED RESIN COMPOSITION SET, AND COLOR FILTER

(71) Applicant: Mitsubishi Chemical Corporation, Tokyo (JP)

(72) Inventors: Shigeki HATTORI, Tokyo (JP); Shuuhei NAKAJIMA, Tokyo (JP); Shiharu HIRAOKA, Tokyo (JP)

(73) Assignee: Mitsubishi Chemical Corporation, Tokyo (JP)

(21) Appl. No.: 18/670,882

(22) Filed: May 22, 2024

Related U.S. Application Data
(63) Continuation of application No. PCT/JP2022/043339, filed on Nov. 24, 2022.

(30) Foreign Application Priority Data
Nov. 25, 2021 (JP) 2021-191261

(51) Int. Cl. C09D 7/41; C09B 67/20; C09D 4/06; C09D 5/32; C09D 133/06; C09D 135/02; G02B 5/20

(52) U.S. Cl. CPC C09D 7/41; C09B 67/007; C09D 4/06; C09D 5/32; C09D 133/064; C09D 133/068; C09D 135/02; G02B 5/208

(57) ABSTRACT

Provided is a colored resin composition which can be applied as a color filter of a solid-state imaging device capable of performing high-level imaging by not only spectrally splitting light in a visible region into three colors but also spectrally splitting infrared rays. The colored resin composition includes a colorant (A), a solvent (B), and a binder resin (C), and has a maximum transmittance in a specific wavelength region in a wavelength range of 400 to 900 nm. The colorant (A) includes a colorant having specific light absorbing characteristics and a near-infrared absorbing compound.

This application is a continuation application of International Application No. PCT/JP2022/043339, filed on Nov. 24, 2022, which claims the benefit of priority of the prior Japanese Patent Application No. 2021-191261, filed in Japan on Nov. 25, 2021, the entire contents of which are incorporated herein by reference.

### BACKGROUND OF THE INVENTION

### Field of the Invention

The present invention relates to a colored resin composition, a colored resin composition set, and a color filter.

### Description of Related Art

In general, a solid-state imaging device is known for an application thereof for obtaining a digital camera image or a video image by spectrally splitting visible light into, for example, three colors of red (R), green (G), and blue (B), and capturing the image as a color image. In addition to this application, the solid-state imaging device can also be used for measurement as in a light sensor and the like. Therefore, in recent years, it has begun to be utilized for distance measurement or three-dimensional measurement.

In the distance measurement or the three-dimensional measurement, infrared rays which have a wavelength longer than that of visible light and are less likely to be scattered are considered to be useful. Since the infrared rays are not visible to humans or animals, they enable measurement at night as well as natural measurement. In an infrared sensor using such infrared rays, an infrared transmitting filter is essential.

With regard to the infrared transmitting filter, an infrared transmitting filter produced by using a composition including a coloring material is known (see, for example, Patent Document 1).

### DOCUMENTS OF RELATED ART

### Patent Document

Patent Document 1: PCT International Publication No. WO 2019/150833

### SUMMARY OF THE INVENTION

However, by incorporating a metal-free phthalocyanine compound and a red colorant into the infrared transmitting filter disclosed in Patent Document 1, light in a visible region (at a wavelength of 400 to 700 nm) is shielded whereas infrared rays are transmitted, and there was no function of spectrally splitting the infrared rays. Therefore, a solid-state imaging device using the infrared transmitting filter was not capable of performing high-level imaging by infrared rays.

The present invention has been made in view of the circumstances, and has an object to provide a colored resin composition which can be applied as a color filter of a solid-state imaging device capable of performing high-level imaging by not only spectrally splitting light in a visible region into three colors but also spectrally splitting infrared rays.

### Means for Solving Problems

As a result of intensive studies conducted by the inventors, it has been found that the problems can be solved with a colored resin composition including a specific combination of colorants, thus leading to the present invention.

That is, the present invention has the following configurations.
[1] A colored resin composition comprising:
a colorant (A);
a solvent (B); and
a binder resin (C),
wherein the colored resin composition has a maximum transmittance at a wavelength range of 400 to 500 nm in a wavelength range of 400 and 900 nm, and
the colorant (A) comprises a colorant (a1) having a light absorption maximum at a wavelength range of 580 to 650 nm in a wavelength range of 400 and 900 nm, and a near-infrared absorbing compound.
[2] The colored resin composition according to [1],
wherein when a film having a film thickness of 5 μm or less after drying is formed using the colored resin composition, an average transmittance of the film in a wavelength range of 400 to 500 nm is 30% or more.
[3] The colored resin composition according to [1] or [2],
wherein the colorant (a1) is a triarylmethane compound represented by General Formula (1).

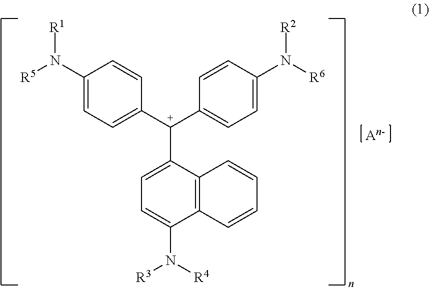

(In Formula (1), [Aⁿ⁻] represents an n-valent halogenoalkylsulfonylimide anion which may have a substituent or an n-valent halogenoalkylsulfonylmethide anion which may have a substituent,
R¹ to R⁴ each independently represent a hydrogen atom, an alkyl group which may have a substituent, or an aromatic ring group which may have a substituent,
R⁵ and R⁶ each independently represent an aromatic ring group which may have a substituent,
n represents an integer of 1 to 4, and when n is 2 to 4, a plurality of cations represented by Formula (2), which are included in one molecule, may each independently have the same structure or may have different structures, and
R¹ to R⁶ and n in Formula (2) each have the same definitions as R¹ to R⁶ and n in Formula (1).

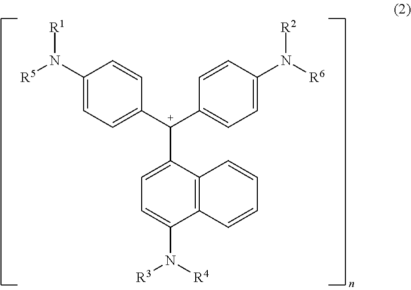

[4] A colored resin composition comprising:
a colorant (A);
a solvent (B); and
a binder resin (C),
wherein the colored resin composition has a maximum transmittance at a wavelength range of 500 to 600 nm in a wavelength range of 400 and 900 nm, and
the colorant (A) comprises a colorant (a2) having a light absorption maximum at a wavelength range of 650 to 700 nm in a wavelength range of 400 and 900 nm, and a near-infrared absorbing compound.
[5] The colored resin composition according to [4],
wherein when a film having a film thickness of 5 μm or less after drying is formed using the colored resin composition, an average transmittance of the film in a wavelength range of 500 to 600 nm is 30% or more.
[6] The colored resin composition according to [4] or [5],
wherein the colorant (a2) is a phthalocyanine compound represented by General Formula (3).

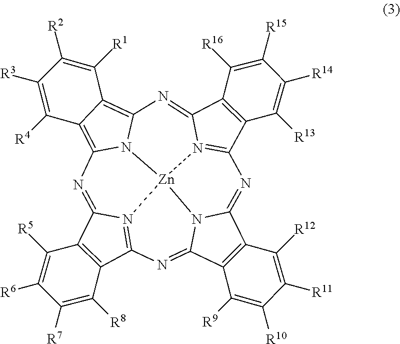

(In Formula (3), R¹ to R¹⁶ each independently represent a hydrogen atom, a halogen atom, or a group represented by General Formula (4), provided that one or more of R¹ to R¹⁶ represent a halogen atom, and one or more of R¹ to R¹⁶ represent a group represented by General Formula (4).

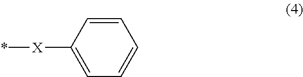

(In Formula (4), X represents a divalent linking group, a benzene ring in Formula (4) may have any substituent, and * represents a binding site.)
[7] A colored resin composition comprising:
a colorant (A);
a solvent (B); and
a binder resin (C),
wherein the colored resin composition has a maximum transmittance at a wavelength range of 600 to 700 nm in a wavelength range of 400 and 900 nm, and
the colorant (A) comprises a colorant (a3) having a light absorption maximum at a wavelength range of 430 to 570 nm in a wavelength range of 400 and 900 nm, and a near-infrared absorbing compound.
[8] The colored resin composition according to [7],
wherein when a film having a film thickness of 5 μm or less after drying is formed using the colored resin composition, an average transmittance of the film in a wavelength range of 600 to 700 nm is 30% or more.
[9] The colored resin composition according to [7] or [8],
wherein the colorant (a3) is a dihydropyrrolopyrrole dione compound represented by General Formula (5).

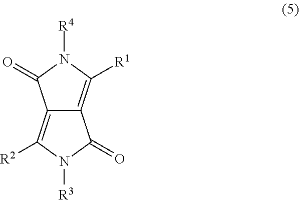

(In Formula (5), R¹ to R⁴ each independently represent a hydrogen atom, an alkyl group which may have a substituent, or an aryl group which may have a substituent.)
[10] A colored resin composition comprising:
a colorant (A);
a solvent (B); and
a binder resin (C),
wherein the colored resin composition has a maximum transmittance at a wavelength range of 700 to 800 nm in a wavelength range of 400 and 900 nm,
the colorant (A) comprises a compound represented by General Formula (8) and a near-infrared absorbing compound, and
the near-infrared absorbing compound has a light absorption maximum value in a wavelength range of 790 to 830 nm in a wavelength range of 400 and 900 nm.

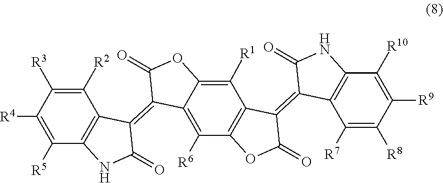

(In Formula (8), R¹ and R⁶ each independently represent a hydrogen atom, CH₃, CF₃, a fluorine atom, or a chlorine atom,
R², R³, R⁴, R⁵, R⁷, R⁸, R⁹, and R¹⁰ each independently represent a hydrogen atom, a halogen atom, R¹¹, COOH, COOR¹¹, COO⁻, CONH₂, CONHR¹¹, CONR¹¹R¹², CN, OH, OR¹¹, COCR¹¹, OOCNH₂, OOCNHR¹¹, OOCNR¹¹R¹², NO₂, NH₂, NHR¹, NR¹¹R¹², NHCOR¹², NR¹¹COR¹², N═CH₂, N═CHR¹¹, N═CR¹¹R¹², SH, SR¹¹, SOR¹¹, SO₂R¹¹, SO₃R¹¹, SO₃H, SO₃⁻, SO₂NH₂, SO₂NHR¹¹, or SO₂NR¹¹R¹², at least one combination selected from the group consisting of R² and R³, R³ and R⁴, R⁴ and R⁵, R⁷ and R⁸, R⁸ and R⁹, and R⁹ and R¹⁰ may be directly bonded to each other or may be bonded to each other through an oxygen atom, a sulfur atom, NH, or an NR¹¹ bridge, and
R¹¹ and R¹² each independently represent an alkyl group having 1 to 12 carbon atoms, a cycloalkyl group having 3 to 12 carbon atoms, an alkenyl group having 2 to 12 carbon atoms, a cycloalkenyl group having 3 to 12 carbon atoms, or an alkynyl group having 2 to 12 carbon atoms.)
[11] The colored resin composition according to [10],
wherein when a film having a film thickness of 5 μm or less after drying is formed using the colored resin composition, an average transmittance of the film in a wavelength range of 700 to 800 nm is 30% or more.
[12] A colored resin composition comprising:
a colorant (A);
a solvent (B); and
a binder resin (C),
wherein the colored resin composition has a maximum transmittance at a wavelength range of 800 to 900 nm in a wavelength range of 400 and 900 nm,
the colorant (A) comprises a compound represented by General Formula (8) and a near-infrared absorbing compound, and
the near-infrared absorbing compound has a light absorption maximum value in a wavelength range of 720 to 780 nm in a wavelength range of 400 and 900 nm.

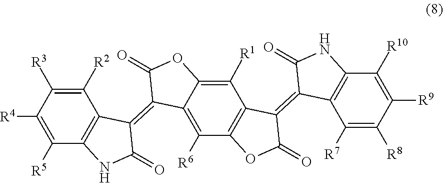

(In Formula (8), R¹ and R⁶ each independently represent a hydrogen atom, CH₃, CF₃, a fluorine atom, or a chlorine atom,
R², R³, R⁴, R⁵, R⁷, R⁸, R⁹, and R¹⁰ each independently represent a hydrogen atom, a halogen atom, R¹¹, COOH, COOR¹¹, COO⁻, CONH₂, CONHR¹¹, CONR¹¹R¹², CN, OH, OR¹¹, COCR¹¹, OOCNH₂, OOCNHR¹¹, OOCNR¹¹R¹², NO₂, NH₂, NHR¹, NR¹¹R¹², NHCOR¹², NR¹¹COR¹², N═CH₂, N═CHR¹¹, N═CR¹¹R¹², SH, SR¹¹, SOR¹¹, SO₂R¹¹, SO₃R¹¹, SO₃H, SO₃⁻, SO₂NH₂, SO₂NHR¹¹, or SO₂NR¹¹R¹²,
at least one combination selected from the group consisting of R² and R³, R³ and R⁴, R⁴ and R⁵, R⁷ and R⁸, R⁸ and R⁹, and R⁹ and R¹⁰ may be directly bonded to each other or may be bonded to each other through an oxygen atom, a sulfur atom, NH, or an NR¹¹ bridge, and
R¹¹ and R¹² each independently represent an alkyl group having 1 to 12 carbon atoms, a cycloalkyl group having 3 to 12 carbon atoms, an alkenyl group having 2 to 12 carbon atoms, a cycloalkenyl group having 3 to 12 carbon atoms, or an alkynyl group having 2 to 12 carbon atoms.)
[13] The colored resin composition according to [12],
wherein when a film having a film thickness of 5 μm or less after drying is formed using the colored resin composition, an average transmittance of the film in a wavelength range of 800 to 900 nm is 30% or more.
[14] The colored resin composition according to any one of [1], [4], [7], [10], and [12],
wherein the near-infrared absorbing compound includes at least one or more compounds selected from the group consisting of a cyanine-based compound, a merocyanine-based compound, a squarylium-based compound, a phthalocyanine-based compound, a diimmonium-based compound, and a diketopyrrolopyrrole-based compound.
[15] The colored resin composition according to any one of [1] to [14], further comprising:
a photopolymerizable monomer having a partial structure represented by General Formula (9).

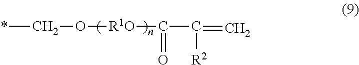

(In Formula (9), R¹ represents an alkylene group having 2 or more carbon atoms,
R² represents a hydrogen atom or a methyl group,
n represents an integer of 1 or more, and
* represents a binding site.)
[16] The colored resin composition according to any one of [1] to [14], further comprising:
a photopolymerizable monomer having a partial structure represented by General Formula (10).

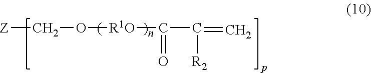

(In Formula (10), R¹ represents an alkylene group having 2 or more carbon atoms,
R² represents a hydrogen atom or a methyl group,
n represents an integer of 1 or more,
Z is a direct bond, an oxygen atom, a sulfur atom, a divalent to tetravalent aliphatic hydrocarbon group, a tetravalent carbon atom, a divalent to tetravalent non-aromatic heterocyclic group, a divalent to tetravalent aromatic ring group, or a partial structure represented by General Formula (12),
p represents an integer of 2 to 6, and a plurality of structures represented by General Formula (11), which are included in one molecule, may each independently have the same structure or may be different structures,
R¹, R², and n in Formula (11) each have the same definitions as R¹, R², and n in Formula (10), and * represents a binding site, and * in Formula (12) represents a binding site.)

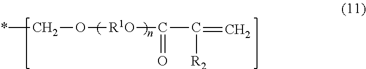

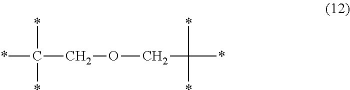 [SMILES: *C(*)(*)COCC(*)(*)*]

[17] The colored resin composition according to any one of [1] to [16],
wherein a content proportion of the colorant (A) is 10% by mass or more in a total solid content of the colored resin composition.
[18] The colored resin composition according to [15] or [16],
wherein a content proportion of the photopolymerizable monomer is 1% by mass or more in a total solid content of the colored resin composition.
[19] A colored resin composition set comprising:
the colored resin composition according to [10]; and
the colored resin composition according to [12].
[20] A colored resin composition set comprising:
at least two resin compositions selected from the group consisting of the colored resin composition according to [1], the colored resin composition according to [4], the colored resin composition according to [7], the colored resin composition according to
[10], and the colored resin composition according to [12].
[21] A color filter comprising:
a pixel formed of the colored resin composition according to any one of [1] to
[18].

### Effects of the Invention

According to the present invention, it is possible to provide a colored resin composition which can be applied as a color filter of a solid-state imaging device capable of performing high-level imaging by not only spectrally splitting light in a visible region into three colors but also spectrally splitting infrared rays.

### BRIEF DESCRIPTION OF THE DRAWINGS

FIG. 1 is a cross-sectional schematic view showing an example of an organic EL display element having a color filter of the present invention.

FIG. 2 is a graph showing the measurement results of a transmission spectrum of a colored resin composition obtained in each Example. The horizontal axis shows a wavelength and the vertical axis shows a transmittance at the wavelength.

FIG. 3 is a cross-sectional schematic view showing an example of a solid-state imaging device having the color filter of the present invention.

### DETAILED DESCRIPTION OF THE INVENTION

According to the present invention, a “weight-average molecular weight” means a polystyrene-equivalent weight-average molecular weight (Mw) obtained by gel permeation chromatography (GPC).

According to the present invention, “(meth)acryl” means “acryl and/or methacryl”.

In the present invention, a “solid content” means a component other than a solvent in the colored resin composition. Even when the component other than the solvent is liquid at room temperature, the component is not included in the solvent, but is included in the solid content.

In the present invention, the “amine value” represents an amine value in terms of an active solid content unless otherwise specified, and means a value represented by a mass of KOH equivalent to the amount of a base per gram of the solid content of a dispersant.

In the present invention, “C. I.” means a color index.

### 1 Colored Resin Composition

The colored resin composition of a first aspect according to the present invention contains a colorant (A), a solvent (B), and a binder resin (C), in which the colorant (A) contains a colorant (a1) having a light absorption maximum at a wavelength range of 580 to 650 nm in a wavelength range of 400 and 900 nm, and a near-infrared absorbing compound, and the colored resin composition has a maximum transmittance at a wavelength range of 400 to 500 nm in a wavelength range of 400 and 900 nm. It is preferable that the colorant (a1) is a triarylmethane compound represented by General Formula (1) which will be described later. In addition, it is preferable that the near-infrared absorbing compound contains at least one or more compounds selected from the group consisting of a cyanine-based compound, a merocyanine-based compound, a squarylium-based compound, a phthalocyanine-based compound, a diimmonium-based compound, and a diketopyrrolopyrrole-based compound. The colored resin composition of the present aspect may be blended with other additives and the like other than the components, as necessary.

The colored resin composition of a second aspect according to the present invention contains a colorant (A), a solvent (B), and a binder resin (C), in which the colorant (A) contains a colorant (a2) having a light absorption maximum at a wavelength range of 650 to 700 nm in a wavelength range of 400 and 900 nm, and a near-infrared absorbing compound, and the colored resin composition has a maximum transmittance at a wavelength range of 500 to 600 nm in a wavelength range of 400 and 900 nm. It is preferable that the colorant (a2) is a phthalocyanine compound represented by General Formula (3) which will be described later. In addition, it is preferable that the near-infrared absorbing compound contains at least one or more compounds selected from the group consisting of a cyanine-based compound, a merocyanine-based compound, a squarylium-based compound, a phthalocyanine-based compound, a diimmonium-based compound, and a diketopyrrolopyrrole-based compound. The colored resin composition of the present aspect may be blended with other additives and the like other than the components, as necessary.

The colored resin composition of a third aspect according to the present invention contains a colorant (A), a solvent (B), and a binder resin (C), in which the colorant (A) contains a colorant (a3) having a light absorption maximum at a wavelength range of 430 to 570 nm in a wavelength range of 400 and 900 nm, and a near-infrared absorbing compound, and the colored resin composition has a maximum transmittance at a wavelength range of 600 to 700 nm in a wavelength range of 400 and 900 nm. It is preferable that the colorant (a3) is a dihydropyrrolopyrrole dione compound represented by General Formula (5) which will be described later. In addition, it is preferable that the near-infrared absorbing compound contains at least one or more compounds selected from the group consisting of a cyanine-based compound, a merocyanine-based compound, a squarylium-based compound, a phthalocyanine-based compound, a diimmonium-based compound, and a diketopyrrolopyrrole-based compound. The colored resin composition of the present aspect may be blended with other additives and the like other than the components, as necessary.

The colored resin composition of a fourth aspect according to the present invention contains a colorant (A), a solvent (B), and a binder resin (C), in which the colorant (A) contains a compound represented by General Formula (8) which will be described later, a near-infrared absorbing compound, the near-infrared absorbing compound according to the present aspect has a light absorption maximum value in a wavelength range of 790 to 830 nm in a wavelength range of 400 and 900 nm, and the colored resin composition has a maximum transmittance at a wavelength range of 700 to 800 nm in a wavelength range of 400 and 900 nm. It is preferable that the near-infrared absorbing compound contains at least one or more compounds selected from the group consisting of a cyanine-based compound, a merocyanine-based compound, a squarylium-based compound, a phthalocyanine-based compound, a diimmonium-based compound, and a diketopyrrolopyrrole-based compound. The colored resin composition of the present aspect may be blended with other additives and the like other than the components, as necessary.

The colored resin composition of a fifth aspect according to the present invention contains a colorant (A), a solvent (B), and a binder resin (C), in which the colorant (A) contains a compound represented by General Formula (8) which will be described later, and a near-infrared absorbing compound, the near-infrared absorbing compound according to the present aspect has a light absorption maximum value in a wavelength range of 720 to 780 nm in a wavelength range of 400 and 900 nm, and the colored resin composition has a maximum transmittance at a wavelength range of 800 to 900 nm in a wavelength range of 400 and 900 nm. It is preferable that the near-infrared absorbing compound contains at least one or more compounds selected from the group consisting of a cyanine-based compound, a merocyanine-based compound, a squarylium-based compound, a phthalocyanine-based compound, a diimmonium-based compound, and a diketopyrrolopyrrole-based compound. The colored resin composition of the present aspect may be blended with other additives and the like other than the components, as necessary.

### 1-1 Colorant (A)

The colored resin composition of the present invention includes a colorant (A). The colorant is a component that colors the colored resin composition. A desired light absorbing property can be obtained by allowing the composition to include the colorant (A).

The colorant (A) in the colored resin composition of the present invention may include a dye. In a case of including the dye, the transmittance is improved and a colored resin composition having a high luminance is obtained.

In the present invention, the dye means a dye compound that is soluble in a specific organic solvent. Here, examples of the specific organic solvent include the organic solvents that are exemplary examples mentioned in the column of the solvent which will be described later, and propylene glycol monomethyl ether acetate, propylene glycol monomethyl ether, and 3-methoxy-1-butanol are preferable. 1-1-1 Colorant (a1) Included in Colorant (A) in Colored Resin Composition of First Aspect

The colorant (A) in the colored resin composition of the first aspect contains a colorant (a1) having a light absorption maximum at a wavelength range of 580 to 650 nm in a wavelength range of 400 and 900 nm. By allowing the composition to contain the colorant (a1), there is a tendency that a color filter having excellent transparency of blue light is obtained.

The colorant (a1) is not particularly limited as long as it is a colorant having a light absorption maximum at a wavelength range of 580 to 650 nm in a wavelength range of 400 and 900 nm. The colorant (a1) is preferably a triarylmethane compound represented by General Formula (1) (hereinafter also referred to as a “triarylmethane compound (1)”), and the colorant (A) in the colored resin composition of the first aspect preferably contains at least one or more triarylmethane compounds (1) having a light absorption maximum at a wavelength range of 580 to 650 nm in a wavelength range of 400 and 900 nm. By allowing the composition to contain the triarylmethane compound (1), blue light in a visible region can be selectively transmitted, and by further combining a near-infrared absorbing compound therewith, there is a tendency that a color filter which selectively transmits only blue light in a visible region through a near-infrared region is obtained. In addition, by allowing the composition to contain the triarylmethane compound (1), there is a tendency that a color filter having excellent heat resistance and light resistance and having excellent transparency of blue light is obtained.

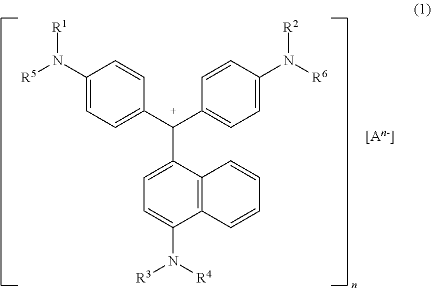

In Formula (1), [Aⁿ⁻] represents an n-valent halogenoalkylsulfonylimide anion which may have a substituent or an n-valent halogenoalkylsulfonylmethide anion which may have a substituent;
R¹ to R⁴ each independently represent a hydrogen atom, an alkyl group which may have a substituent, or an aromatic ring group which may have a substituent,
R⁵ and R⁶ each independently represent an aromatic ring group which may have a substituent,
n represents an integer of 1 to 4, and when n is 2 to 4, a plurality of cations represented by Formula (2), which are included in one molecule, may each independently have the same structure or may have different structures, and
R¹ to R⁶ and n in Formula (2) each have the same definitions as R¹ to R⁶ and n in Formula (1).

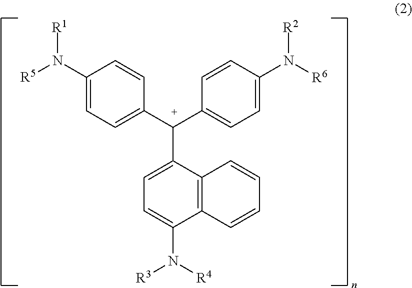

R¹ to R⁴

R¹ to R⁴ in Formula (1) each independently represent a hydrogen atom, an alkyl group which may have a substituent, or an aromatic ring group which may have a substituent.

Examples of the alkyl group for R¹ to R⁴ include a linear, branched, or cyclic alkyl group. The number of carbon atoms thereof is preferably 30 or less, and more preferably 12 or less, and preferably 1 or more. By setting the number of carbon atoms to the upper limit value or less, the solubility of the triarylmethane-based compound in the colored resin composition can be appropriately adjusted, and at the same time, the effective interaction between a cation and an anion occurs. Therefore, there is a tendency that the heat resistance and the light resistance are improved.

The above-described upper limits and lower limits can be combined in any manner. For example, the number of carbon atoms is preferably 1 to 30, and more preferably 1 to 12.

Examples of the alkyl group include a methyl group, an ethyl group, an n-propyl group, a 2-propyl group, an n-butyl group, an isobutyl group, a tert-butyl group, a cyclohexyl group, a cyclohexylmethyl group, a cyclohexylethyl group, and 3-methylbutyl group. Among these, the linear alkyl group is preferable from the viewpoint of the aggregation of molecules represented by Formula (1) and the electrostatic interaction with anions.

Examples of the alkyl group having a substituent include a phenethyl group, a 2-ethoxyethyl group, and a 4,4,4-trifluorobutyl group.

Examples of the aromatic ring group for R¹ to R⁴ include an aromatic hydrocarbon ring group and an aromatic heterocyclic group. The number of carbon atoms thereof is preferably 30 or less, and more preferably 12 or less, and preferably 4 or more, and more preferably 6 or more. By setting the number of carbon atoms to the upper limit value or less, a tendency of a high luminance is observed since the conjugate length is appropriate and the absorption waveform in the vicinity of 500 nm is sharp. At the same time, since the interaction between the triarylmethane-based compound and another compound constituting the composition is appropriate in the colored resin composition, there is a tendency that the solubility can be appropriately adjusted.

The above-described upper limits and lower limits can be combined in any manner. For example, the number of carbon atoms is preferably 4 to 30, more preferably 4 to 12, and still more preferably 6 to 12.

The aromatic hydrocarbon ring group may be a monocyclic ring or a fused ring, and examples thereof include a benzene ring, a naphthalene ring, an anthracene ring, a phenanthrene ring, a perylene ring, a tetracene ring, a pyrene ring, a benzopyrene ring, a chrysene ring, a triphenylene ring, an acenaphthene ring, a fluoranthene ring, and a fluorene ring, each of which has one free valence.

The aromatic heterocyclic group may be a monocyclic ring or a fused ring, and examples thereof include a furan ring, a benzofuran ring, a thiophene ring, a benzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzisoxazole ring, a benzisothiazole ring, a benzimidazole ring, a pyridine ring, a pyrazine ring, a pyridazine ring, a pyrimidine ring, a triazine ring, a quinoline ring, an isoquinoline ring, a shinorine ring, a quinoxaline ring, a phenanthridine ring, a perimidine ring, a quinazoline ring, a quinazolinone ring, and an azulene ring, each of which has one free valence.

From the viewpoint of the heat resistance, it is preferable that R¹ to R⁴ are each independently a hydrogen atom, an alkyl group having 1 to 12 carbon atoms, which may have a substituent, or a phenyl group which may have a substituent, or adjacent R³ and R⁴ are linked to each other to form a ring, and it is more preferable that R¹ to R⁴ are each independently the hydrogen atom or an alkyl group which may have a substituent. These substituents are also preferable from the viewpoint of a luminance.

From the viewpoint that the heat resistance of the triarylmethane compound (1) is improved and the heat resistance of the obtained color filter is excellent, it is preferable that R¹ and R² are each an alkyl group having 1 to 12 carbon atoms, which may have a substituent or a phenyl group which may have a substituent. From the viewpoint of the luminance, it is more preferable that R¹ and R² are each the alkyl group having 1 to 12 carbon atoms, which may have a substituent.

When R¹ and R² are each the alkyl group having 1 to 12 carbon atoms, which may have a substituent, it is presumed that the charges in cations are dispersed and the cations are stabilized by hyperconjugation.

More specifically, from the viewpoints that the number of carbon atoms of the alkyl group for R¹ and R² is less likely to affect the conformation of the triarylmethane skeleton (giving a less influence on the luminance) and that a substituent on nitrogen is less likely to be leaving (stabilizing the triarylmethane compound (1)), the number of carbon atoms is preferably 8 or less, and more preferably 4 or less, and preferably 2 or more. The number of carbon atoms is, for example, preferably 2 to 8, and more preferably 2 to 4.

When R¹ and R² are each the phenyl group which may have a substituent, it is considered that since the conjugated system extends, the charges in cations are dispersed, thereby stabilizing the cation. In this way, it can be considered that as a result of stabilizing the cation, the heat resistance of the obtained color filter is more excellent.

From the viewpoint that the luminance of the triarylmethane compound (1) is excellent, it is preferable that at least one of R³ and R⁴ is an alkyl group which may have a substituent. From the viewpoint of the heat resistance, it is preferable that either one of R³ and R⁴ is the alkyl group which may have a substituent and the other is a hydrogen atom.

On the other hand, it is preferable that at least one of R³ and R⁴ is an alkyl group having a secondary carbon, which may have a substituent. It is considered that by using the alkyl group having a secondary carbon, which may have a substituent, as at least one of R³ and R⁴, the substituent inhibits attacks from other molecules that cause the molecule represented by Formula (1) to decompose due to heat or light, contributing to improved heat resistance and light resistance.

It is more preferable that either one of R³ and R⁴ is the alkyl group having a secondary carbon, which may have a substituent, and the other is a group other than the alkyl group, and it is still more preferable that either one is the alkyl group having a secondary carbon, which may have a substituent, and the other is a hydrogen atom.

Furthermore, the expression, “at least one of R³ and R⁴ is an alkyl group having a secondary carbon, which may have a substituent”, means that at least one of R³ or R⁴ is an alkyl group having a group represented by General Formula (A-3), which may have a substituent. Furthermore, * in the formula means a binding site.

α and β in General Formula (A-3) each independently represent an alkyl group which may have a substituent, or an aromatic ring group which may have a substituent. The C-α bond represents a bond between a carbon atom and a carbon atom having a substituent α, and the C-β bond also represents a bond between a carbon atom and a carbon atom having a substituent β in the similar manner. Furthermore, α and β may be linked to each other to form a ring, and the ring formed by further linking α and β to each other may have a substituent.

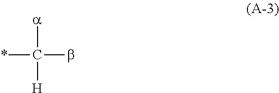

The alkyl group having a secondary carbon, which may have a substituent, is not limited to any particular alkyl groups as long as it is an alkyl group having a group represented by Formula (A-3), which may have a substituent, but may be, for example, the group represented by Formula (A-3) itself, or may be the alkyl group having the group represented by Formula (A-3), bonded to an alkylene group which may have a substituent. It should be noted that from the viewpoint that the vicinity of a nitrogen atom can be bulked, the group represented by Formula (A-3) itself is preferable. That is, since the substituent inhibits attacks from other molecules that cause the decomposition by light, which tends to contributes to the improvement of various physical properties.

Examples of the alkyl group for α and β include a linear, branched, or cyclic alkyl group. The number of carbon atoms thereof is preferably 30 or less, more preferably 12 or less, still more preferably 8 or less, and particularly preferably 6 or less, and preferably 1 or more. The number of carbon atoms is, for example, preferably 1 to 30, more preferably 1 to 12, still more preferably 1 to 8, and particularly preferably 1 to 6. By setting the number of carbon atoms to the upper limit value or less, the solubility of the triarylmethane compound (1) in a solvent in the colored resin composition can be appropriately adjusted, and at the same time, the aggregation of molecules represented by Formula (1) or the effective interaction between a cation and an anion occurs. Therefore, there is a tendency that the heat resistance and the light resistance are improved.

Examples of the alkyl group include a methyl group, an ethyl group, an n-propyl group, a 2-propyl group, an n-butyl group, an isobutyl group, a tert-butyl group, a cyclohexyl group, a cyclohexylmethyl group, a cyclohexylethyl group, and 3-methylbutyl group. Among these, the linear alkyl group is preferable from the viewpoint of the aggregation of molecules represented by Formula (1) and the electrostatic interaction with anions.

Examples of the alkyl group having a substituent include a phenethyl group and a 2-ethoxyethyl group.

Examples of the aromatic ring group for α and β include an aromatic hydrocarbon ring group and an aromatic heterocyclic group. The number of carbon atoms thereof is preferably 30 or less, more preferably 12 or less, and still more preferably 6 or less, and preferably 4 or more. The number of carbon atoms is, for example, preferably 4 to 30, more preferably 4 to 12, and still more preferably 4 to 6. By setting the number of carbon atoms to the upper limit value or less, the solubility of the triarylmethane compound (1) in a solvent can be appropriately adjusted, and at the same time, the aggregation of molecules represented by Formula (1) or the effective interaction between a cation and an anion occurs. Therefore, there is a tendency that the heat resistance and the light resistance are improved.

The aromatic hydrocarbon ring group may be a monocyclic ring or a fused ring, and examples thereof include a benzene ring, a naphthalene ring, an anthracene ring, a phenanthrene ring, a perylene ring, a tetracene ring, a pyrene ring, a benzopyrene ring, a chrysene ring, a triphenylene ring, an acenaphthene ring, a fluoranthene ring, and a fluorene ring, each of which has one free valence.

The aromatic heterocyclic group may be a monocyclic ring or a fused ring, and examples thereof include a furan ring, a benzofuran ring, a thiophene ring, a benzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzisoxazole ring, a benzisothiazole ring, a benzimidazole ring, a pyridine ring, a pyrazine ring, a pyridazine ring, a pyrimidine ring, a triazine ring, a quinoline ring, an isoquinoline ring, a shinorine ring, a quinoxaline ring, a phenanthridine ring, a perimidine ring, a quinazoline ring, a quinazolinone ring, and an azulene ring, each of which has one free valence.

α and β may be linked to each other to form a ring, and the ring formed by further linking α and β to each other may have a substituent.

The ring formed by linking α and β to each other may be a ring crosslinked with a heteroatom. The number of carbon atoms of the ring formed by linking α and β to each other (provided that a C atom bonded to α and β, α, and β are included) is preferably 30 or less, more preferably 12 or less, and still more preferably 8 or less, and is usually 3 or more. The number of carbon atoms is, for example, preferably 3 to 30, more preferably 3 to 12, and still more preferably 3 to 8.

By setting the number of carbon atoms to the upper limit value or less, the solubility of the triarylmethane compound (1) in a solvent can be appropriately adjusted, and at the same time, the aggregation of molecules represented by Formula (1) or the effective interaction between a cation and an anion occurs. Therefore, there is a tendency that the heat resistance and the light resistance are improved.

When α and β are linked to each other to form a ring, examples of the alkyl group having a secondary carbon include the following structure.

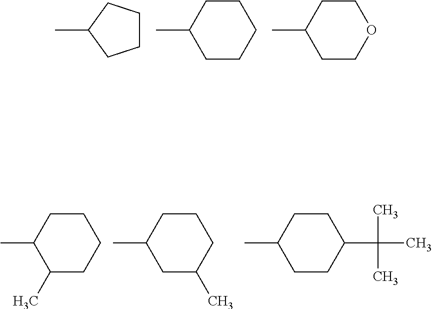

Examples of the substituent that the alkyl group in α and β may have include the substituents of the substituent group W1 which will be described later.

Examples of the substituent that the aromatic ring group may have include the substituents in a substituent group W2 which will be described later.

Examples of the substituent that the ring formed by being linked to each other may have include the substituents in a substituent group W3 which will be described later.

As α and β, including α and β in the number of carbon atoms, it is preferable that α and β are each independently a linear alkyl group having 1 to 12 carbon atoms, which may have a substituent, or are linked to each other to form a ring. It is more preferable that α and β are each independently an alkyl group having 2 to 6 carbon atoms, which may have a substituent, or adjacent α and β having 3 to 10 carbon atoms are linked to each other to form a ring. When α and β are these substituents, the aggregation between the compounds represented by Formula (1) and the effective interaction between a cation and an anion occurs. Therefore, there is a tendency that the heat resistance and the light resistance are improved.

A sum of the numbers of carbon atoms in the alkyl groups having a secondary carbon as R³ and R⁴ is preferably 30 or less, more preferably 12 or less, still more preferably 8 or less, and most preferably 6 or less. In addition, the sum of the numbers of carbon atoms is preferably 3 or more, more preferably 4 or more, and still more preferably 5 or more. By setting the sum of the numbers of carbon atoms to be within the ranges, there is a tendency that the interaction between molecules represented by Formula (1) and the electrostatic interaction of cations with anions in the compound represented by Formula (1) in the molecule in the colored resin composition are appropriate, and the durability can be improved.

The above-described upper limits and lower limits can be combined in any manner. For example, the sum of the numbers of carbon atoms is preferably 3 to 30, more preferably 3 to 12, still more preferably 4 to 8, and particularly preferably 5 or 6.

Examples of the alkyl group having a secondary carbon include an isopropyl group, an s-butyl group, a 1-methylpropyl group, a 1-ethylpropyl group, a 1-methylbutyl group, a cyclopentyl group, a 1-methylpentyl group, a 1-ethylbutyl group, a 1-propylbutyl group, a 1-ethylpentyl group, a 1-propylpentyl group, a 1-butylpentyl group, a 1-methylhexyl group, a 1-ethylhexyl group, a 1-propylhexyl group, a 1-butylhexyl group, a cyclohexyl group, a 2-methylcyclohexyl group, a 2-ethylcyclohexyl group, a 2-propylcyclohexyl group, a 2-isopropylcyclohexyl group, a 2-cyclopropylcyclohexyl group, a 2-butylcyclohexyl group, a 2-s-butylcyclohexyl group, a 2-t-butylcyclohexyl group, a 2-isobutylcyclohexyl group, a 2-cyclobutylcyclohexyl group, a 2-pentylcyclohexyl group, a 2-cyclopentylcyclohexyl group, a 2-cyclohexylcyclohexyl group, a 3-methylcyclohexyl group, a 4-methylcyclohexyl group, a 2,6-dimethylcyclohexyl group, a 2,4-dimethylcyclohexyl group, a 3,5-dimethylcyclohexyl group, a 2,5-dimethylcyclohexyl group, a 2,3-dimethylcyclohexyl group, a 3,3,5-trimethylcyclohexyl group, a 4-t-butylcyclohexyl group, a 1-ethylheptyl group, a 1-methylheptyl group, a 1-propylheptyl group, a 1-butylheptyl group, a 1-pentylheptyl group, a 1-hexylheptyl group, a cycloheptyl group, a 2-methylcycloheptyl group, a 3-methylcycloheptyl group, a 4-methylcycloheptyl group, a 2,7-dimethylcycloheptyl group, a 1-cyclohexylethyl group, a 1-methyloctyl group, a 1-ethyloctyl group, a 1-propyloctyl group, a 1-butyloctyl group, a 1-pentyloctyl group, a 1-hexyloctyl group, a 1-heptyloctyl group, a cyclooctyl group, a 1-methylcyclooctyl group, a 2-methylcyclooctyl group, a 3-methylcyclooctyl group, a 4-methylcyclooctyl group, and a 2-adamantyl group.

From the viewpoint of improving durability by the aggregation of molecules represented by Formula (1) and the electrostatic interaction with anions, an isopropyl group, an s-butyl group, a 1-methylpropyl group, a 1-ethylpropyl group, a 1-methylbutyl group, a 1-ethylbutyl group, a 1-propylbutyl group, a cyclohexyl group, a 2-methylcyclohexyl group, a 3-methylcyclohexyl group, a 4-methylcyclohexyl group, a 4-t-butylcyclohexyl group, a cyclopentyl group, or a cyclooctyl group is preferable.

On the other hand, when either one of R³ and R⁴ is used as an alkyl group having a secondary carbon, which may have a substituent, and the other is used as a group other than the alkyl group, examples of the group other than the alkyl group (the group other than the “alkyl group having a secondary carbon, which may have a substituent”) include a hydrogen atom; an alkyl group having 1 to 5 carbon atoms, such as a methyl group, an ethyl group, a propyl group, a butyl group, a t-butyl group, and a pentyl group; a hydroxyalkyl group having 1 to 5 carbon atoms, such as a hydroxyethyl group and a hydroxypropyl group; an alkoxyalkyl group having 1 to 5 carbon atoms, such as a methoxyethyl group, an ethoxyethyl group, an ethoxypropyl group, and a butoxyethyl group; a hydroxyalkoxy group having 1 to 5 carbon atoms, such as a 2-hydroxyethoxy group; an alkoxy (having 1 to 5 carbon atoms) alkoxy group having 1 to 5 carbon atoms, such as a 2-methoxyethoxy group and a 2-ethoxyethoxy group; a 2-sulfoethyl group; a carboxyethyl group; and a cyanoethyl group.

Examples of the substituent that the alkyl group for R¹ to R⁴ may have include the substituents in the following substituent group W1.

Examples of the substituent that the aromatic ring group may have include the substituents in the following substituent group W2.

Examples of the substituent that the ring formed by being linked to each other may have include the substituents in the following substituent group W3.

### Substituent Group W1

A fluorine atom, a chlorine atom, an alkenyl group having 2 to 8 carbon atoms, an alkoxyl group having 1 to 8 carbon atoms, a phenyl group, a mesityl group, a tolyl group, a naphthyl group, a cyano group, an acetyloxy group, an alkylcarbonyloxy group having 2 to 9 carbon atoms, a sulfamoyl group, an alkylsulfamoyl group having 2 to 9 carbon atoms, an alkylcarbonyl group having 2 to 9 carbon atoms, a phenethyl group, a hydroxyethyl group, an acetylamide group, a dialkylaminoethyl group formed by bonding of an alkyl group having 1 to 4 carbon atoms, a trifluoromethyl group, a trialkylsilyl group having 1 to 8 carbon atoms, a nitro group, and an alkylthio group having 1 to 8 carbon atoms.

Preferably, an alkoxyl group having 1 to 8 carbon atoms, a cyano group, an acetyloxy group, an alkylcarboxyl group having 2 to 8 carbon atoms, a sulfamoyl group, an alkylsulfamoyl group having 2 to 9 carbon atoms, and a fluorine atom.

### Substituent Group W2

A fluorine atom, a chlorine atom, an alkyl group having 1 to 8 carbon atoms, an alkenyl group having 2 to 8 carbon atoms, an alkoxyl group having 1 to 8 carbon atoms, a phenyl group, a mesityl group, a tolyl group, a naphthyl group, a cyano group, an acetyloxy group, an alkylcarbonyloxy group having 2 to 9 carbon atoms, a sulfamoyl group, an alkylsulfamoyl group having 2 to 9 carbon atoms, an alkylcarbonyl group having 2 to 9 carbon atoms, a hydroxyethyl group, an acetylamide group, a dialkylaminoethyl group formed by bonding of an alkyl group having 1 to 4 carbon atoms, a trifluoromethyl group, a trialkylsilyl group having 1 to 8 carbon atoms, a nitro group, and an alkylthio group having 1 to 8 carbon atoms.

Preferably, an alkyl group having 1 to 12 carbon atoms, an alkoxyl group having 1 to 8 carbon atoms, a cyano group, an acetyloxy group, an alkylcarboxyl group having 2 to 8 carbon atoms, a sulfamoyl group, an alkylsulfamoyl group having 2 to 9 carbon atoms, and a fluorine atom.

### Substituent Group W3

A fluorine atom, a chlorine atom, an alkyl group having 1 to 8 carbon atoms, an alkenyl group having 2 to 8 carbon atoms, an alkoxyl group having 1 to 8 carbon atoms, a phenyl group, a mesityl group, a tolyl group, a naphthyl group, a cyano group, an acetyloxy group, an alkylcarbonyloxy group having 2 to 9 carbon atoms, a sulfamoyl group, an alkylsulfamoyl group having 2 to 9 carbon atoms, an alkylcarbonyl group having 2 to 9 carbon atoms, a phenethyl group, a hydroxyethyl group, an acetylamide group, a dialkylaminoethyl group formed by bonding of an alkyl group having 1 to 4 carbon atoms, a trifluoromethyl group, a trialkylsilyl group having 1 to 8 carbon atoms, a nitro group, and an alkylthio group having 1 to 8 carbon atoms.

Preferably, an alkyl group having 1 to 12 carbon atoms, an alkoxyl group having 1 to 8 carbon atoms, a cyano group, an acetyloxy group, an alkylcarboxyl group having 2 to 8 carbon atoms, a sulfamoyl group, an alkylsulfamoyl group having 2 to 9 carbon atoms, and a fluorine atom.

R⁵ and R⁶

R⁵ and R⁶ are each independently an aromatic ring group which may have a substituent. In the triarylmethane compound represented by Formula (1) used for the colored resin composition, it is considered that since R⁵ and R⁶ are each independently an aromatic ring group which may have a substituent, the conjugated system of the cation is widened, the charges are stabilized, and the heat resistance and the light resistance are improved.

Examples of the aromatic ring group for R⁵ and R⁶ include an aromatic hydrocarbon ring group and an aromatic heterocyclic group. The number of carbon atoms thereof is preferably 30 or less, and more preferably 12 or less, and preferably 4 or more, and more preferably 6 or more. By setting the number of carbon atoms to the upper limit value or less, the solubility of the triarylmethane compound (1) in a solvent in the colored resin composition can be appropriately adjusted, and at the same time, the aggregation of molecules represented by Formula (1) or the effective interaction between a cation and an anion occurs. Therefore, there is a tendency that the heat resistance and the light resistance are improved.

The above-described upper limits and lower limits can be combined in any manner. For example, the number of carbon atoms is preferably 4 to 30, more preferably 4 to 12, and still more preferably 6 to 12.

The aromatic hydrocarbon ring group may be a monocyclic ring or a fused ring, and examples thereof include a benzene ring, a naphthalene ring, an anthracene ring, a phenanthrene ring, a perylene ring, a tetracene ring, a pyrene ring, a benzopyrene ring, a chrysene ring, a triphenylene ring, an acenaphthene ring, a fluoranthene ring, and a fluorene ring, each of which has one free valence.

The aromatic heterocyclic group may be a monocyclic ring or a fused ring, and examples thereof include a furan ring, a benzofuran ring, a thiophene ring, a benzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzisoxazole ring, a benzisothiazole ring, a benzimidazole ring, a pyridine ring, a pyrazine ring, a pyridazine ring, a pyrimidine ring, a triazine ring, a quinoline ring, an isoquinoline ring, a shinorine ring, a quinoxaline ring, a phenanthridine ring, a perimidine ring, a quinazoline ring, a quinazolinone ring, and an azulene ring, each of which has one free valence.

R⁵ and R⁶ may be each linked to R¹ and R² to form a ring, and the ring formed by each linking R⁵ or R⁶ to R¹ or R² may further have a substituent. In addition, the ring formed by each linking R⁵ or R⁶ to R¹ or R² may be a ring crosslinked with a heteroatom. The number of carbon atoms thereof is preferably 28 or less, more preferably 10 or less, and still more preferably 6 or less. Examples of the substituent that the rings formed by each linking R⁵ or R⁶ to R¹ or R² may have include the substituents in the substituent group W3 described above. With these substituents, the aggregation between the compounds represented by Formula (1) or the effective interaction of cations with anions between molecules occurs. Therefore, there is a tendency that the heat resistance and the light resistance are improved.

Among those, from the viewpoint of the sharpness of an absorption waveform in the vicinity of 500 nm, that is, a high luminance, an aromatic hydrocarbon ring having one free valence is preferable, an aromatic monocyclic or bicyclic hydrocarbon ring having one free valence is more preferable, and a benzene ring having one free valence is still more preferable.

Examples of the substituent that the aromatic ring group for R⁵ and R⁶ may have include the substituents in the substituent group W2 described above. In particular, from the viewpoint of the sharpness of an absorption waveform in the vicinity of 500 nm, that is, a high luminance, and the viewpoint of improving the heat resistance and the light resistance by stabilizing the cation by dispersing the charges in cations by hyperconjugation, it is preferable that the aromatic ring group for R⁵ or R⁶ is unsubstituted, has an alkyl group as a substituent, or has an alkoxy group as a substituent, and it is more preferable that the aromatic ring group is unsubstituted or has an alkyl group as a substituent. The number of carbon atoms of each of the alkyl group and the alkoxy group which the aromatic ring group may have is not particularly limited, but from the viewpoint of the heat resistance, the number of carbon atoms is preferably 8 or less, more preferably 4 or less, and still more preferably 2 or less, and preferably 1 or more. The number of carbon atoms is, for example, preferably 1 to 8, more preferably 1 to 4, and still more preferably 1 or 2.

Combination of R¹ to R⁶

R¹ to R⁶ may be appropriately selected from those described above. Examples of the combination of R¹ to R⁶ include those shown in Table 1. The alkyl group, the aromatic hydrocarbon ring group, and the aromatic heterocyclic group, which are mentioned in Table 1, may further include any substituent. C in the table means the number of carbon atoms.

As a combination of R¹ to R⁶, from the viewpoint of the heat resistance, since the compounds represented by Formula (1) are likely to aggregate with each other, attacks from other molecules that cause the compound represented by Formula (1) to thermally decompose can be inhibited, and the electrostatic interaction between a cation and an anion due to the steric hindrance of the substituent is not decreased, it is preferable that R³ is a hydrogen atom and R⁴ is an alkyl group having 1 to 12 carbon atoms, which may have a substituent. Since the attacks from other molecules toward a carbon atom to which two benzene rings and a naphthalene ring of a triarylmethane skeleton are bonded can be inhibited, it is preferable that R¹ and R² are each independently an alkyl group having 1 to 12 carbon atoms, which may have a substituent, an aromatic hydrocarbon ring group having 4 to 12 carbon atoms, which may have a substituent, or an aromatic heterocyclic group having 4 to 12 carbon atoms, which may have a substituent.

On the other hand, from the viewpoint that in terms of the sharpness of the absorption waveform in the vicinity of 500 nm, that is, a high luminance, the widening of a π-conjugated system is prevented and the shape of the absorption spectrum is sharpened, it is preferable that R¹ and R² are each independently an alkyl group having 1 to 12 carbon atoms, which may have a substituent, R³ is a hydrogen atom, and R⁴ is an alkyl group having 1 to 12 carbon atoms, which may have a substituent. Further, from the viewpoint that there is no bias of charges in a π-conjugated system and the shape of an absorption spectrum is sharpened, it is more preferable that R⁵ and R⁶ are each independently an aromatic hydrocarbon ring having 4 to 12 carbon atoms, which may have a substituent.

Since the triarylmethane-based compound represented by Formula (1) has a symmetrical molecular structure in which a nitrogen atom is bonded to the para-position of two benzene rings forming a triarylmethane skeleton, and a hydrogen atom is bonded to the ortho-position and the meta-position, it is considered that the triarylmethane-based compound has a favorable spectral shape and a higher luminance, as compared with other structures having a substituent at the ortho-position or the meta-position. In addition, it is considered that the molecular distortion due to the steric hindrance is decreased and the heat resistance is favorable, as compared with a case where a substituent is present at the ortho-position or the meta-position. From the viewpoint of contrasting the molecular structures, it is preferable that R¹ and R² and/or R⁵ and R⁶ are the same groups.

TABLE 1

| | R¹ | R⁵ | R² | R⁶ | R³ | R⁴ |
|---|---|---|---|---|---|---|
| 1 | C1-C12 | C4-C12 aromatic | C1-C12 | C4-C12 aromatic | Hydrogen | C1-C12 |
| | alkyl | hydrocarbon | alkyl | hydrocarbon | atom | alkyl |
| | group | ring group | group | ring group | | group |
| 2 | C1-C12 | C4-C12 aromatic | C1-C12 | C4-C12 aromatic | Hydrogen | C1-C12 |
| | alkyl | hydrocarbon | alkyl | hydrocarbon | atom | alkyl |
| | group | ring group | group | ring group | | group |
| 3 | C1-C12 | C4-C12 aromatic | C1-C12 | C4-C12 aromatic | Hydrogen | C4-C12 aromatic |
| | alkyl | hydrocarbon | alkyl | hydrocarbon | atom | hydrocarbon |
| | group | ring group | group | ring group | | ring group |
| 4 | C1-C12 | C4-C12 aromatic | C1-C12 | C4-C12 aromatic | Hydrogen | C4-C12 aromatic |
| | alkyl | hydrocarbon | alkyl | hydrocarbon | atom | hydrocarbon |
| | group | ring group | group | ring group | | ring group |
| 5 | C1-C12 | C4-C12 aromatic | C1-C12 | C4-C12 aromatic | C1-C12 | C1-C12 |
| | alkyl | hydrocarbon | alkyl | hydrocarbon | alkyl | alkyl |
| | group | ring group | group | ring group | group | group |
| 6 | C1-C12 | C4-C12 aromatic | C1-C12 | C4-C12 aromatic | C1-C12 | C1-C12 |
| | alkyl | hydrocarbon | alkyl | hydrocarbon | alkyl | alkyl |
| | group | ring group | group | ring group | group | group |
| 7 | C1-C12 | C4-C12 aromatic | C1-C12 | C4-C12 aromatic | C1-C12 | C4-C12 aromatic |
| | alkyl | hydrocarbon | alkyl | hydrocarbon | alkyl | hydrocarbon |
| | group | ring group | group | ring group | group | ring group |
| 8 | C1-C12 | C4-C12 aromatic | C1-C12 | C4-C12 aromatic | C1-C12 | C4-C12 aromatic |
| | alkyl | hydrocarbon | alkyl | hydrocarbon | alkyl | hydrocarbon |
| | group | ring group | group | ring group | group | ring group |
| 9 | C4-C12 aromatic | C4-C12 aromatic | C4-C12 aromatic | C4-C12 aromatic | Hydrogen | C1-C12 |
| | hydrocarbon | hydrocarbon | hydrocarbon | hydrocarbon | atom | alkyl |
| | ring group | ring group | ring group | ring group | | group |
| 10 | C4-C12 aromatic | C4-C12 aromatic | C4-C12 aromatic | C4-C12 aromatic | Hydrogen | C1-C12 |
| | hydrocarbon | hydrocarbon | hydrocarbon | hydrocarbon | atom | alkyl |
| | ring group | ring group | ring group | ring group | | group |
| 11 | C4-C12 aromatic | C4-C12 aromatic | C4-C12 aromatic | C4-C12 aromatic | Hydrogen | C4-C12 aromatic |
| | hydrocarbon | hydrocarbon | hydrocarbon | hydrocarbon | atom | hydrocarbon |
| | ring group | ring group | ring group | ring group | | ring group |
| 12 | C4-C12 aromatic | C4-C12 aromatic | C4-C12 aromatic | C4-C12 aromatic | Hydrogen | C4-C12 aromatic |
| | hydrocarbon | hydrocarbon | hydrocarbon | hydrocarbon | atom | hydrocarbon |
| | ring group | ring group | ring group | ring group | | ring group |
| 13 | C4-C12 aromatic | C4-C12 aromatic | C4-C12 aromatic | C4-C12 aromatic | C1-C12 | C1-C12 |
| | hydrocarbon | hydrocarbon | hydrocarbon | hydrocarbon | alkyl | alkyl |
| | ring group | ring group | ring group | ring group | group | group |
| 14 | C4-C12 aromatic | C4-C12 aromatic | C4-C12 aromatic | C4-C12 aromatic | C1-C12 | C1-C12 |
| | hydrocarbon | hydrocarbon | hydrocarbon | hydrocarbon | alkyl | alkyl |
| | ring group | ring group | ring group | ring group | group | group |
| 15 | C4-C12 aromatic | C4-C12 aromatic | C4-C12 aromatic | C4-C12 aromatic | C1-C12 | C4-C12 aromatic |
| | hydrocarbon | hydrocarbon | hydrocarbon | hydrocarbon | alkyl | hydrocarbon |
| | ring group | ring group | ring group | ring group | group | ring group |
| 16 | C4-C12 aromatic | C4-C12 aromatic | C4-C12 aromatic | C4-C12 aromatic | C1-C12 | C4-C12 aromatic |
| | hydrocarbon | hydrocarbon | hydrocarbon | hydrocarbon | alkyl | hydrocarbon |
| | ring group | ring group | ring group | ring group | group | ring group |

| | | | | |
|---|---|---|---|---|
| 17 | Cyclic heterocyclic group | Cyclic heterocyclic group | Hydrogen | C1-C12 |
| | formed by linking R¹ and | formed by linking R² and | atom | alkyl |
| | R⁵ to each other | R⁶ to each other | | group |
| 18 | Cyclic heterocyclic group | Cyclic heterocyclic group | Hydrogen | C1-C12 |
| | formed by linking R¹ and | formed by linking R² and | atom | alkyl |
| | R⁵ to each other | R⁶ to each other | | group |
| 19 | Cyclic heterocyclic group | Cyclic heterocyclic group | Hydrogen | C4-C12 aromatic |
| | formed by linking R¹ and | formed by linking R² and | atom | hydrocarbon |
| | R⁵ to each other | R⁶ to each other | | ring group |
| 20 | Cyclic heterocyclic group | Cyclic heterocyclic group | Hydrogen | C4-C12 aromatic |
| | formed by linking R¹ and | formed by linking R² and | atom | hydrocarbon |
| | R⁵ to each other | R⁶ to each other | | ring group |
| 21 | Cyclic heterocyclic group | Cyclic heterocyclic group | C1-C12 | C1-C12 |
| | formed by linking R¹ and | formed by linking R² and | alkyl | alkyl |
| | R⁵ to each other | R⁶ to each other | group | group |
| 22 | Cyclic heterocyclic group | Cyclic heterocyclic group | C1-C12 | C1-C12 |
| | formed by linking R¹ and | formed by linking R² and | alkyl | alkyl |
| | R⁵ to each other | R⁶ to each other | group | group |
| 23 | Cyclic heterocyclic group | Cyclic heterocyclic group | C1-C12 | C4-C12 aromatic |
| | formed by linking R¹ and | formed by linking R² and | alkyl | hydrocarbon |
| | R⁵ to each other | R⁶ to each other | group | ring group |
| 24 | Cyclic heterocyclic group | Cyclic heterocyclic group | C1-C12 | C4-C12 aromatic |
| | formed by linking R¹ and | formed by linking R² and | alkyl | hydrocarbon |
| | R⁵ to each other | R⁶ to each other | group | ring group |

### [Aⁿ⁻] and n

In Formula (1), [Aⁿ⁻] represents an n-valent halogenoalkylsulfonylimide anion which may have a substituent or an n-valent halogenoalkylsulfonylmethide anion which may have a substituent, and n represents an integer of 1 to 4. Here, A represents an atomic group constituting an anion.

From the viewpoint of the interaction with a cation, n is 1 to 4, preferably 1 to 2, and more preferably 1. By setting n to the upper limit value or less, the anions and the cations are disposed close to each other. Therefore, there is a tendency that the physical properties such as heat resistance and light resistance can be improved.

From the viewpoint that the charges of counter anions are likely to be delocalized, the counter anion of the triarylmethane cation includes an imide anion or a methide anion. That is, the delocalization of the charges of anions makes it possible to suppress the reaction of the counter anion with the triarylmethane cation by heat and light. Therefore, there is a tendency that the durability is improved.

It is considered that in particular, by using a halogenoalkylsulfonylimide anion or a halogenoalkylsulfonylmethide anion as the anion, the charges of the anions are delocalized, and thus, there is a tendency that the interaction with cations is increased and the heat resistance is improved.

The number of carbon atoms of the halogenoalkyl group in the halogenoalkylsulfonylimide anion or the halogenoalkylsulfonylmethide anion is preferably 12 or less, more preferably 10 or less, and still more preferably 6 or less, and preferably 1 or more. The number of carbon atoms is, for example, preferably 1 to 12, more preferably 1 to 10, and still more preferably 1 to 6. By setting the number of carbon atoms to the lower limit value or more, there is a tendency that the charges of the anions are dispersed, and thus, the anions are stabilized. Further, by setting the number of carbon atoms to the upper limit value or less, there is a tendency that the influence of the steric repulsion with the cations is smaller and the interaction with the cations can be stronger.

The type of the halogen atom contained in the halogenoalkyl group is not particularly limited, but is preferably fluorine, chlorine, bromine, or iodine, more preferably fluorine or chlorine, and still more preferably fluorine. By setting the type of the halogen atom to the above-described atoms, there is a tendency that the charges of the anions are more delocalized, and thus, the heat resistance of a coloring material can be improved.

The number of halogen atoms in the halogenoalkyl group is not particularly limited, but is preferably 27 or less, more preferably 12 or less, and still more preferably 6 or less, and preferably 3 or more. The number of halogen atoms is, for example, preferably 3 to 27, more preferably 3 to 12, and still more preferably 3 to 6. By setting the number of halogen atoms to the lower limit value or more, there is a tendency that the charges of the anions are dispersed to stabilize the anions. Further, by setting the number of halogen atoms to the upper limit value or less, there is a tendency that the solubility is moderate, an influence of the steric repulsion with the cations is smaller, and the interaction with cations can be stronger.

Examples of the halogenoalkylsulfonylimide anion include a bistrifluoromethanesulfonylimide anion, a bispentafluoroethanesulfonylimide anion, and a bisnonafluorobutanesulfonylimide anion. From the viewpoint of the heat resistance of the anions, the bistrifluoromethanesulfonylimide anion and the bispentafluoroethanesulfonylimide anion are preferable, and the bistrifluoromethanesulfonylimide anion is more preferable.

Examples of the halogenoalkylsulfonylmethide anion include a tristrifluoromethanesulfonylimide anion, a trispentafluoroethanesulfonylimide anion, and a trisnonafluorobutanesulfonylimide anion. From the viewpoint that the influence of the steric repulsion with the cation is small, the tristrifluoromethanesulfonylimide anion and the trispentafluoroethanesulfonylimide anion are preferable, and the bistrifluoromethanesulfonylimide anion is more preferable.

The substituent that the halogenoalkylsulfonylimide anion or the halogenoalkylsulfonylmethide anion may have is not particularly limited, and the substituents that are exemplary examples mentioned as the substituent group W3 described above can be used. Among these, the aromatic ring group which may have a substituent is preferable from the viewpoint of the stability of a charge distribution in the anions.

Examples of the aromatic ring group include an aromatic hydrocarbon ring group and an aromatic heterocyclic group. The number of carbon atoms is not particularly limited, but is preferably 30 or less, and more preferably 12 or less, and preferably 4 or more, and more preferably 6 or more. By setting the number of carbon atoms to the upper limit value or less, there is a tendency that the steric hindrance with cations is suppressed, and thus, the anions can be stabilized.

The above-described upper limits and lower limits can be combined in any manner. For example, the number of carbon atoms is preferably 4 to 30, more preferably 4 to 12, and still more preferably 6 to 12.

The aromatic hydrocarbon ring group may be a monocyclic ring or a fused ring, and examples thereof include a benzene ring, a naphthalene ring, an anthracene ring, a phenanthrene ring, a perylene ring, a tetracene ring, a pyrene ring, a benzopyrene ring, a chrysene ring, a triphenylene ring, an acenaphthene ring, a fluoranthene ring, and a fluorene ring, each of which has one free valence.

The aromatic heterocyclic group may be a monocyclic ring or a fused ring, and examples thereof include a furan ring, a benzofuran ring, a thiophene ring, a benzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzisoxazole ring, a benzisothiazole ring, a benzimidazole ring, a pyridine ring, a pyrazine ring, a pyridazine ring, a pyrimidine ring, a triazine ring, a quinoline ring, an isoquinoline ring, a shinorine ring, a quinoxaline ring, a phenanthridine ring, a perimidine ring, a quinazoline ring, a quinazolinone ring, and an azulene ring, each of which has one free valence.

From the viewpoint of suppressing the steric hindrance with the cations, the benzene ring, the naphthalene ring, the thiophene ring, and the triazine ring, each of which has one free valence, are preferable, the benzene ring and the triazine ring, each of which has one free valence, are more preferable, and the triazine ring having one free valence is still more preferable. Since the triazine ring has high planarity, it is considered that there is a tendency that the interaction with an aromatic moiety contained in a cation of a dye or an anionic moiety present in the same system is increased. In addition, since [Aⁿ⁻] has a sulfonylimide skeleton or a sulfonylmethide skeleton, it is considered that steric repulsion with the cation is decreased and a more solid ion pair is easily formed. As a result, since the cation and the anion are less likely to be separated from each other, there is a tendency that the heat resistance is high, a reduction in interaction between a cation and an anion is likely to be suppressed even in an electric field, and the voltage retention rate of a pixel obtained in this manner is increased.

The number of substituents that the halogenoalkylsulfonylimide anion or the halogenoalkylsulfonylmethide anion may have is not particularly limited, but from the viewpoint of suppressing the steric hindrance, the number of substituents is preferably 1 to 3, and more preferably 1.

### Anion Represented by Formula (A-1) or Formula (A-2)

Among those, from the viewpoint of anion stability, a substituent of an n-valent halogenoalkylsulfonylimide anion which may have a substituent or an n-valent halogenoalkylsulfonylmethide anion which may have a substituent, represented by [Aⁿ⁻], is preferably at a terminal of the anion, and in particular, an anion represented by General Formula (A-1) or an anion represented by General Formula (A-2) is preferable.

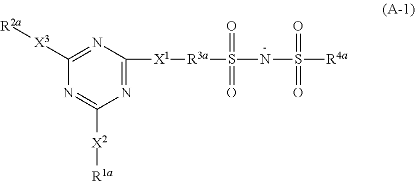

In Formula (A-1), R^{1a} and R^{2a} each independently represent a hydrogen atom, an alkyl group which may have a substituent, or an aromatic ring group which may have a substituent.
R^{3a} represents a direct bond, an alkylene group which may have a substituent, or a divalent aromatic ring group which may have a substituent.
R^{4a} represents a halogenoalkyl group.
X¹ to X³ each independently represent at least one group selected from the group consisting of a direct bond, —(CH₂)—, —NH—, —O—, and —S—, or a group in which two or more of these are bonded to each other.

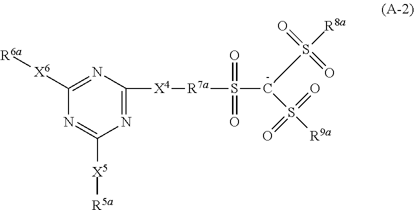

In Formula (A-2), R^{5a} and R^{1a} each independently represent a hydrogen atom, an alkyl group which may have a substituent, or an aromatic ring group which may have a substituent.
R^{7a} represents a direct bond, an alkylene group which may have a substituent, or a divalent aromatic ring group which may have a substituent.
R^{8a} and R^{9a} each independently represent a halogenoalkyl group.
X⁴ to X⁶ each independently represent at least one group selected from the group consisting of a direct bond, —(CH₂)—, —NH—, —O—, and —S—, or a group in which two or more of these are bonded to each other.
   R^{1a}, R^{2a}, R^{5a}, and R^{6a}
R^{1a}, R^{2a}, R^{5a}, and R^{6a} each independently represent a hydrogen atom, an alkyl group which may have a substituent, or an aromatic ring group which may have a substituent.

Examples of the alkyl group include a linear, branched, or cyclic alkyl group. The number of carbon atoms thereof is preferably 8 or less, and more preferably 5 or less from the viewpoint of the solubility in a solvent, and is preferably 2 or more from the viewpoint of the solubility in a solvent. For example, the number of carbon atoms is preferably 2 to 8, and more preferably 2 to 5.

Examples of the alkyl group include a methyl group, an ethyl group, an n-propyl group, a 2-propyl group, an n-butyl group, an isobutyl group, a tert-butyl group, a 2-ethylhexyl group, a cyclohexyl group, a cyclohexylmethyl group, a cyclohexylethyl group, and a 3-methylbutyl group. Among these, the linear or branched alkyl group is preferable, and the linear alkyl group is more preferable from the viewpoint of a balance between the crystallinity and the solubility of the formed salt.

Examples of the substituent that the alkyl group may have include the substituents in the substituent group W1 described above.

Examples of the aromatic ring group include an aromatic hydrocarbon ring group and an aromatic heterocyclic group. From the viewpoint of suppressing the steric hindrance, the number of carbon atoms is preferably 30 or less, and more preferably 12 or less, and from the viewpoint of a balance between crystallinity and solubility, the number of carbon atoms is preferably 4 or more, and more preferably 6 or more.

The above-described upper limits and lower limits can be combined in any manner. For example, the number of carbon atoms is preferably 4 to 30, more preferably 4 to 12, and still more preferably 6 to 12.

The aromatic hydrocarbon ring group may be a monocyclic ring or a fused ring, and examples thereof include a benzene ring, a naphthalene ring, an anthracene ring, a phenanthrene ring, a perylene ring, a tetracene ring, a pyrene ring, a benzopyrene ring, a chrysene ring, a triphenylene ring, an acenaphthene ring, a fluoranthene ring, and a fluorene ring, each of which has one free valence.

The aromatic heterocyclic group may be a monocyclic ring or a fused ring, and examples thereof include a furan ring, a benzofuran ring, a thiophene ring, a benzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzisoxazole ring, a benzisothiazole ring, a benzimidazole ring, a pyridine ring, a pyrazine ring, a pyridazine ring, a pyrimidine ring, a triazine ring, a quinoline ring, an isoquinoline ring, a shinorine ring, a quinoxaline ring, a phenanthridine ring, a perimidine ring, a quinazoline ring, a quinazolinone ring, and an azulene ring, each of which has one free valence.

Among these aromatic ring groups, from the viewpoint of an ease in production, the aromatic hydrocarbon ring group is preferable.

Examples of the substituent that the aromatic ring group may have include the substituents in the substituent group W2 described above.

Among those, R^{1a} and R^{2a} are each independently preferably the alkyl group which may have a substituent, or the aromatic ring group which may have a substituent from the viewpoint of the stability of the colored resin composition.
R^{1a} and R^{2a} may be the same as or different from each other. For example, Ria and R^{2a} may be each independently an alkyl group which may have a substituent, R^{1a} and R^{2a} may be each independently an aromatic ring group which may have a substituent, Ria may be an alkyl group which may have a substituent, and R^{2a} may be an aromatic ring group which may have a substituent.

R^{5a} and R^{6a} may be the same as or different from each other. For example, R^{5a} and R^{6a} may be each independently an alkyl group which may have a substituent, R^{5a} and R^{6a} may be each independently an aromatic ring group which may have a substituent, R^{5a} may be an alkyl group which may have a substituent, and R^{6a} may be an aromatic ring group which may have a substituent.

R^{3a} and R^{7a}

R^{3a} represents a direct bond, an alkylene group which may have a substituent, or a divalent aromatic ring group which may have a substituent.

Examples of the alkylene group include a linear alkylene group, a branched alkylene group, a cyclic alkylene group, or a group in which these are bonded to each other. From the viewpoint of suppressing a bias of charges, the number of carbon atoms is preferably 8 or less, and more preferably 5 or less, and preferably 1 or more. The number of carbon atoms is, for example, preferably 1 to 8, and more preferably 1 to 5.

Examples of the alkylene group include a methylene group, an ethylene group, and a propylene group. From the viewpoint of suppressing a bias of charges, the methylene group is preferable.

Examples of the substituent that the alkylene group may have include the substituents in the substituent group W1 described above.

Examples of the divalent aromatic ring group include a divalent aromatic hydrocarbon ring group and a divalent aromatic heterocyclic group. From the viewpoint of the rigidity and the heat resistance of anions, the number of carbon atoms is preferably 30 or less, and more preferably 12 or less, and preferably 4 or more, and more preferably 6 or more.

The above-described upper limits and lower limits can be combined in any manner. For example, the number of carbon atoms is preferably 4 to 30, more preferably 4 to 12, and still more preferably 6 to 12.

The divalent aromatic hydrocarbon ring group may be a monocyclic ring or a fused ring, and examples thereof include a benzene ring, a naphthalene ring, an anthracene ring, a phenanthrene ring, a perylene ring, a tetracene ring, a pyrene ring, a benzopyrene ring, a chrysene ring, a triphenylene ring, an acenaphthene ring, a fluoranthene ring, and a fluorene ring, each of which has 2 free valences.

The aromatic heterocyclic group may be a monocyclic ring or a fused ring, and examples thereof include a furan ring, a benzofuran ring, a thiophene ring, a benzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzisoxazole ring, a benzisothiazole ring, a benzimidazole ring, a pyridine ring, a pyrazine ring, a pyridazine ring, a pyrimidine ring, a triazine ring, a quinoline ring, an isoquinoline ring, a shinorine ring, a quinoxaline ring, a phenanthridine ring, a perimidine ring, a quinazoline ring, a quinazolinone ring, and an azulene ring, each of which has 2 free valences.

From the viewpoint of suppressing a bias of charges, the divalent aromatic hydrocarbon ring group is preferable, and the benzene ring having 2 free valences is more preferable.

Examples of the substituent that the divalent aromatic ring group may have include the substituents in the substituent group W2 described above.

R^{4a}, R^{8a}, and R^{9a}

R^{4a}, R^{8a}, and R^{9a} each independently represent a halogenoalkyl group.

The type of the halogen atom contained in the halogenoalkyl group is not particularly limited, but is preferably fluorine, chlorine, bromine, or iodine, more preferably fluorine or chlorine, and still more preferably fluorine. By setting the type of the halogen atom to the above-described atoms, there is a tendency that the charges of the anions are more delocalized, and thus, the heat resistance of a coloring material can be improved.

The number of halogen atoms in the halogenoalkyl group is not particularly limited, but is preferably 27 or less, more preferably 12 or less, and still more preferably 6 or less, and preferably 3 or more. The number of halogen atoms is, for example, preferably 3 to 27, more preferably 3 to 12, and still more preferably 3 to 6. By setting the number of halogen atoms to the lower limit value or more, there is a tendency that the charges of the anions are dispersed to stabilize the anions. Further, by setting the number of halogen atoms to the upper limit value or less, there is a tendency that the solubility is moderate, an influence of the steric repulsion with the cations is smaller, and the interaction with cations can be stronger.

The number of carbon atoms of the halogenoalkyl group is not particularly limited, but is preferably 12 or less, and more preferably 6 or less, and preferably 1 or more. The number of carbon atoms is, for example, preferably 1 to 12, and more preferably 1 to 6. By setting the number of carbon atoms to the lower limit value or more, there is a tendency that the charges of the anions are dispersed, and thus, the anions are stabilized. Further, by setting the number of carbon atoms to the upper limit value or less, there is a tendency that the influence of the steric repulsion with the cations is smaller and the interaction with the cations can be stronger.

Examples of the halogenoalkyl group include a trifluoromethyl group, a pentafluoroethyl group, and a 1,1,1-trifluoroethyl group. From the viewpoint of suppressing a bias of charges, the trifluoromethyl group is preferable.

X¹ to X⁶

X¹ to X⁶ each independently represent at least one group selected from the group consisting of a direct bond, —(CH₂)—, —NH—, —O—, and —S—, or a group in which two or more of these are bonded to each other.
X¹ to X⁶ may be each independently a group obtained by bonding two or more kinds of divalent groups selected from the group, or may be a group obtained by bonding two or more groups of one kind. The number of carbon atoms when the groups are bonded is preferably 2 or more, and preferably 15 or less, more preferably 12 or less, and still more preferably 10 or less, and is, for example, preferably 2 to 15, more preferably 2 to 12, and still more preferably 2 to 10.

From the viewpoint of an ease in synthesis, —(CH₂)— or —NH— is preferable, and —NH— is more preferable.

From the viewpoint that since the heat resistance is high and the influence of steric repulsion with cations is small, the interaction between anions and cations is increased, and the counterion is stabilized to improve the heat resistance of a dye, a bistrifluoromethanesulfonylimide anion, a tristrifluoromethanesulfonylmethide anion, or a 2,6-diphenylamino-4-butylamino-1,3,5-triazine ring-containing trifluoromethanesulfonylimide anion is preferable as [Aⁿ⁻].

In the colored resin composition of the first aspect, an existence form of the triarylmethane compound represented by Formula (1) is not particularly limited, and may be a dye and/or a pigment. From the viewpoints of a luminance and a contrast, the triarylmethane compound is preferably present in the form of the dye.

### Molecular Weight

In the triarylmethane compound represented by Formula (1), the molecular weight of the triarylmethane cation is preferably 270 or more, and more preferably 470 or more, and preferably 1,970 or less. The molecular weight is, for example, preferably 270 to 1,970, and more preferably 470 to 1,970. When the molecular weight is within the range, the solubility in the colored resin composition is sufficient, the content in the colored resin composition can be decreased. Therefore, the curability is sufficiently ensured, and such the molecular weight is preferable.

The total molecular weight of the cations and the anions is preferably 300 or more, and more preferably 500 or more, and preferably 2,000 or less. The total molecular weight is, for example, preferably 300 to 2,000, and more preferably 500 to 2,000. When the molecular weight is within the range, the solubility in the colored resin composition is sufficient, the content in the colored resin composition can be decreased. Therefore, the curability is sufficiently ensured, and such the molecular weight is preferable.

### Specific Examples of Compound Represented by Formula (1)

As the compound represented by Formula (1), for example, the following compounds can be used.

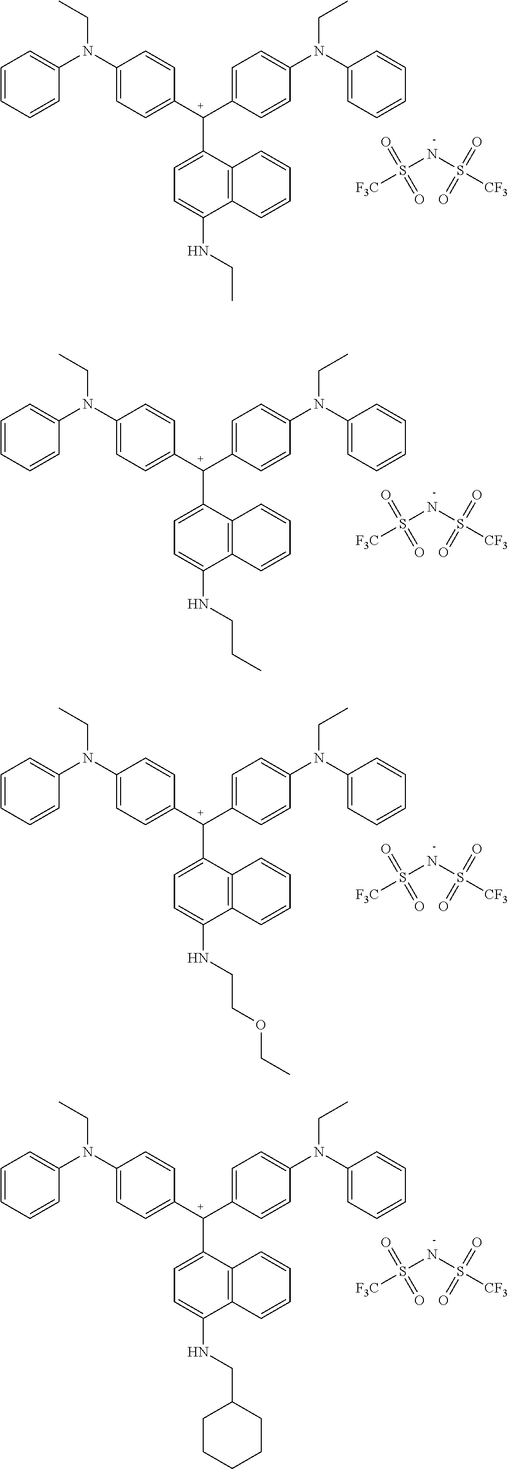

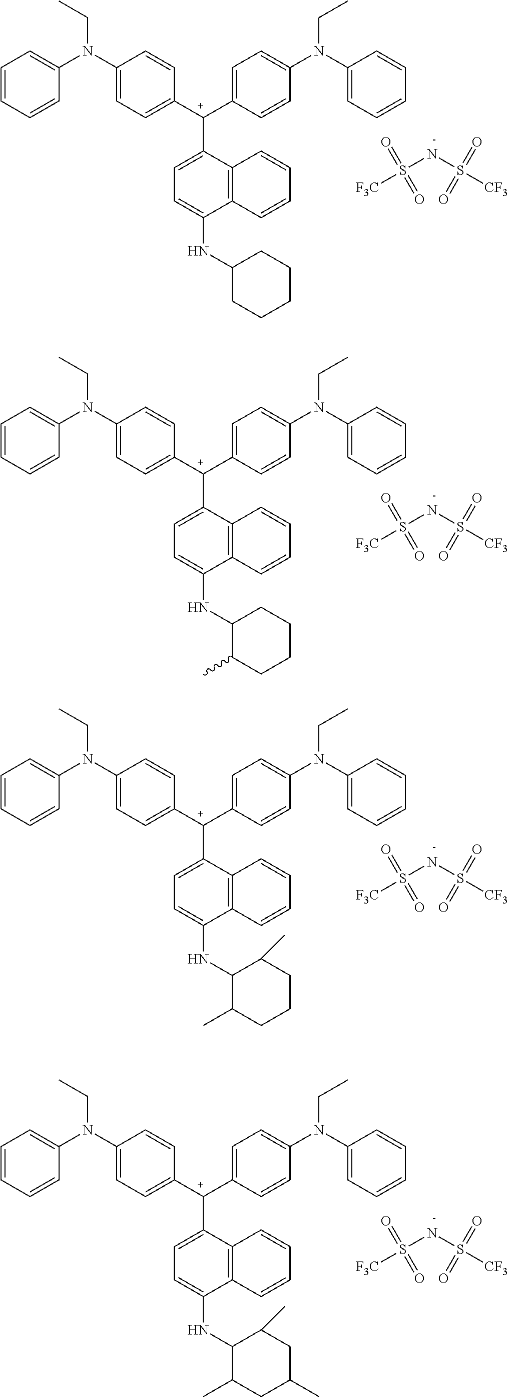

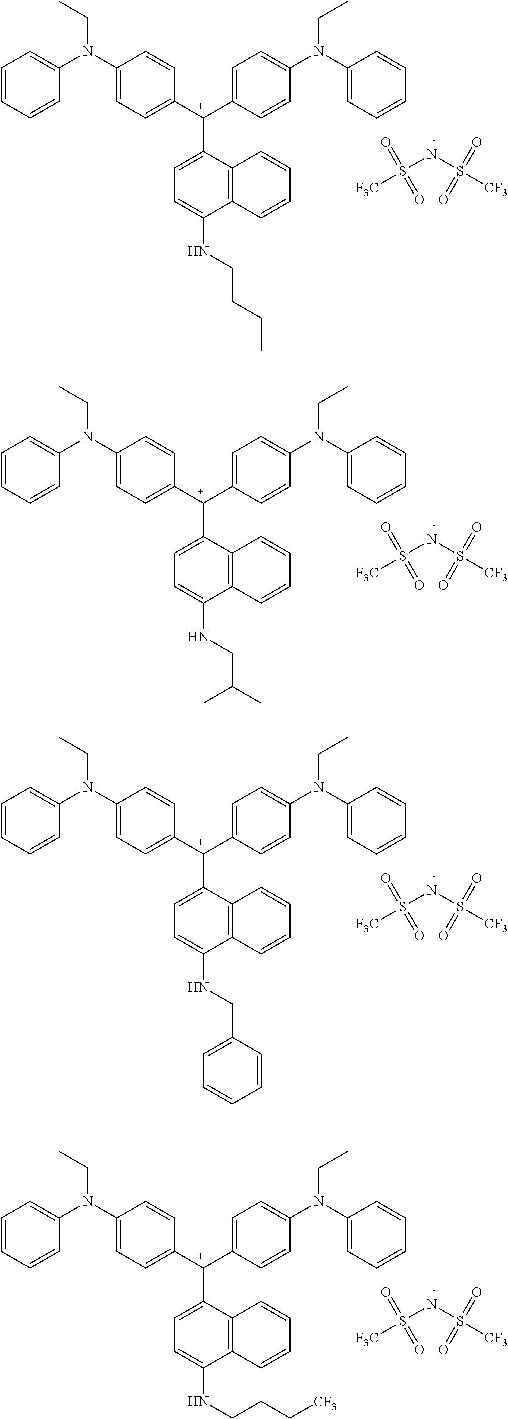

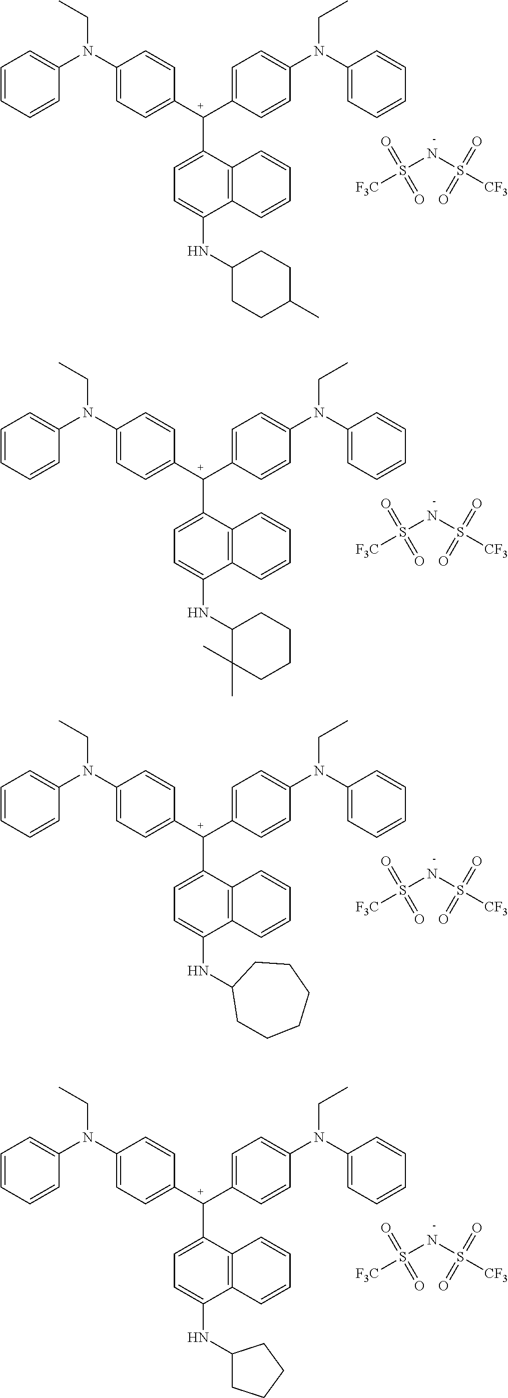

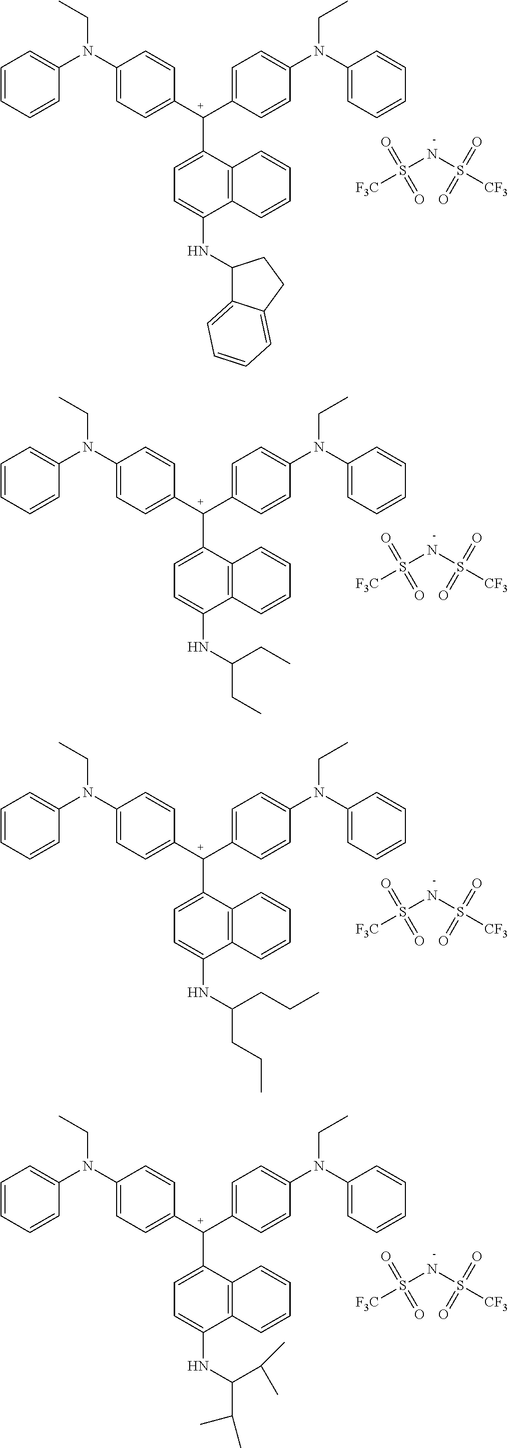

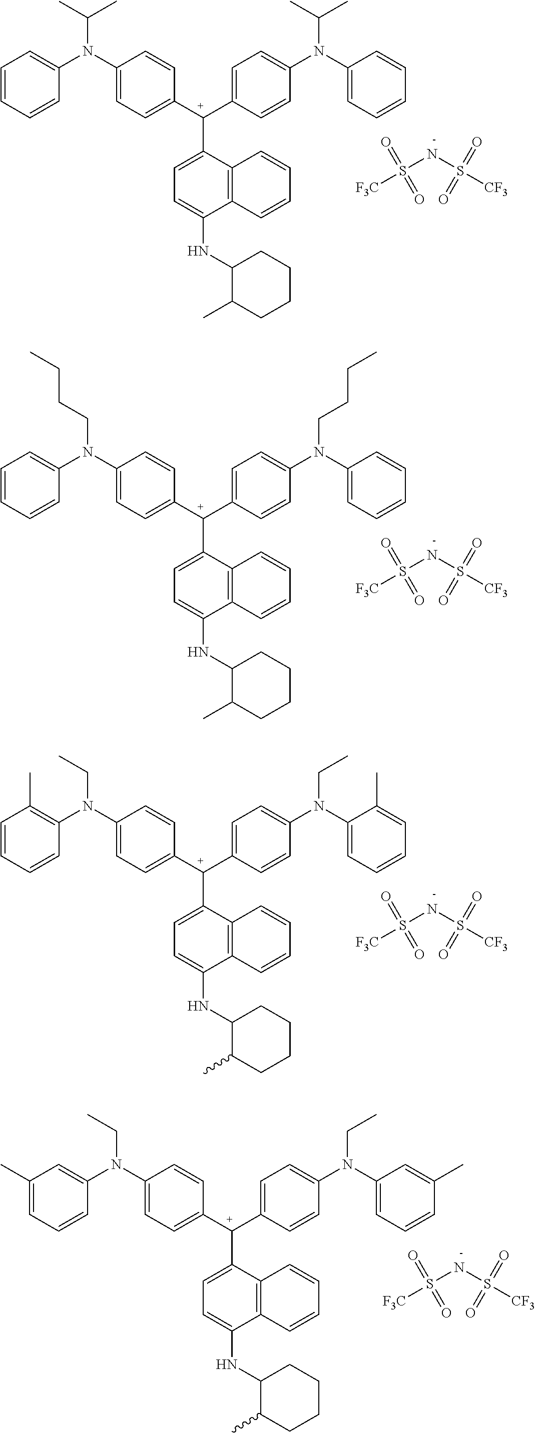

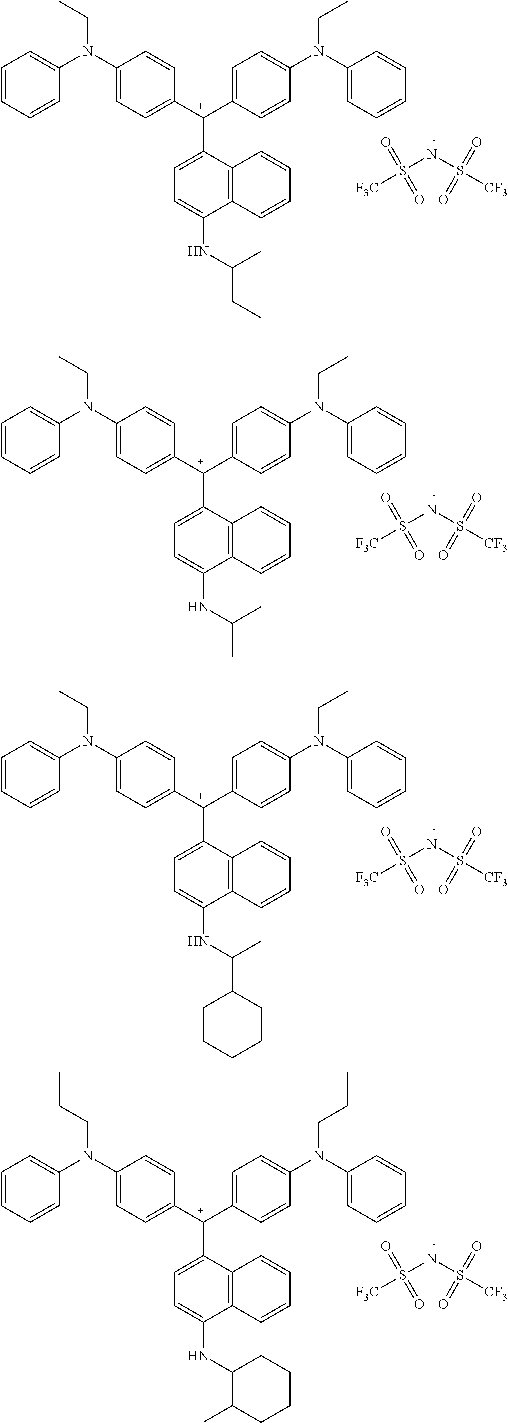

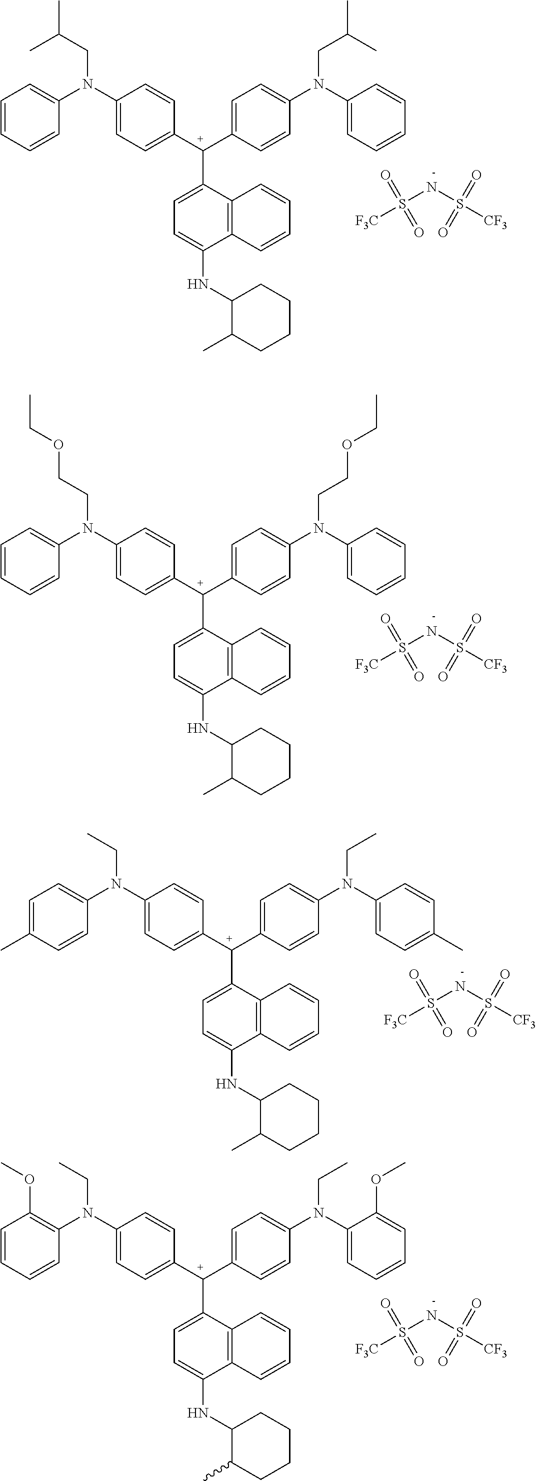

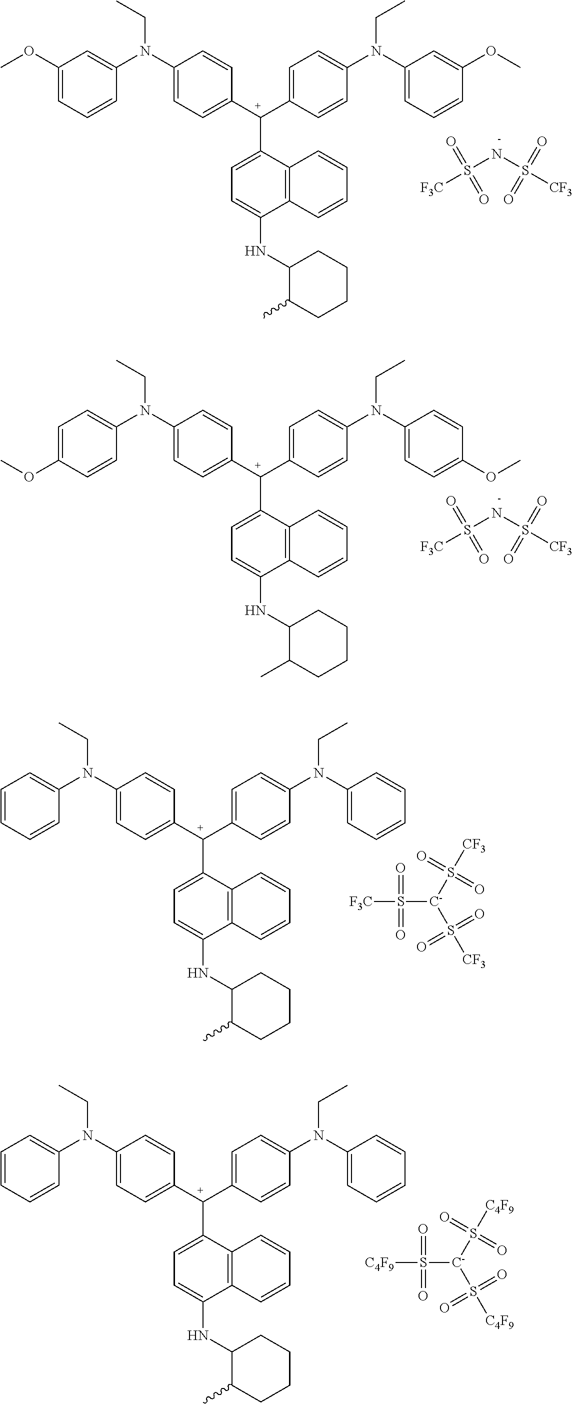

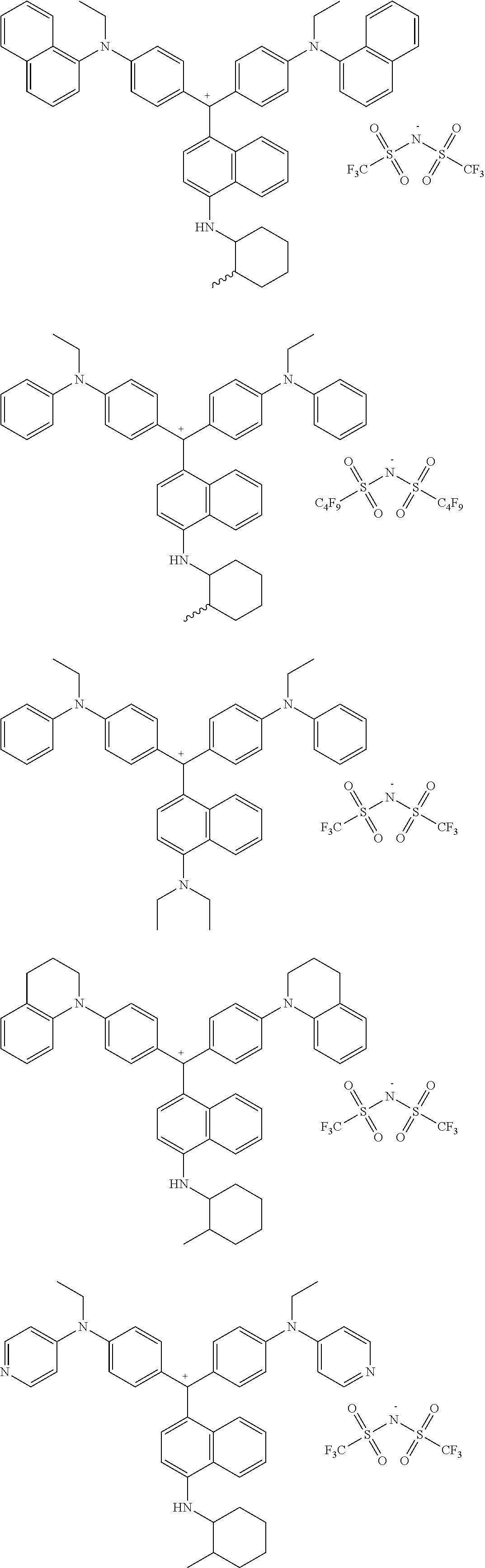

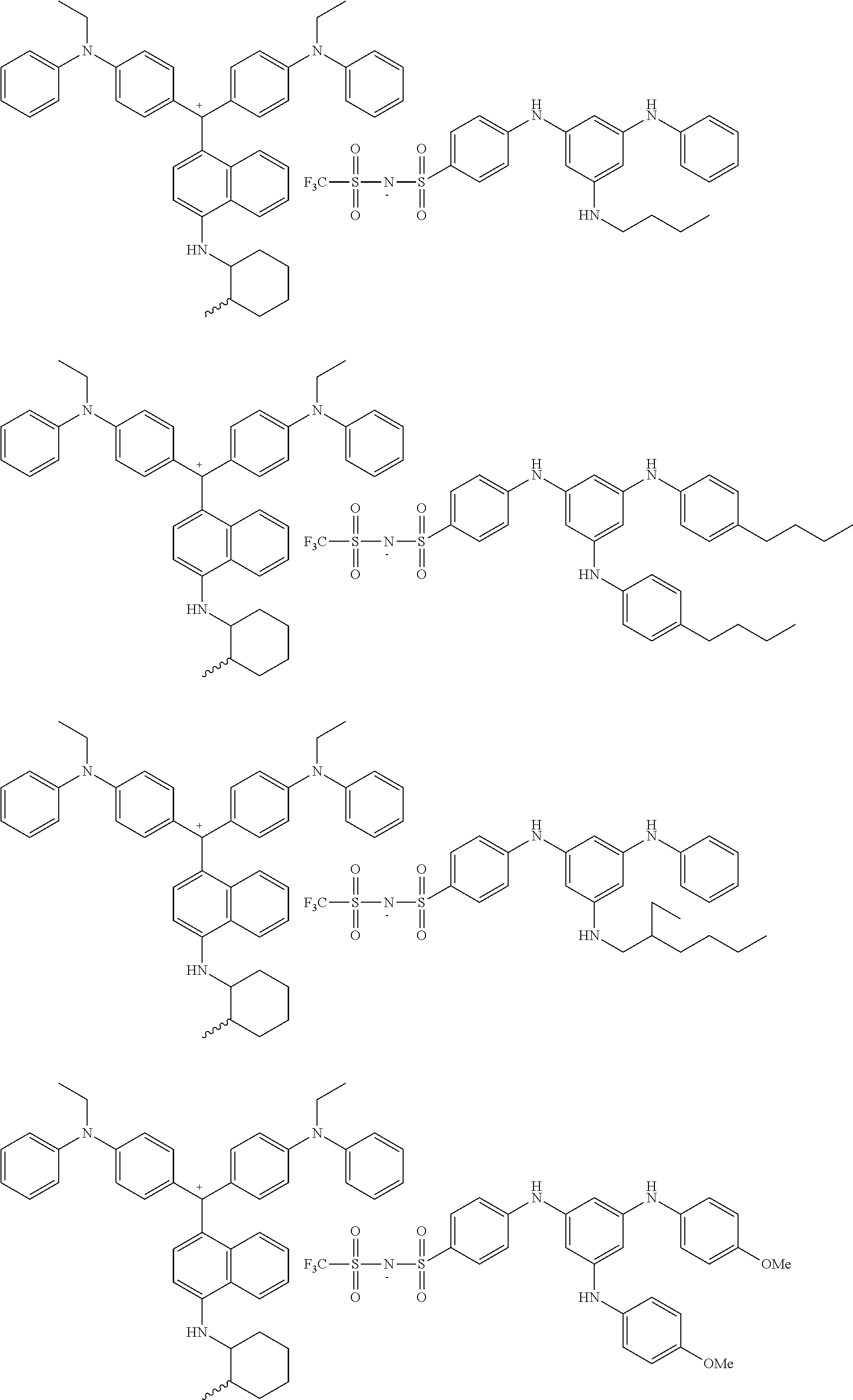

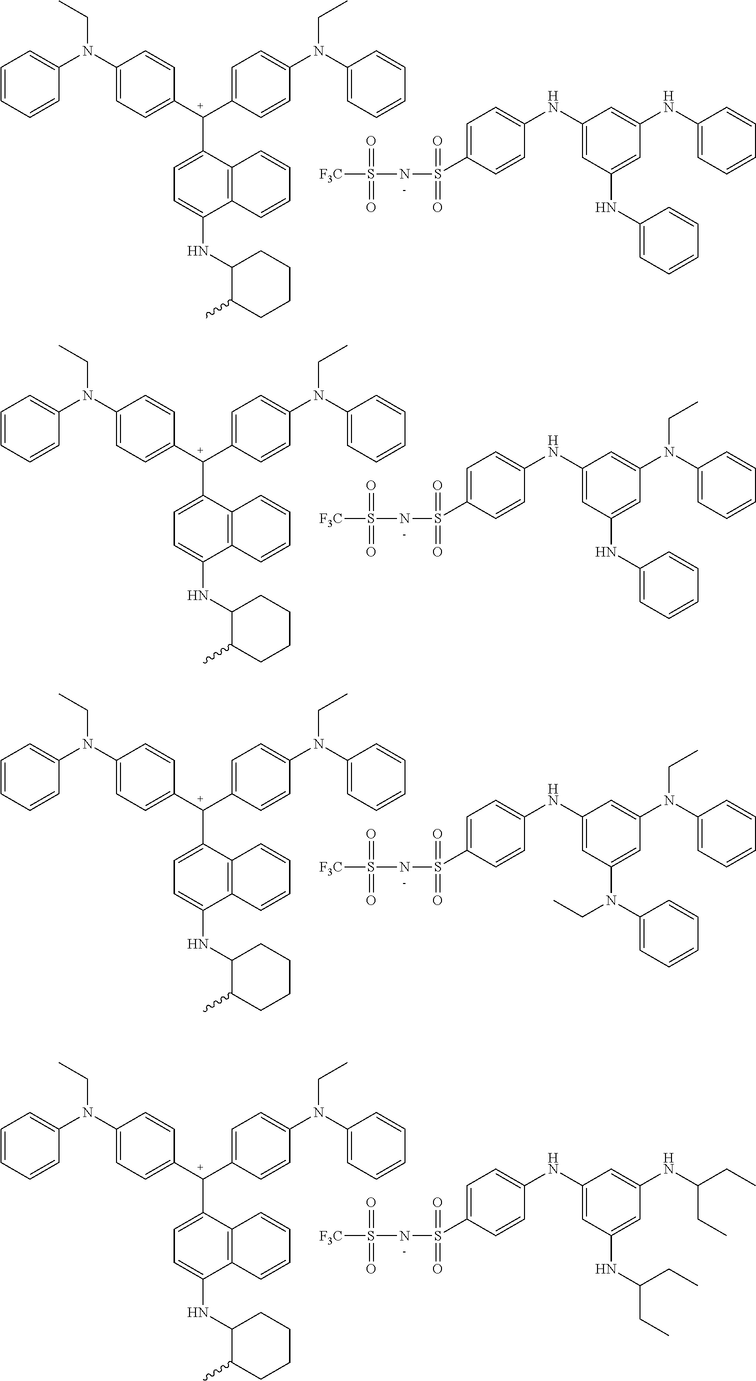

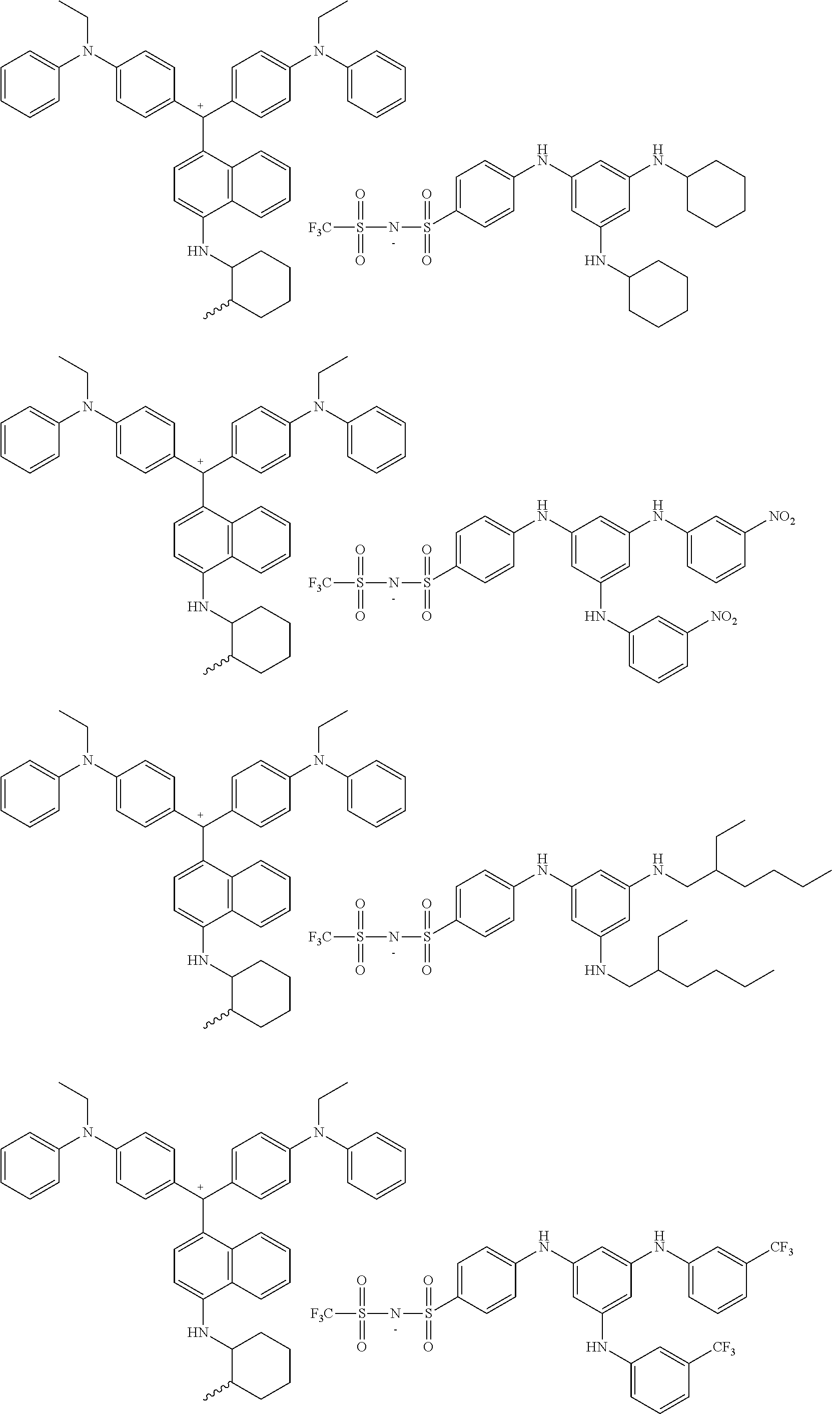

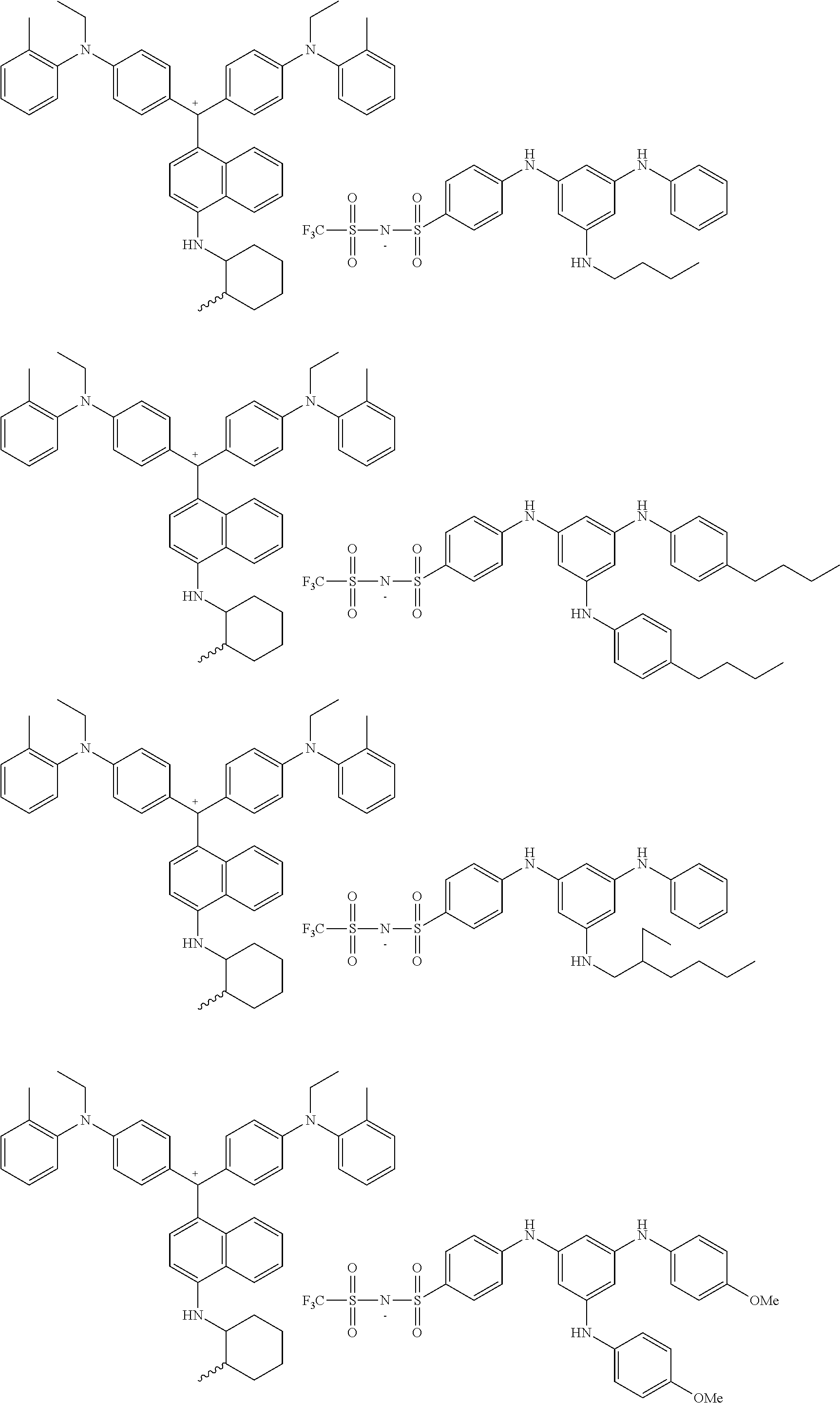

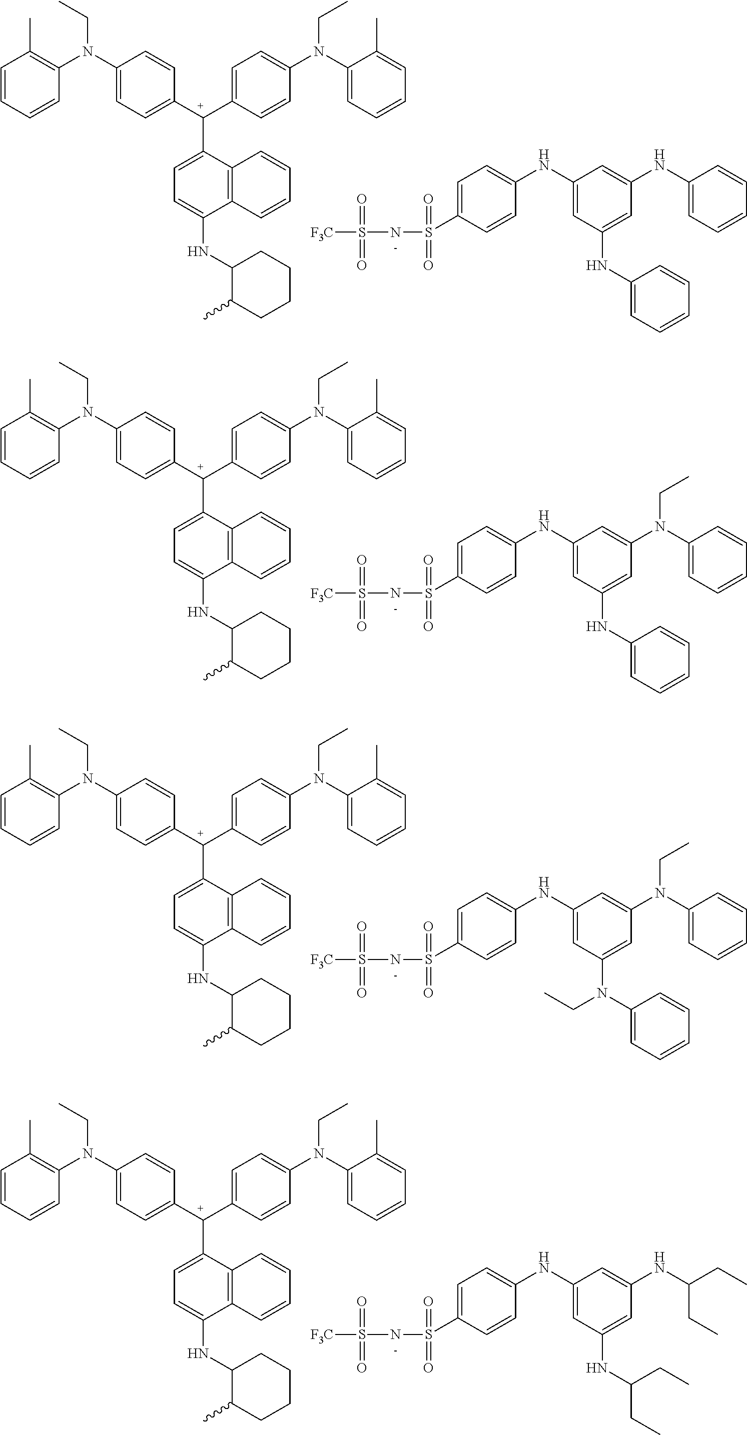

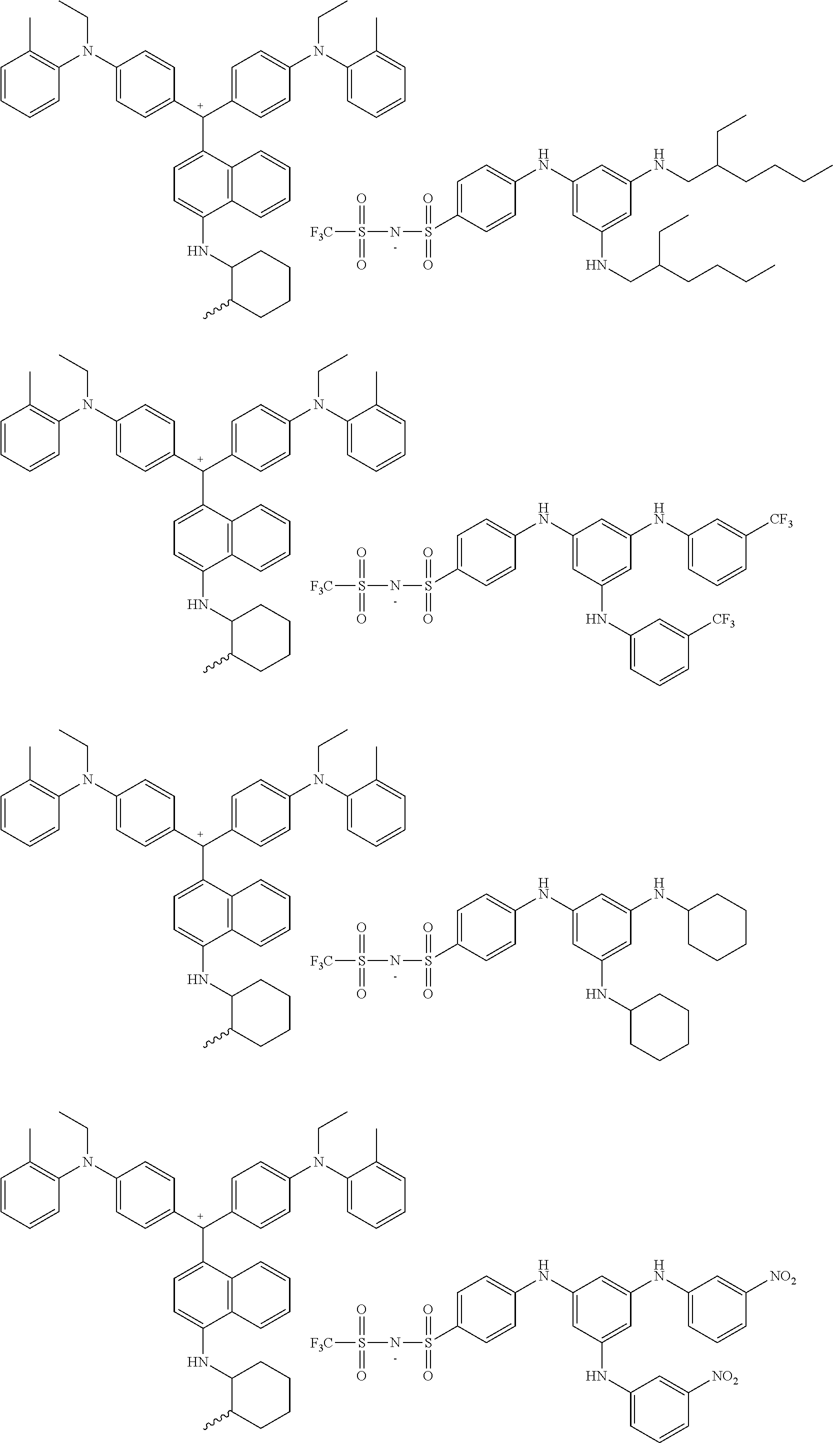

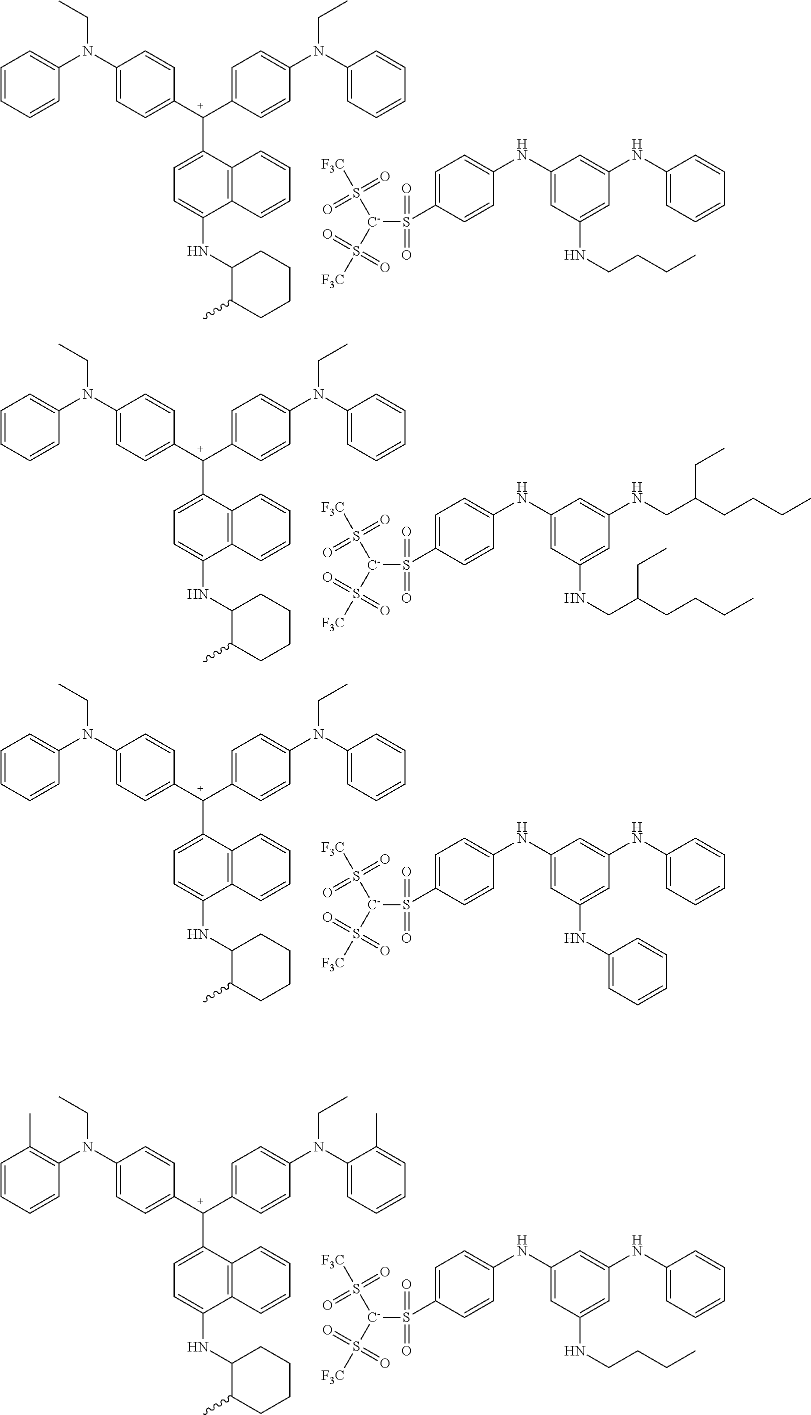

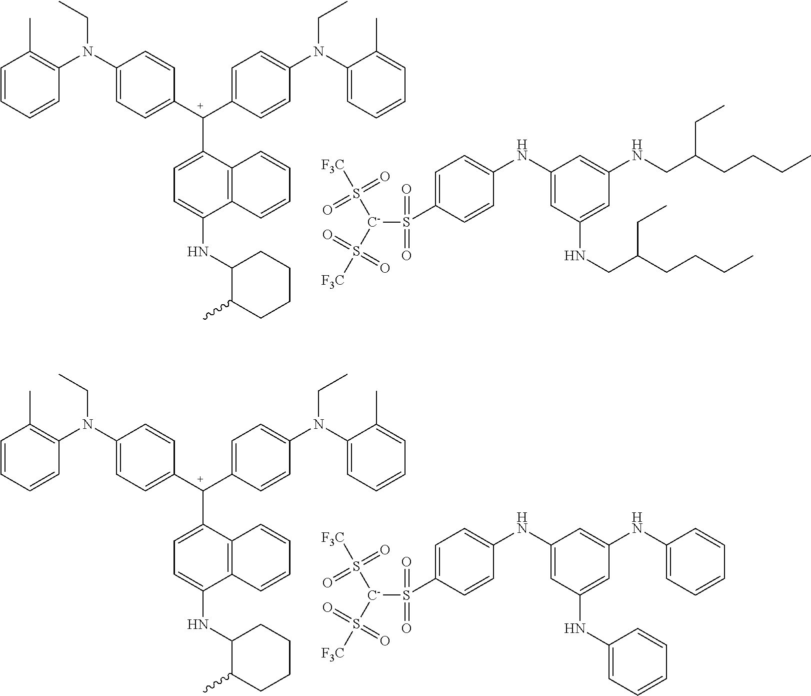

### Method for Synthesizing Compound Represented by Formula (1)

The triarylmethane compound represented by Formula (1) can be synthesized according to, for example, the method described in “General Synthesis Dye” (Horiguchi Hiroshi, Sankyo Shuppan Co., Ltd., 1968), “Theoretical Manufacturing/Dye Chemistry” (Yutaka Hosoda, Gihodo Shuppan Co., Ltd., 1957), and PCT International Publication No. 2009/107734, but the present invention is not limited to these methods.

### Content Proportion of Colorant (a1) in Colored Resin Composition

The colorant (a1) can be contained at a content proportion of preferably 0.01% by mass or more, more preferably 0.1% by mass or more, still more preferably 1% by mass or more, even still preferably 5% by mass or more, and particularly preferably 8% by mass or more, and preferably 70% by mass or less, more preferably 40% by mass or less, still more preferably 30% by mass or less, and particularly preferably 25% by mass or less, in a total solid content of the colored resin composition of the first aspect. When the content proportion is the upper limit value or less, there is a tendency that the curability of a coating film is less likely to be deteriorated and a film strength is sufficient, which is thus preferable. In addition, when the content proportion is the lower limit value or more, a coloring power is sufficient, a chromaticity having a desired concentration can be easily obtained, and a film thickness is less likely to be increased, which is thus preferable.

The above-described upper limits and lower limits can be combined in any manner. For example, the content proportion is preferably 0.01% to 70% by mass, more preferably 0.1% to 70% by mass, still more preferably 1% to 40% by mass, even still more preferably 5% to 30% by mass, and particularly preferably 8% to 25% by mass.

### Content Proportion of Compound Represented by Formula (1) in Colored Resin Composition

The colored resin composition of the first aspect may include only one kind of the compound represented by Formula (1) as the colorant (a1) or may include two or more kinds of the compounds.

The compound represented by Formula (1) can be contained at a content proportion of preferably 0.01% by mass or more, more preferably 0.1% by mass or more, still more preferably 1% by mass or more, even still preferably 5% by mass or more, and particularly preferably 8% by mass or more, and preferably 70% by mass or less, more preferably 40% by mass or less, still more preferably 30% by mass or less, and particularly preferably 25% by mass or less, in a total solid content of the colored resin composition of the first aspect. When the content proportion is the upper limit value or less, there is a tendency that the curability of a coating film is less likely to be deteriorated and a film strength is sufficient, which is thus preferable. In addition, when the content proportion is the lower limit value or more, a coloring power is sufficient, a chromaticity having a desired concentration can be easily obtained, and a film thickness is less likely to be increased, which is thus preferable.

The above-described upper limits and lower limits can be combined in any manner. For example, the content proportion is preferably 0.01% to 70% by mass, more preferably 0.1% to 70% by mass, still more preferably 1% to 40% by mass, even still more preferably 5% to 30% by mass, and particularly preferably 8% to 25% by mass. 1-1-2 Colorant (a2) Included in Colorant (A) in Colored Resin Composition of Second Aspect

The colorant (A) in the colored resin composition of the second aspect contains a colorant (a2) having a light absorption maximum at a wavelength range of 650 to 700 nm in a wavelength range of 400 and 900 nm. By allowing the composition to contain the colorant (a2), there is a tendency that a color filter having excellent transparency of green light is obtained.

The colorant (a2) is not particularly limited as long as it is a colorant having a light absorption maximum at a wavelength range of 650 to 700 nm in a wavelength range of 400 and 900 nm. The colorant (a2) is preferably a phthalocyanine compound represented by General Formula (3) (hereinafter also referred to as a “phthalocyanine compound (3)”), and the colorant (A) in the colored resin composition of the second aspect preferably has at least one or more phthalocyanine compounds (3) having a light absorption maximum at a wavelength range of 650 to 700 nm in a wavelength range of 400 and 900 nm. By allowing the composition to contain the phthalocyanine compound (3), green light in a visible region can be selectively transmitted, and by further combining a near-infrared absorbing compound therewith, there is a tendency that a color filter which selectively transmits only green light in a visible region through a near-infrared region is obtained.

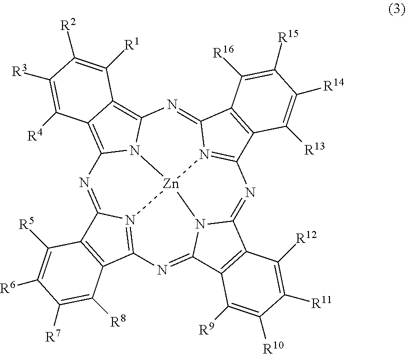

In Formula (3), R¹ to R¹⁶ each independently represent a hydrogen atom, a halogen atom, or a group represented by General Formula (4). It should be noted that one or more of R¹ to R¹⁶ represent a halogen atom, and one or more of R¹ to R¹⁶ represent a group represented by General Formula (4).

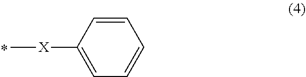

In Formula (4), X represents a divalent linking group, a benzene ring in Formula (4) may have any substituent, and * represents a binding site.

R¹ to R¹⁶

Examples of the halogen atom for R¹ to R¹⁶ include a fluorine atom, a chlorine atom, and a bromine atom. From the viewpoint of achieving a high luminance, the fluorine atom is preferable.

Preferably 6 or more groups, more preferably 7 or more groups, still more preferably 8 or more groups of R¹ to R¹⁶ are fluorine atoms, and preferably 15 or less groups, more preferably 12 or less groups, and still more preferably 10 or less groups of R¹ to R¹⁶ are fluorine atoms. By setting the number of the groups that are fluorine atoms to the lower limit value or more, there is a tendency that the stability of the phthalocyanine compound (3) is improved. By setting the number of the groups that are fluorine atoms to the upper limit value or less, the affinity of the dispersant or the solvent in the colored resin composition is improved.

The above-described upper limits and lower limits can be combined in any manner. For example, preferably 6 to 15 groups, more preferably 7 to 12 groups, and still more preferably 8 to 10 groups of R¹ to R¹⁶ are fluorine atoms.

### X

X in Formula (4) represents a divalent linking group. The divalent linking group is not particularly limited, but examples thereof include an oxygen atom, a sulfur atom, or a —N(R^{a1})— group (R^{a1} represents a hydrogen atom or an aliphatic hydrocarbon group having 1 to 6 carbon atoms). Among these, the oxygen atom or the sulfur atom is preferable, and the oxygen atom is more preferable from the viewpoint of the stability during sintering.

Substituent that Benzene Ring May have

a benzene ring in Formula (4) may have any substituent. The acceptable substituent is not particularly limited, but examples thereof include a halogen atom, an alkyl group, an alkoxy group (—OR^{A} group (R^{A} represents an alkyl group)), an alkoxycarbonyl group (—COOR^{A} group (R^{A} represents an alkyl group)), an aryl group, an aryloxy group (—OR^{B} group (R^{B} represents an aryl group)), and an aryloxycarbonyl group (—COOR^{B} group (R^{B} represents an aryl group)). Among these, the alkoxycarbonyl group is preferable from the viewpoints of a development solubility and a luminance.

The alkyl group included in these groups may be linear, branched, or cyclic. From the viewpoint of the affinity with an organic solvent, the alkyl group is preferably linear.

The number of carbon atoms of the alkyl group is not particularly limited, but is preferably 1 or more, and more preferably 2 or more, and preferably 6 or less, more preferably 5 or less, and still more preferably 4 or less. By setting the number of carbon atoms to the lower limit value or more, there is a tendency that the aggregation is suppressed and foreign matters are suppressed. By setting the number of carbon atoms to the upper limit value or less, there is a tendency that the solvent affinity is improved and the stability over time is improved.

The above-described upper limits and lower limits can be combined in any manner. For example, the number of carbon atoms of the alkyl group is preferably 1 to 6, more preferably 1 to 5, still more preferably 1 to 4, and particularly preferably 2 to 4.

Examples of the alkyl group include a methyl group, an ethyl group, a propyl group, a butyl group, a pentyl group, and a hexyl group. From the viewpoint of suppressing the aggregation, the methyl group and the ethyl group are preferable, and the ethyl group is more preferable.

The aryl group included in these groups may be an aromatic hydrocarbon ring group or an aromatic heterocyclic group.

The number of carbon atoms of the aryl group is not particularly limited, but is preferably 4 or more, and more preferably 6 or more, and preferably 12 or less, more preferably 10 or less, and still more preferably 8 or less. By setting the number of carbon atoms to the lower limit value or more, there is a tendency that the aggregation is suppressed by steric repulsion. By setting the number of carbon atoms to the upper limit value or less, there is a tendency that the solvent affinity is improved and the stability over time is improved.

The above-described upper limits and lower limits can be combined in any manner. For example, the number of carbon atoms is preferably 4 to 12, more preferably 4 to 10, still more preferably 4 to 8, and particularly preferably 6 to 8.

The aromatic hydrocarbon ring in the aromatic hydrocarbon ring group may be a monocyclic ring or a fused ring. Examples of the aromatic hydrocarbon ring group include a benzene ring, a naphthalene ring, a pentalene ring, an indene ring, an azulene ring, and a heptalene ring, each of which has one free valence.

The aromatic heterocyclic ring in the aromatic heterocyclic group may be a monocyclic ring or a fused ring. Examples of the aromatic heterocyclic group include a furan ring, a thiophene ring, a pyrrole ring, a 2H-pyran ring, a 4H-thiopyran ring, a pyridine ring, a 1,3-oxazole ring, an isoxazole ring, a 1,3-thiazole ring, an isothiazole ring, an imidazole ring, a pyrazole ring, a furazan ring, a pyrazine ring, a pyrimidine ring, a pyridazine ring, a 1,3,5-triazine ring, a benzofuran ring, a 2-benzofuran ring, a benzothiophene ring, a 2-benzothiophene ring, a 1H-pyrrolidine ring, an indole ring, an isoindole ring, an indolizine ring, a 2H-1-benzopyran ring, a 1H-2-benzopyran ring, a quinoline ring, an isoquinoline ring, a 4H-quinolidine ring, a benzimidazole ring, a 1H-indazole ring, a quinoxaline ring, a quinazoline ring, a cinnoline ring, a phthalazine ring, a 1,8-naphthyridine ring, a purine ring, and a pteridine ring, each of which has one free valence.

When the benzene ring in Formula (4) has any substituent, the number of substituents is not particularly limited, but from the viewpoint that the dye molecules are π-π stacked to improve heat resistance and a decrease in luminance due to the decomposition of the dye is suppressed, it is preferable that the number of substituents is 1 with respect to one benzene ring.

When the benzene ring in Formula (4) has any substituent, the substitution position may be the o-position, the m-position, or the p-position, but from the viewpoint that the stacking of the highest density structure is enabled, the p-position is preferable.

One or more of R¹ to R¹⁶ each represent the group represented by Formula (4). From the viewpoints of a solubility in an organic solvent and a luminance, it is preferable that one or more of R¹ to R⁴ are each the group represented by Formula (4), one or more of R⁵ to R⁸ are each the group represented by Formula (4), one or more of R⁹ to R¹² are each the group represented by Formula (4), and one or more of R¹³ to R¹⁶ are each the group represented by Formula (4), and it is more preferable that two or more of R¹ to R⁴ are each the group represented by Formula (4), two or more of R⁵ to R¹ are each the group represented by Formula (4), two or more of R⁹ to R¹² are each the group represented by Formula (4), and two or more of R¹³ to R¹⁶ are each the group represented by Formula (4).

In particular, from the viewpoint that a decrease in luminance is suppressed by efficient stacking, it is particularly preferable that R², R³, R⁶, R⁷, R¹⁰, R¹¹, R¹⁴, and R¹⁵ are each the group represented by Formula (4), and R¹, R⁴, R⁵, R⁸, R⁹, R¹², R¹³, and R¹⁶ are each a halogen atom.

Specific examples of the phthalocyanine compound (3) include the following compounds.

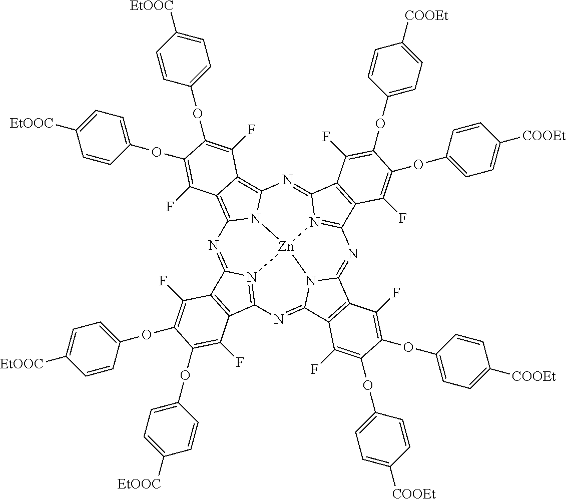

In the formula, Et represents ethyl.

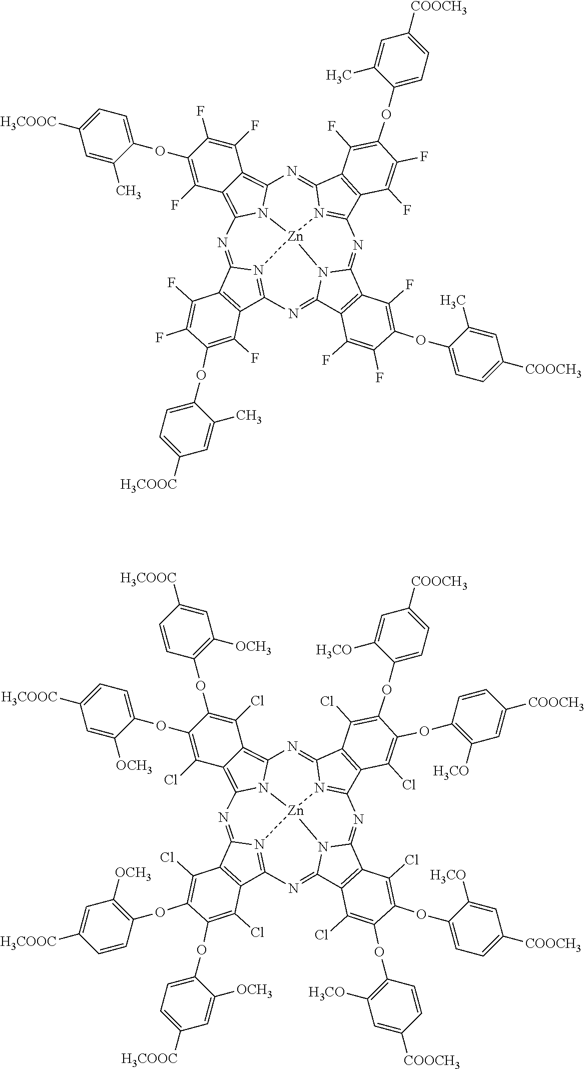

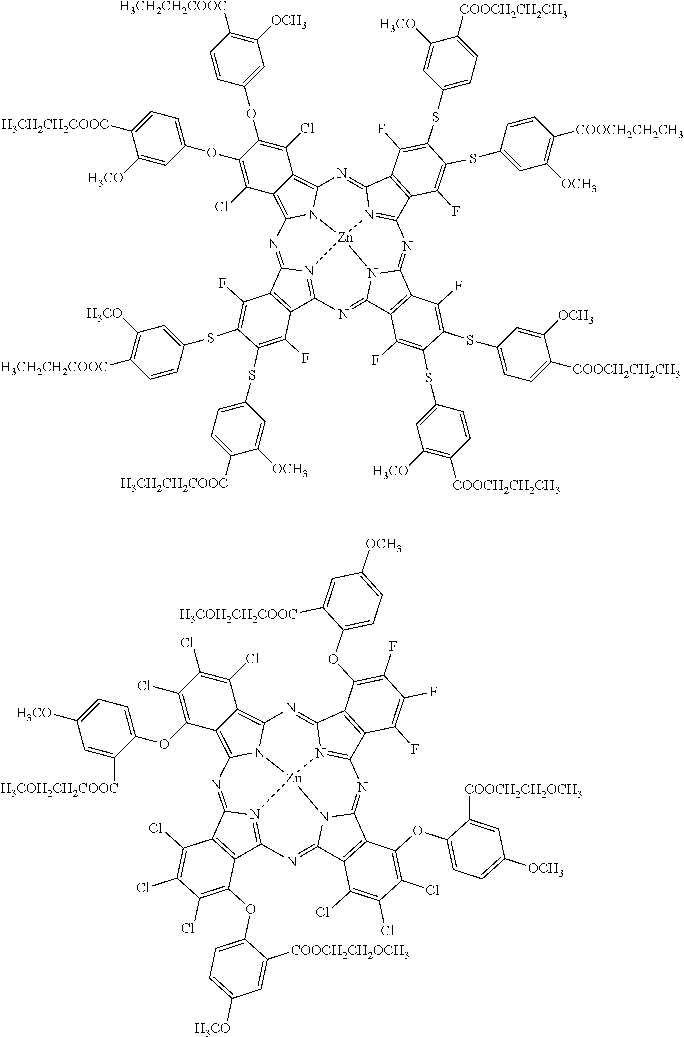

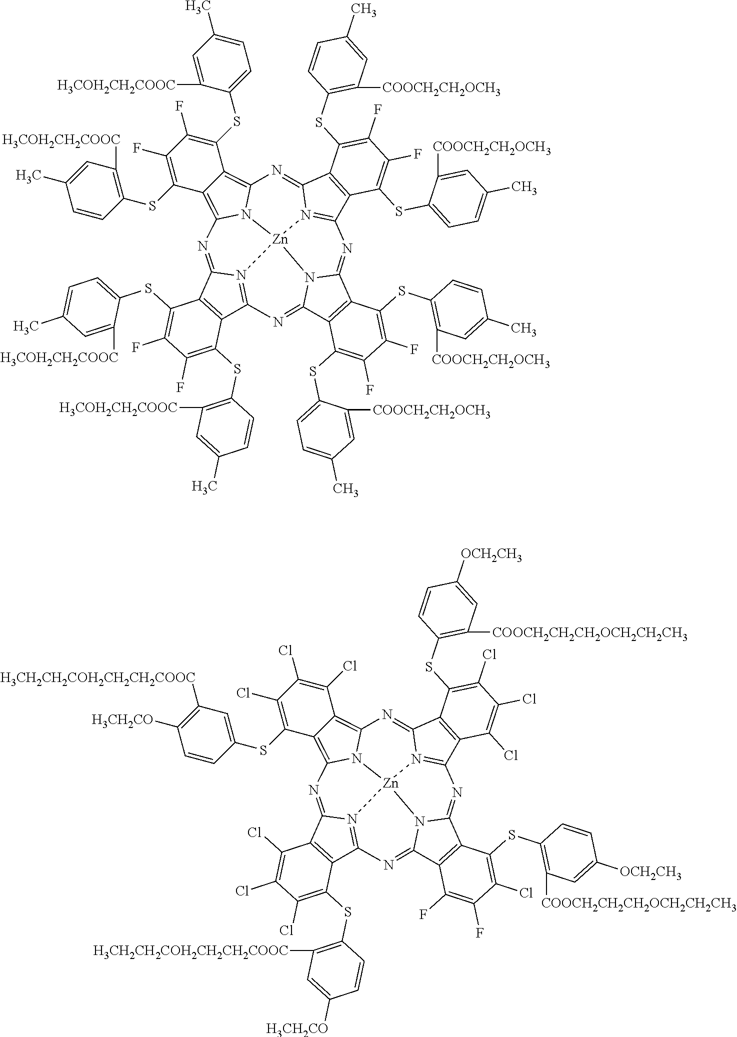

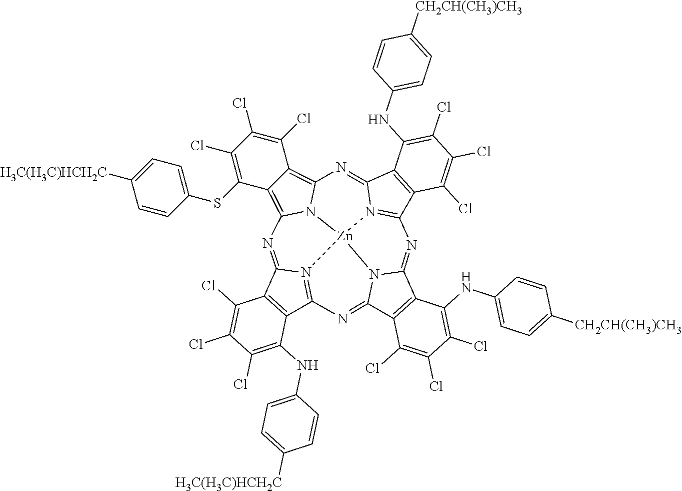

As a method for producing the phthalocyanine compound (3), a known method can be employed, and for example, the method described in Japanese Unexamined Patent Application, First Publication No. H05-345861 can be employed.

### Content Proportion of Colorant (a2) in Colored Resin Composition

The colorant (a2) can be contained at a content proportion of preferably 0.01% by mass or more, more preferably 0.1% by mass or more, still more preferably 1% by mass or more, even still preferably 5% by mass or more, and particularly preferably 8% by mass or more, and preferably 70% by mass or less, more preferably 40% by mass or less, still more preferably 30% by mass or less, and particularly preferably 20% by mass or less, in a total solid content of the colored resin composition of the second aspect. When the content proportion is the upper limit value or less, there is a tendency that the curability of a coating film is less likely to be deteriorated and a film strength is sufficient, which is thus preferable. In addition, when the content proportion is the lower limit value or more, a coloring power is sufficient, a chromaticity having a desired concentration can be easily obtained, and a film thickness is less likely to be increased, which is thus preferable.

The above-described upper limits and lower limits can be combined in any manner. For example, the content proportion is preferably 0.01% to 70% by mass, more preferably 0.1% to 70% by mass, still more preferably 1% to 40% by mass, even still more preferably 5% to 30% by mass, and particularly preferably 8% to 20% by mass.

### Content Proportion of Compound Represented by Formula (3) in Colored Resin Composition

The colored resin composition of the second aspect may include only one kind of the compound represented by Formula (3) as the colorant (a2) or may include two or more kinds of the compounds.

The compound represented by Formula (3) can be contained at a content proportion of preferably 0.01% by mass or more, more preferably 0.1% by mass or more, still more preferably 1% by mass or more, even still preferably 5% by mass or more, and particularly preferably 8% by mass or more, and preferably 70% by mass or less, more preferably 40% by mass or less, still more preferably 30% by mass or less, and particularly preferably 20% by mass or less, in a total solid content of the colored resin composition of the second aspect. When the content proportion is the upper limit value or less, there is a tendency that the curability of a coating film is less likely to be deteriorated and a film strength is sufficient, which is thus preferable. In addition, when the content proportion is the lower limit value or more, a coloring power is sufficient, a chromaticity having a desired concentration can be easily obtained, and a film thickness is less likely to be increased, which is thus preferable.

The above-described upper limits and lower limits can be combined in any manner. For example, the content proportion is preferably 0.01% to 70% by mass, more preferably 0.1% to 70% by mass, still more preferably 1% to 40% by mass, even still more preferably 5% to 30% by mass, and particularly preferably 8% to 20% by mass. 1-1-3 Colorant (a3) Included in Colorant (A) in Colored Resin Composition of Third Aspect

By allowing the colorant (A) in the colored resin composition of the third aspect to contain a colorant (a3) having a light absorption maximum at wavelength range of 430 to 570 nm in a wavelength range of 400 and 900 nm, there is a tendency that a color filter having excellent transparency of red light is obtained.

The colorant (a3) is not particularly limited as long as it is a colorant having a light absorption maximum at a wavelength range of 430 to 570 nm in a wavelength range of 400 and 900 nm. The colorant (a3) is preferably a dihydropyrrolopyrrole dione compound represented by General Formula (5) (hereinafter also referred to as a “dihydropyrrolopyrrole dione compound (5)”), and the colorant (A) in the colored resin composition of the third aspect preferably contains at least one or more dihydropyrrolopyrrole dione compounds (5) having a light absorption maximum at a wavelength range of 430 to 570 nm in a wavelength range of 400 and 900 nm. By allowing the composition to contain the dihydropyrrolopyrrole dione compound (5), red light in a visible region can be selectively transmitted, and by further combining a near-infrared absorbing compound therewith, there is a tendency that a color filter which selectively transmits only red light in a visible region through a near-infrared region is obtained.

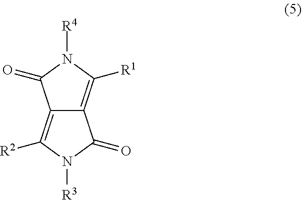

In Formula (5), R¹ to R⁴ each independently represent a hydrogen atom, an alkyl group which may have a substituent, or an aryl group which may have a substituent.

Examples of the alkyl group as R¹ to R⁴ in Formula (5) include a methyl group, an ethyl group, an n-propyl group, and an isopropyl group. Examples of the substituent that the alkyl group may have include a halogen atom such as fluorine, chlorine, bromine, and iodine, and an aryl group.

Examples of the aryl group as R¹ to R⁴ in Formula (5) include a phenyl group, a naphthyl group, a pyrrole group, and a thiophene group. Examples of the substituent that the aryl group may have include a halogen atom such as fluorine, chlorine, bromine, and iodine, and an alkyl group.

Examples of the dihydropyrrolopyrrole dione compound (5) include the following compounds.

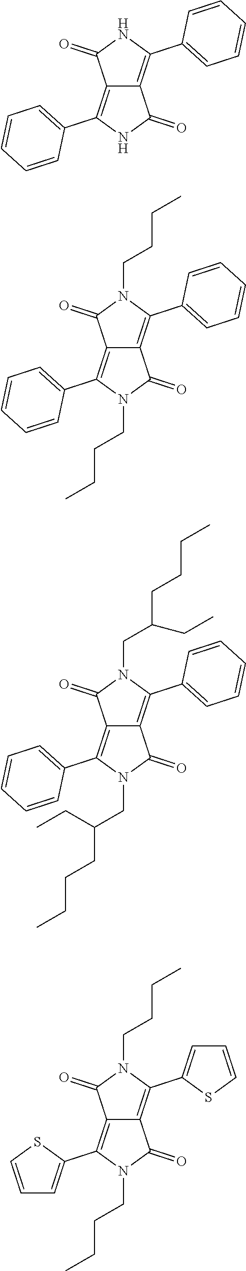 [SMILES: O=C1NC(c2ccccc2)=C2C(=O)NC(c3ccccc3)=C12 ; CCCCN1C(=O)C2=C(c3ccccc3)N(CCCC)C(=O)C2=C1c1ccccc1 ; CCCCC(CC)CN1C(=O)C2=C(c3ccccc3)N(CC(CC)CCCC)C(=O)C2=C1c1ccccc1 ; CCCCN1C(=O)C2=C(c3cccs3)N(CCCC)C(=O)C2=C1c1cccs1]

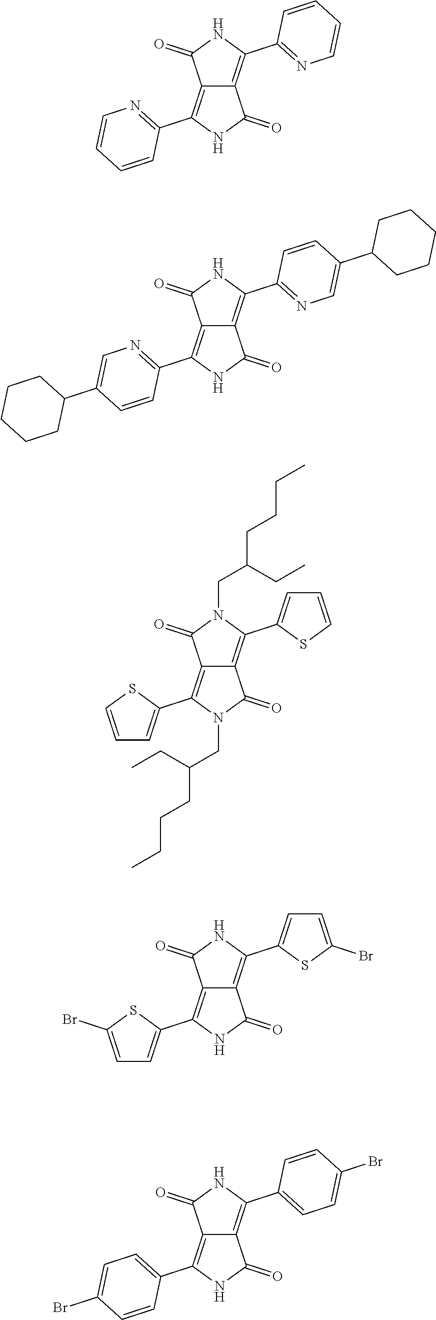 [SMILES: O=C1NC(c2ccccn2)=C2C(=O)NC(c3ccccn3)=C12 ; O=C1NC(c2ccc(C3CCCCC3)cn2)=C2C(=O)NC(c3ccc(C4CCCCC4)cn3)=C12 ; CCCCC(CC)CN1C(=O)C2=C(c3cccs3)N(CC(CC)CCCC)C(=O)C2=C1c1cccs1 ; O=C1NC(c2ccc(Br)s2)=C2C(=O)NC(c3ccc(Br)s3)=C12 ; O=C1NC(c2ccc(Br)cc2)=C2C(=O)NC(c3ccc(Br)cc3)=C12]

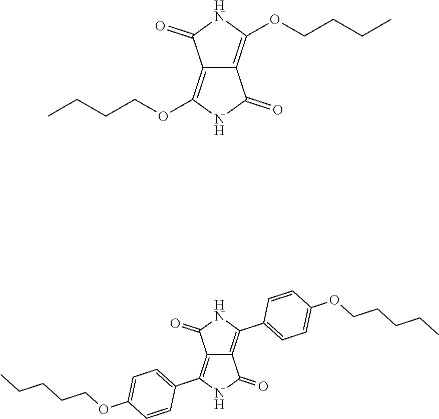

From the viewpoint of light absorption characteristics and light stability, it is desirable that the dihydropyrrolopyrrole dione compound represented by Formula (5) is a dihydropyrrolopyrrole dione compound represented by General Formula (6).

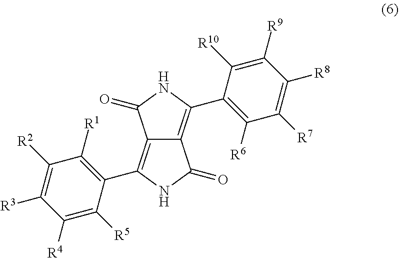

In Formula (6), R¹ to R¹⁰ each independently represent a hydrogen atom, a halogen atom, or an alkyl group. It should be noted that one or more of R¹ to R⁵ each represent a halogen atom, and one or more of R⁶ to R¹⁰ each represent a halogen atom.

In Formula (6), one or more of R¹ to R⁵ each represent a halogen atom, and one or more of R⁶ to R¹⁰ each represent a halogen atom. Examples of the halogen atom for R¹ to R¹⁰ include fluorine, chlorine, bromine, and iodine, and chlorine is preferable.

The alkyl group for R¹ to R¹⁰ may be either linear or branched. The alkyl group preferably has 1 to 4 carbon atoms, and specific examples thereof include a methyl group, an ethyl group, a propyl group, an isopropyl group, a butyl group, an isobutyl group, a sec-butyl group, and a tert-butyl group.

From the viewpoint of light absorption characteristics, R¹ to R¹⁰ are each independently preferably the hydrogen atom or the halogen atom, R³ and R⁸ are each more preferably the halogen atom, and R³ and R¹ are each still more preferably chlorine.

Examples of such a compound include a compound represented by General Formula (7).

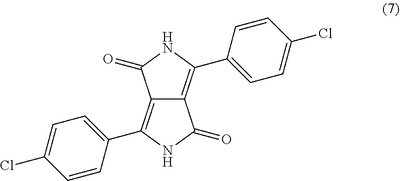

As a method for producing the dihydropyrrolopyrrole dione compound (5), a known method can be employed, and for example, the method described in Japanese Patent No. 6846739 can be employed.

### Content Proportion of Colorant (a3) in Colored Resin Composition

The colorant (a3) can be contained at a content proportion of preferably 0.01% by mass or more, more preferably 0.1% by mass or more, still more preferably 1% by mass or more, even still preferably 5% by mass or more, and particularly preferably 8% by mass or more, and preferably 70% by mass or less, more preferably 40% by mass or less, still more preferably 30% by mass or less, and particularly preferably 20% by mass or less, in a total solid content of the colored resin composition of the third aspect. When the content proportion is the upper limit value or less, there is a tendency that the curability of a coating film is less likely to be deteriorated and a film strength is sufficient, which is thus preferable. In addition, when the content proportion is the lower limit value or more, a coloring power is sufficient, a chromaticity having a desired concentration can be easily obtained, and a film thickness is less likely to be increased, which is thus preferable.

The above-described upper limits and lower limits can be combined in any manner. For example, the content proportion is preferably 0.01% to 70% by mass, more preferably 0.1% to 70% by mass, still more preferably 1% to 40% by mass, even still more preferably 5% to 30% by mass, and particularly preferably 8% to 20% by mass.

### Content Proportion of Compound Represented by Formula (5) in Colored Resin Composition

The colored resin composition of the third aspect may include only one kind of the compound represented by Formula (5) as the colorant (a3) or may include two or more kinds of the compounds.

The compound represented by Formula (5) can be contained at a content proportion of preferably 0.01% by mass or more, more preferably 0.1% by mass or more, still more preferably 1% by mass or more, even still preferably 5% by mass or more, and particularly preferably 8% by mass or more, and preferably 70% by mass or less, more preferably 40% by mass or less, still more preferably 30% by mass or less, and particularly preferably 20% by mass or less, in a total solid content of the colored resin composition of the third aspect. When the content proportion is the upper limit value or less, there is a tendency that the curability of a coating film is less likely to be deteriorated and a film strength is sufficient, which is thus preferable. In addition, when the content proportion is the lower limit value or more, a coloring power is sufficient, a chromaticity having a desired concentration can be easily obtained, and a film thickness is less likely to be increased, which is thus preferable.

The above-described upper limits and lower limits can be combined in any manner. For example, the content proportion is preferably 0.01% to 70% by mass, more preferably 0.1% to 70% by mass, still more preferably 1% to 40% by mass, even still more preferably 5% to 30% by mass, and particularly preferably 8% to 20% by mass. 1-1-4 Compound of Formula (8) Included in Colorant (A) in Colored Resin Composition of Fourth Aspect and Fifth Aspect

The colorant (A) in the colored resin composition of the fourth aspect and the fifth aspect contains a compound represented by General Formula (8). It is preferable that the colorant (A) in the colored resin composition of the fourth aspect and the fifth aspect contains the compound represented by General Formula (8), which has a light absorption maximum value in a wavelength range of 370 to 650 nm.

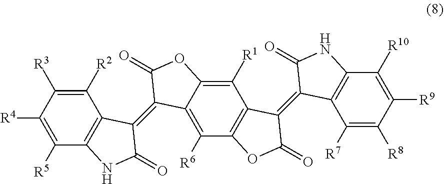

In Formula (8), R¹ and R⁶ each independently represent a hydrogen atom, CH₃, CF₃, a fluorine atom, or a chlorine atom,
R², R³, R⁴, R⁵, R⁷, R⁸, R⁹, and R¹⁰ each independently represent a hydrogen atom, a halogen atom, R¹¹, COOH, COOR¹¹, COO⁻, CONH₂, CONHR¹¹, CONR¹¹R¹², CN, OH, OR¹¹, COCR¹¹, OOCNH₂, OOCNHR¹¹, OOCNR¹¹R¹², NO₂, NH₂, NHR¹¹, NR¹¹R¹², NR¹¹COR¹², NR¹¹COR¹², N═CH₂, N═CHR¹¹, N═CR¹¹R¹², SH, SR¹¹, SOR¹¹, SO₂R¹¹, SO₃R¹¹, SO₃H, SO₃⁻, SO₂NH₂, SO₂NHR¹¹, or SO₂NR¹¹R¹²,
at least one combination selected from the group consisting of R² and R³, R³ and R⁴, R⁴ and R¹, R⁷ and R⁸, R⁸ and R⁹, and R⁹ and R¹¹ may be directly bonded to each other or may be bonded to each other through an oxygen atom, a sulfur atom, NH, or an NR¹¹ bridge, and
R¹¹ and R¹² each independently represent an alkyl group having 1 to 12 carbon atoms, a cycloalkyl group having 3 to 12 carbon atoms, an alkenyl group having 2 to 12 carbon atoms, a cycloalkenyl group having 3 to 12 carbon atoms, or an alkynyl group having 2 to 12 carbon atoms.

Furthermore, the compound represented by Formula (8) (which may be hereinafter referred to as a “compound (8)”) in the present specification can be treated as a notion that encompasses, in addition to the compound represented by Formula (8), a geometric isomer of the compound (8), a salt of the compound (8), and a salt of the geometric isomer of the compound (8).

The compound (8) and the geometric isomer of the compound (8) have the following core structure (provided that the substituent in the structural formula is omitted), and a trans-trans isomer thereof is presumably the most stable.

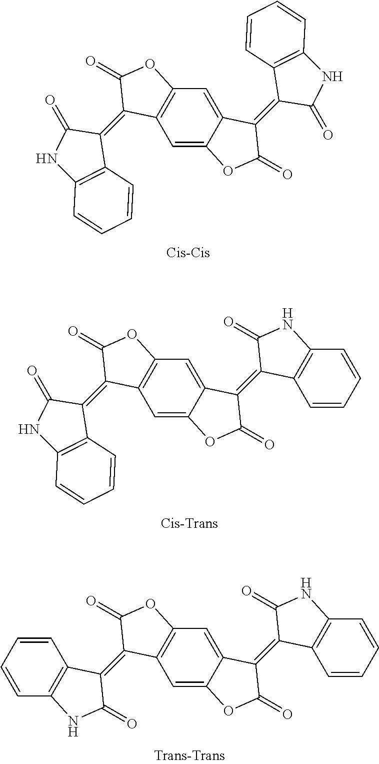 [SMILES: O=C1Nc2ccccc2/C1=C1/C(=O)Oc2cc3c(cc21)OC(=O)/C3=C1\C(=O)Nc2ccccc21 ; O=C1Nc2ccccc2/C1=C1/C(=O)Oc2cc3c(cc21)OC(=O)/C3=C1/C(=O)Nc2ccccc21 ; O=C1Nc2ccccc2/C1=C1\C(=O)Oc2cc3c(cc21)OC(=O)/C3=C1/C(=O)Nc2ccccc21]

When the compound (8) is anionic, the compound (8) is preferably a salt that is charged with any known suitable cation, for example, a metal, an organic, an inorganic or metal organic cation, specifically an alkali metal, an alkaline earth metal, a transition metal, a primary ammonium, a secondary ammonium, a tertiary ammonium such as a trialkylammonium, a quaternary ammonium such as a tetraalkylammonium, or an organometallic complex. In addition, when the geometric isomer of the compound (8) is anionic, it is preferably the same salt.

In the substituents and definitions thereof in Formula (8), the following are preferable since there is a tendency that the shielding rate is increased. This is because it is considered that the following substituents have no absorption and do not affect a color phase of the colorant.
R², R⁴, R⁵, R⁷, R⁹, and R¹⁰ are each independently preferably the hydrogen atom, the fluorine atom, or the chlorine atom, and more preferably the hydrogen atom.
R³ and R⁸ each independently preferably the hydrogen atom, NO₂, OCH₃, OC₂H₅, a bromine atom, a chlorine atom, CH₃, C₂H₅, N(CH₃)₂, N(CH₃)(C₂H₅), N(C₂H₅)₂, α-naphthyl, β-naphthyl, SO₃H, or SO₃⁻, more preferably the hydrogen atom or SO₃H, and particularly preferably the hydrogen atom.
R¹ and R⁶ are each independently preferably the hydrogen atom, CH₃, or CF₃, and more preferably the hydrogen atom.

It is preferable that at least one combination selected from the group consisting of R¹ and R⁶, R² and R⁷, R³ and R¹, R⁴ and R⁹, and R⁵ and R¹⁰ is the same, and it is more preferable that R¹ is the same as R⁶, R² is the same as R⁷, R³ is the same as R¹, R⁴ is the same as R⁹, and R⁵ is the same as R¹⁰.

The alkyl group having 1 to 12 carbon atoms is, for example, a methyl group, an ethyl group, an n-propyl group, an isopropyl group, an n-butyl group, a sec-butyl group, an isobutyl group, a tert-butyl group, a 2-methylbutyl group, an n a-pentyl group, a 2-pentyl group, a 3-pentyl group, a 2,2-dimethylpropyl group, an n-hexyl group, an n-heptyl group, an n-octyl group, a 1,1,3,3-tetramethylbutyl group, a 2-ethylhexyl group, a nonyl group, a decyl group, an undecyl group, or a dodecyl group.

The cycloalkyl group having 3 to 12 carbon atoms is, for example, a cyclopropyl group, a cyclopropylmethyl group, a cyclobutyl group, a cyclopentyl group, a cyclohexyl group, a cyclohexylmethyl group, a trimethylcyclohexyl group, a thujyl group, a norbornyl group, a bornyl group, a norcaryl group, a caryl group, a menthyl group, a norpynyl group, a pynyl group, an adamantan-1-yl group, or an adamantan-2-yl group.

The alkenyl group having 2 to 12 carbon atoms is, for example, a vinyl group, an allyl group, a 2-propen-2-yl group, a 2-buten-1-yl group, a 3-buten-1-yl group, a 1,3-butadien-2-yl group, a 2-penten-1-yl group, a 3-penten-2-yl group, a 2-menthyl-1-buten-3-yl group, a 2-methyl-3-buten-2-yl group, a 3-methyl-2-buten-1-yl group, a 1,4-pentadien-3-yl group, a hexenyl group, an octenyl group, a nonenenyl group, a decenyl group, or a dodecenyl group.

The cycloalkenyl group having 3 to 12 carbon atoms is, for example, a 2-cyclobuten-1-yl group, a 2-cyclopenten-1-yl group, a 2-cyclohexen-1-yl group, a 3-cyclohexen-1-yl group, a 2,4-cyclohexadien-1-yl group, a 1-p-menthen-8-yl group, a 4(10)-thujen-10-yl group, a 2-norbornen-1-yl group, a 2,5-norbornadien-1-yl group, a 7,7-dimethyl-2,4-norcaradien-3-yl group, or a camphenyl group.

The alkynyl group having 2 to 12 carbon atom is, for example, a 1-propyn-3-yl group, a 1-butyn-4-yl group, a 1-pentyn-5-yl group, a 2-methyl-3-butyn-2-yl group, a 1,4-pentadiyn-3-yl group, a 1,3-pentadiyn-5-yl group, a 1-hexyn-6-yl group, a cis-3-methyl-2-penten-4-yn-1-yl group, a trans-3-methyl-2-penten-4-yn-1-yl group, a 1,3-hexadiyn-5-yl group, a 1-octyn-8-yl group, a 1-nonyn-9-yl group, a 1-decyn-10-yl group, or a 1-dodecyn-12-yl group.

The halogen atom is, for example, a fluorine atom, a chlorine atom, a bromine atom, or an iodine atom.

The compound (8) is preferably an organic black pigment including at least one selected from the group consisting of a compound represented by the following formula and a geometric isomer of the compound represented by the following formula.

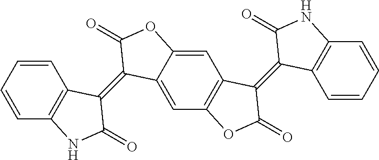 [SMILES: O=C1Nc2ccccc2/C1=C1\C(=O)Oc2cc3c(cc21)OC(=O)/C3=C1/C(=O)Nc2ccccc21]

Examples of such a compound include a product name Irgaphor (registered trademark) Black S0100 CF (manufactured by BASF SE).

The compound is preferably used in a state of being dispersed by a dispersant, a solvent, and a method, which will be described later. When a sulfonic acid derivative of the compound (8), in particular, a sulfonic acid derivative of the compound represented by the formula, is present at the time of dispersing, the dispersibility and the storage stability may be improved. Therefore, it is preferable that the sulfonic acid derivative is included.

### Content Proportion of Compound Represented by Formula (8) in Colored Resin Composition

The colored resin compositions of the fourth aspect and the fifth aspect may include only one kind of the compound represented by Formula (8) as the colorant (A), or may include two or more kinds thereof.

The compound represented by Formula (8) can be contained at a content proportion of preferably 0.01% by mass or more, more preferably 0.1% by mass or more, still more preferably 1% by mass or more, even still preferably 5% by mass or more, and particularly preferably 8% by mass or more, and preferably 70% by mass or less, more preferably 40% by mass or less, still more preferably 30% by mass or less, and particularly preferably 20% by mass or less, in a total solid content of the colored resin composition. When the content proportion is the upper limit value or less, there is a tendency that the curability of a coating film is less likely to be deteriorated and a film strength is sufficient, which is thus preferable. In addition, when the content proportion is the lower limit value or more, a coloring power is sufficient, a chromaticity having a desired concentration can be easily obtained, and a film thickness is less likely to be increased, which is thus preferable.

The above-described upper limits and lower limits can be combined in any manner. For example, the content proportion is preferably 0.01% to 70% by mass, more preferably 0.1% to 70% by mass, still more preferably 1% to 40% by mass, even still more preferably 5% to 30% by mass, and particularly preferably 8% to 20% by mass. 1-1-5 Near-Infrared Absorbing Compound

The colorants (A) in the colored resin compositions according to the first aspect, the second aspect, the third aspect, the fourth aspect, and the fifth aspect each contain a near-infrared absorbing compound, in addition to the above-mentioned compound. It is preferable that the near-infrared absorbing compound contains at least one or more compounds selected from the group consisting of a cyanine-based compound, a merocyanine-based compound, a squarylium-based compound, a phthalocyanine-based compound, a diimmonium-based compound, and a diketopyrrolopyrrole-based compound.

The colored resin composition of the fourth aspect contains a near-infrared absorbing compound having a light absorption maximum value in a wavelength range of 790 to 830 nm in a wavelength range of 400 and 900 nm, and as the near-infrared absorbing compound according to the fourth aspect, the above-described near-infrared absorbing compound is preferable.

In addition, the colored resin composition of the fifth aspect contains a near-infrared absorbing compound having a light absorption maximum value in a wavelength range of 720 to 780 nm in a wavelength range of 400 and 900 nm, and as the near-infrared absorbing compound according to the fifth aspect, the above-described near-infrared absorbing compound is preferable.

The colorants (A) in the colored resin compositions according to the first aspect, the second aspect, and the third aspect each preferably contain, in addition to the compounds, a near-infrared absorbing compound having a light absorption maximum value in a wavelength range of 720 to 780 nm and a wavelength range of 820 to 880 nm, and as the near-infrared absorbing compounds in the first aspect, the second aspect, and the third aspect, the above-described near-infrared absorbing compound is preferable.

In the present invention, when near-infrared absorbing compounds having a light absorption maximum value in a wavelength range of 720 to 780 nm and a wavelength range of 820 to 880 nm are referred,
(i) the compound may be, as a single compound, at least one or more near-infrared absorbing compounds selected from the group consisting of a cyanine-based compound, a merocyanine-based compound, a squarylium-based compound, a phthalocyanine-based compound, a diimmonium-based compound, and a diketopyrrolopyrrole-based compound, having light absorption maximum values in a wavelength range of 720 to 780 nm and a wavelength range of 820 to 880 nm, and
(ii) the compound may be a combination with at least one or more near-infrared absorbing compounds selected from the group consisting of a cyanine-based compound, a merocyanine-based compound, a squarylium-based compound, a phthalocyanine-based compound, a diimmonium-based compound, and a diketopyrrolopyrrole-based compound, each having a light absorption maximum value in a wavelength range of 720 to 780 nm, and at least one or more near-infrared absorbing compounds selected from the group consisting of a cyanine-based compound, a merocyanine-based compound, a squarylium-based compound, a phthalocyanine-based compound, a diimmonium-based compound, and a diketopyrrolopyrrole-based compound, each having a light absorption maximum value in a wavelength range of 820 to 880 nm.

Examples of the cyanine-based compound, the merocyanine-based compound, the squarylium-based compound, the phthalocyanine-based compound, the diimmonium-based compound, and the diketopyrrolopyrrole-based compound include the following compounds.

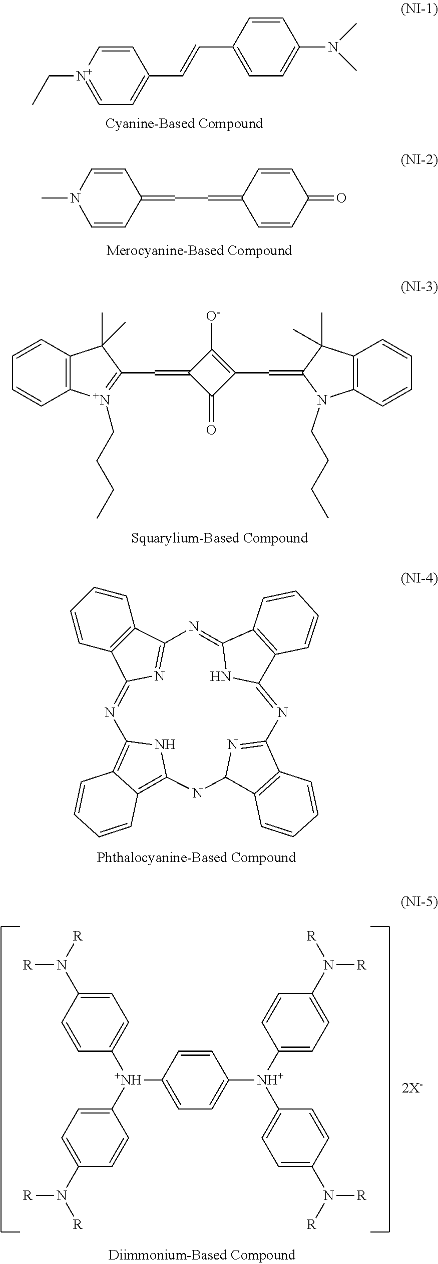

In Formula (NI-5), R's each independently represent an alkyl group or an aryl group. X⁻ represents a monovalent anion.

In Formula (NI-5), examples of the alkyl group for R include a methyl group, an ethyl group, an n-propyl group, and an isopropyl group. Examples of the aryl group include a phenyl group and a naphthyl group.

Examples of the monovalent anion for X⁻ include halogen ions such as a chlorine ion (Cl⁻), a bromine ion (Br⁻), and an iodine ion (I⁻), a tetrafluoroborone ion (BF₄⁻), a hexafluorophosphate ion (PF₆⁻), and a trifluorosulfate ion (CF₃SO₄⁻).

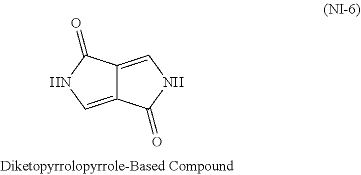

The structures of the near-infrared absorbing compounds that are exemplary examples mentioned in Formulae (NI-1) to (NI-6) may include similar structures.

As the cyanine-based compound, for example, a compound represented by General Formula (NI-7) is preferable.

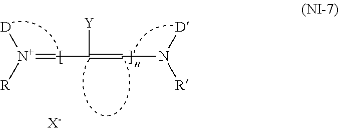

In Formula (NI-7), D and D′ each independently represent —CH═CH—, O, S, Se, or N. A carbon atom adjacent to D or D′, a nitrogen atom adjacent to D or D′, and a nitrogen atom adjacent to D or D′ (carbon atom connected to D or D′ by a dotted line) in Formula (NI-7) is closed by a hydrocarbon chain which may include a double bond. R and R′ each independently represent an alkyl group or an aralkyl group. Y represents any substituent. A ring structure of a broken line part (---) may be present in the repeating portion (on the methine chain). n is any integer. X⁻ represents a monovalent anion.

From the viewpoint of the transparency, the sensitizing properties, and the stability in a visible region, the repeating portion (on the methine chain) preferably includes any substituent Y and a ring structure represented by a broken line part (---), and as the substituent Y, a hydrogen atom, a halogen atom, or an aromatic group having a halogen atom is preferable. n can be adjusted according to a desired absorption wavelength, and is preferably an integer of 0 to 5.

Examples of the monovalent anion for X⁻ include halogen ions such as a chlorine ion (Cl⁻), a bromine ion (Br⁻), and an iodine ion (I⁻), and compound ions such as a tetrafluoroborate ion (BF₄⁻), a hexafluorophosphate ion (PF₆⁻), and a trifluorosulfate ion (CF₃SO₄⁻). From the viewpoint of light resistance and heat resistance, monovalent ions having a large ion radius such as the iodine ion (I) the tetrafluoroborate ion (BF₄⁻), the hexafluorophosphate ion (PF₆⁻), and the trifluorosulfate ion (CF₃SO₄⁻) are preferable.

In the cyanine-based compound represented by Formula (N1-7), a structure which is desirable from the viewpoint of reducing a maximum absorption wavelength of a near-infrared region at optical wavelengths of 700 nm to 900 nm and a half-width thereof, and a visible light transmittance is determined. The maximum absorption wavelength in the near-infrared range is determined by the number of double bonds and single bonds between the nitrogen atoms (N) at both ends in Formula (N1-7). When the number of double bonds and single bonds is large, the maximum absorption wavelength is shifted to the long wavelength side. On the other hand, when the number of double bonds and single bonds is small, the maximum absorption wavelength is shifted to the short wavelength side. In addition, the structure of the double bonds and the single bonds may be fixed by a closed ring structure of a 5-membered ring or a 6-membered ring. As a specific example, the number of double bonds and single bonds can be increased as shown in the following general formulae.

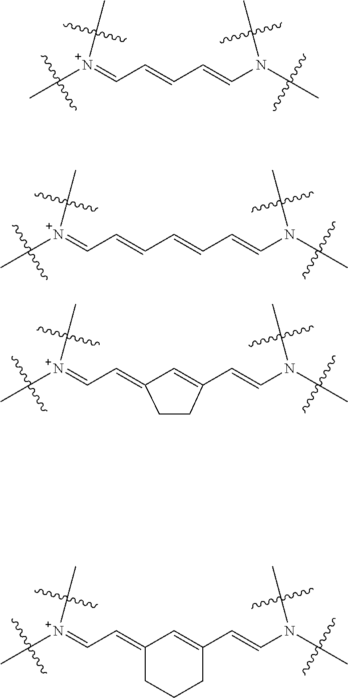

In addition, the maximum absorption wavelength in the near-infrared range can also be adjusted by the heteroaromatic structure at both ends including the nitrogen atom (N) at both ends in Formula (N1-7). Generally, when the heteroaromatic structure at both ends is made bulky, the electron-donating property from both ends is strengthened, and thus, the maximum absorption wavelength is shifted to the long wavelength side. Specific examples of the heteroaromatic structure include structures represented by the following general formulae.

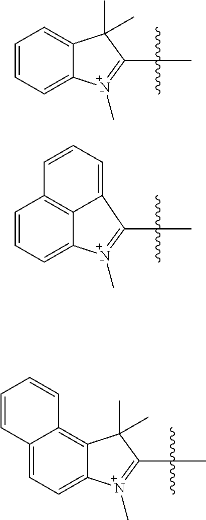

Furthermore, it is desirable that the maximum absorption wavelength in the near-infrared range includes an electron-accepting group between the double bond and the single bond between the nitrogen atoms (N) at both ends in Formula (N1-7). Specific examples thereof include structures represented by the following general formulae, such as halogen ions of a chlorine atom, a bromine atom, and the like, a phenyl group, and a fluorophenyl group.

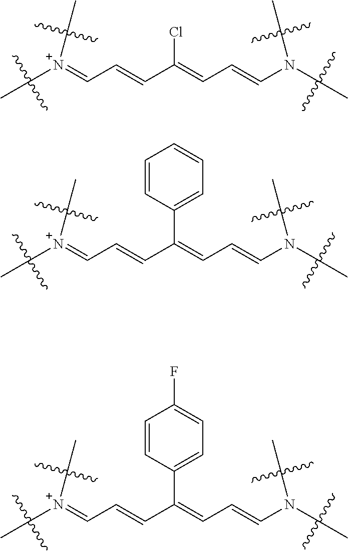

Examples of the cyanine-based compound having a maximum absorption wavelength of a near-infrared region at optical wavelengths of 700 nm to 900 nm include structures represented by General Formulae (NI-8) to (NI-11).

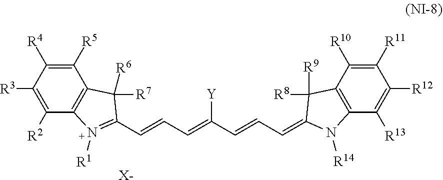

R¹ to R¹⁴ in Formula (NI-8) each independently represent a hydrogen atom, an alkyl group which may have a substituent, or an aryl group which may have a substituent. Y represents a hydrogen atom or an electron-accepting group. X⁻ is a monovalent anion.

Examples of the alkyl group as R¹ to R¹⁴ in Formula (NI-8) include a methyl group, an ethyl group, an n-propyl group, and an isopropyl group. Examples of the aryl group include a phenyl group and a naphthyl group.

Examples of the substituent that the alkyl group or the aryl group may have include a halogen atom such as a fluorine atom, a chlorine atom, a bromine atom, and an iodine atom, a carboxy group, a hydroxy group, an acetyl group, a nitro group, an amino group, and an alkyl group including a double bond, such as a vinyl group.

Examples of the electron-accepting group in Y include a halogen atom and a phenyl group which may have a substituent. Examples of the halogen atom include a chlorine atom and a bromine atom, and examples of the phenyl group which may have a substituent include a phenyl group and a fluorophenyl group.

As the monovalent anion for X⁻, an ion having a large ion radius is preferable, and examples thereof include an iodine ion (I⁻), a tetrafluoroborate ion (BF₄⁻), a hexafluorophosphate ion (PF₆⁻), and a trifluorosulfate ion (CF₃SO₄⁻).

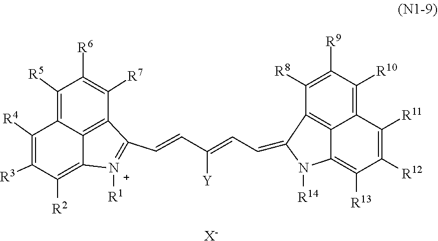

R¹ to R¹⁴, Y, and X⁻ in Formula (NI-9) each have the same definitions as R¹ to R¹⁴, Y, and X⁻ in Formula (NI-8).

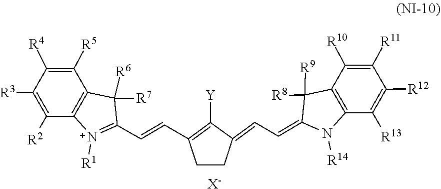

R¹ to R¹⁴, Y, and X⁻ in Formula (NI-10) each have the same definitions as R¹ to R¹⁴, Y, and X⁻ in Formula (NI-8).

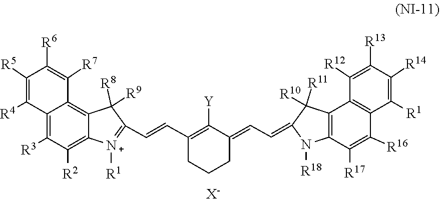

R¹ to R¹⁸ in Formula (NI-11) each independently represent a hydrogen atom, an alkyl group which may have a substituent, or an aryl group which may have a substituent. Y and X⁻ each have the same definitions as Y and X⁻ in Formula (NI-8).

Examples of the alkyl group as R¹ to R¹⁸ in Formula (NI-11) include a methyl group, an ethyl group, an n-propyl group, and an isopropyl group. Examples of the aryl group include a phenyl group and a naphthyl group.

Examples of the substituent that the alkyl group or the aryl group may have include a halogen atom such as a fluorine atom, a chlorine atom, a bromine atom, and an iodine atom, a carboxy group, a hydroxy group, an acetyl group, a nitro group, an amino group, and an alkyl group including a double bond, such as a vinyl group.

More preferred examples of the cyanine-based compound include the following compounds.

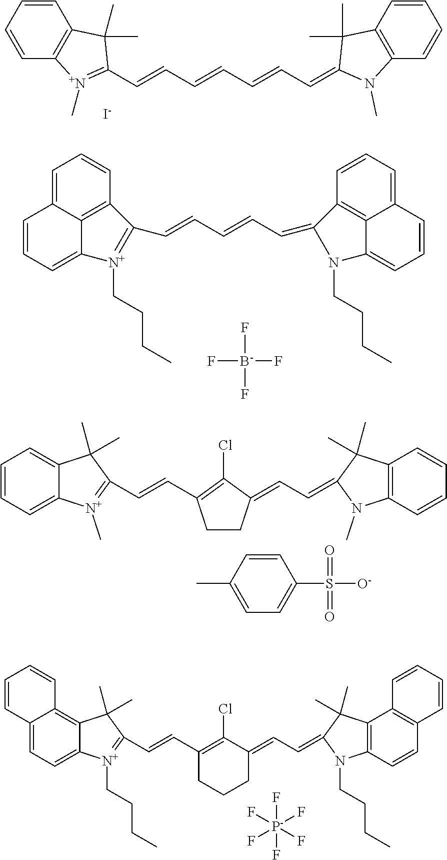

As the near-infrared absorbing compound each included in the colored resin compositions according to the first aspect, the second aspect, the third aspect, the fourth aspect, and the fifth aspect, the cyanine-based compound is more preferable, and the cyanine-based compounds represented by Formulae (NI-8) to (NI-11) are still more preferable.

As the near-infrared absorbing compound, the cyanine-based compounds may be included alone or in combination of a plurality thereof.

### 1-2 Solvent (B)

In the colored resin composition of the present invention, the solvent (B) has a function of dissolving or dispersing the colorant (A), the binder resin (C), and other components used as necessary to adjust the viscosity. Such a solvent (B) may be any solvent capable of dissolving or dispersing each component.

Examples of such a solvent include glycol monoalkyl ethers such as ethylene glycol monomethyl ether, ethylene glycol monoethyl ether, ethylene glycol monopropyl ether, ethylene glycol monobutyl ether, propylene glycol monomethyl ether, propylene glycol monoethyl ether, propylene glycol mono-n-butyl ether, propylene glycol-t-butyl ether, diethylene glycol monomethyl ether, diethylene glycol monoethyl ether, diethylene glycol mono-n-butyl ether, methoxymethyl pentanol, propylene glycol monoethyl ether, dipropylene glycol monoethyl ether, dipropylene glycol monomethyl ether, 3-methyl-3-methoxy-1-butanol, 3-methoxy-1-butanol, triethylene glycol monomethyl ether, triethylene glycol monoethyl ether, and tripropylene glycol methyl ether;
glycol dialkyl ethers such as ethylene glycol dimethyl ether, ethylene glycol diethyl ether, diethylene glycol dimethyl ether, diethylene glycol diethyl ether, diethylene glycol dipropyl ether, diethylene glycol dibutyl ether, and dipropylene glycol dimethyl ether;
glycol alkyl ether acetates such as ethylene glycol monomethyl ether acetate, ethylene glycol monoethyl ether acetate, ethylene glycol mono-n-butyl ether acetate, propylene glycol monomethyl ether acetate, propylene glycol monoethyl ether acetate, propylene glycol monopropyl ether acetate, propylene glycol monobutyl ether acetate, methoxybutyl acetate, 3-methoxybutyl acetate, methoxypentyl acetate, diethylene glycol monomethyl ether acetate, diethylene glycol monoethyl ether acetate, diethylene glycol mono-n-butyl ether acetate, dipropylene glycol monomethyl ether acetate, triethylene glycol monomethyl ether acetate, triethylene glycol monoethyl ether acetate, and 3-methyl-3-methoxybutyl acetate;
glycol diacetates such as ethylene glycol diacetate, 1,3-butylene glycol diacetate, and 1,6-hexanol diacetate;
alkyl acetates such as cyclohexanol acetate;
ethers such as amyl ether, propyl ether, diethyl ether, dipropyl ether, diisopropyl ether, butyl ether, diamyl ether, ethyl isobutyl ether, and dihexyl ether;
ketones such as acetone, methyl ethyl ketone, methyl amyl ketone, methyl isopropyl ketone, methyl isoamyl ketone, diisopropyl ketone, diisobutyl ketone, methyl isobutyl ketone, cyclohexanone, ethyl ketone, methyl butyl ketone, methylhexyl ketone, methyl nonyl ketone, and methoxymethylpentanone;
monohydric or polyhydric alcohols such as ethanol, propanol, butanol, hexanol, cyclohexanol, ethylene glycol, propylene glycol, butanediol, diethylene glycol, dipropylene glycol, triethylene glycol, methoxymethyl pentanol, glycerin, and benzyl alcohol;
aliphatic hydrocarbons such as n-pentane, n-octane, diisobutylene, n-hexane, hexene, isoprene, dipentene, and dodecane;
alicyclic hydrocarbons such as cyclohexane, methylcyclohexane, methylcyclohexene, and bicyclohexyl;
aromatic hydrocarbons such as benzene, toluene, xylene, and cumene;
chain or cyclic esters such as amyl formate, ethyl formate, ethyl acetate, butyl acetate, propyl acetate, amyl acetate, methyl isobutyrate, ethylene glycol acetate, ethyl propionate, propyl propionate, butyl butyrate, isobutyl butyrate, methyl isobutyrate, ethyl caprylate, butyl stearate, ethyl benzoate, methyl 3-ethoxypropionate, ethyl 3-ethoxypropionate, methyl 3-methoxypropionate, ethyl 3-methoxypropionate, propyl 3-methoxypropionate, butyl 3-methoxypropionate, and γ-butyrolactone;
alkoxycarboxylic acids such as 3-methoxypropionic acid and 3-ethoxypropionic acid;
halogenated hydrocarbons such as butyl chloride and amyl chloride;
ether ketones such as methoxymethylpentanone; and
nitriles such as acetonitrile and benzonitrile.

Examples of commercially available solvents include Mineral Spirits, Varsol #2, APCO #18 Solvent, APCO Thinner, Socal Solvent No. 1 and No. 2, Solvesso #150, Shell TS28 Solvent, carbitol, ethyl carbitol, butyl carbitol, methyl cellosolve, ethyl cellosolve, ethyl cellosolve acetate, methyl cellosolve acetate, and diglyme (all product names). These solvents may be used alone or in combination of two or more kinds thereof.

When a pixel of a color filter is formed by a photolithography method, a solvent having a boiling point of 100° C. to 200° C. (under the conditions of a pressure of 1,013.25 [hPa]; the same will apply hereinafter with regard to the boiling point) is preferable as the solvent (B). A solvent having a boiling point of 120° C. to 170° C. is more preferable.

From the viewpoints that a balance among coating properties, a surface tension, and the like is favorable, and the solubility of the constituent components in the composition is relatively high, glycol alkyl ether acetates are preferable.

The glycol alkyl ether acetates may be used alone or may be used in combination with another solvent. As a solvent to be used in combination with the glycol alkyl ether acetates, glycol monoalkyl ethers are particularly preferable. Among these, propylene glycol monomethyl ether is preferable from the viewpoint of the solubility of constituent components in the composition. The glycol monoalkyl ethers have a high polarity, and when the amount of the added glycol monoalkyl ethers is large, there is a tendency that a pigment is likely to aggregate and there is a reduction in storage stability, such as an increase in viscosity of the obtained colored resin composition. From the viewpoint of ensuring the storage stability, when glycol monoalkyl ethers are used in combination, the proportion of the glycol monoalkyl ethers in the solvent is preferably 5% to 30% by mass, and more preferably 5% to 20% by mass in the solvent (B) included in the colored resin composition.

In another aspect, as the solvent to be used in combination with glycol alkyl ether acetates, a solvent having a boiling point of 150° C. or higher is preferable. When the solvent having a boiling point of 150° C. or higher is used in combination, the colored resin composition is less likely to dry and there is an effect of making it less likely for the inter-relationship of a pigment dispersion to be broken due to rapid drying. When the solvent having a boiling point of 150° C. or higher is used in combination, a content proportion of the solvent having a boiling point of 150° C. or higher is preferably 3% to 50% by mass, more preferably 5% to 40% by mass, and particularly preferably 5% to 30% by mass in the solvent (B) included in the colored resin composition. By setting the content proportion to the lower limit value or more, for example, there is a tendency that it is easy to prevent coloring material components and the like from being precipitated and solidified at a slit nozzle tip to cause the occurrence of foreign matter defects. By setting the content proportion to the upper limit value or less, there is a tendency that the drying speed of the composition is decreased, and thus, it is easy to prevent the occurrence of problems such as poor tackiness of the drying process under reduced pressure and pin marks during pre-baking.

The solvent having a boiling point of 150° C. or higher may be either glycol alkyl ether acetates or glycol alkyl ethers, and in this case, it does not matter even if the solvent having a boiling point of 150° C. or higher is not separately contained.

Preferred examples of the solvent having a boiling point of 150° C. or higher include diethylene glycol mono-n-butyl ether acetate, diethylene glycol monoethyl ether acetate, dipropylene glycol methyl ether acetate, 1,3-butylene glycol diacetate, 1,6-hexanol diacetate, and triacetone.

When a pixel of a color filter is formed by an ink jet method, a solvent having a boiling point of 130° C. or higher and 300° C. or lower is preferable, and a solvent having a boiling point of 150° C. or higher and 280° C. or lower is more preferable as the solvent. By setting the boiling point to the lower limit value or higher, there is a tendency that the uniformity of the obtained coating film is improved. By setting the boiling point to the upper limit value or lower, there is a tendency that the residual solvent during sintering is easily reduced.

The vapor pressure of the solvent to be used is preferably 10 mmHg or less, more preferably 5 mmHg or less, and still more preferably 1 mmHg or less from the viewpoint of the uniformity of the obtained coating film.

In the production of a color filter by an ink jet method, the amount of an ink emitted from nozzles is as small as a few to a few tens pL. Therefore, there is a tendency that the solvent evaporates before being impacted around a nozzle port or in a pixel bank, and thus, the ink is concentrated and dried. In order to avoid this, the boiling point of the solvent is preferably high, specifically, a solvent having a boiling point of 180° C. or higher, more preferably having a boiling point of 200° C. or higher, and particularly preferably having a boiling point of 220° C. or higher is contained. In addition, the solvent having a boiling point of 180° C. or higher, more preferably having a boiling point of 200° C. or higher, and particularly preferably having a boiling point of 220° C. or higher is preferably at 50% by mass or more, more preferably at 70% by mass or more, and most preferably at 90% by mass or more in the solvent (B) included in the colored resin composition. By setting the boiling point of the solvent to the lower limit value or higher, there is a tendency that an effect of preventing the evaporation of the solvent from the liquid droplet is likely to be sufficiently exhibited.

Preferred examples of the solvent having a boiling point of 180° C. or higher, more preferably 200° C. or higher, and particularly preferably 220° C. or higher include diethylene glycol mono-n-butyl ether acetate, diethylene glycol monoethyl ether acetate, dipropylene glycol methyl ether acetate, 1,3-butylene glycol diacetate, 1,6-hexanol diacetate, and triacetone.

For adjustment of the viscosity of the colored resin composition or adjustment of the solubility of the solid content, it is also effective to partially contain a solvent having a boiling point lower than 180° C. As a solvent having a boiling point lower than 180° C., a solvent having a low viscosity, a high solubility, and a low surface tension is preferable, and ethers, esters, ketones, and the like are preferable. Among these, particularly, for example, cyclohexanone, dipropylene glycol dimethyl ether, and cyclohexanol acetate are preferable.

When the solvent contains alcohols, the ejection stability in an ink jet method may be deteriorated. From the viewpoint of the ejection stability in the ink jet method, alcohols in the solvent (B) included in the colored resin composition are preferably at 20% by mass or less, more preferably at 10% by mass or less, and particularly preferably at 5% by mass or less.

A content proportion of the solvent in the colored resin composition of the present invention is not particularly limited, but is preferably 99% by mass or less, more preferably 90% by mass or less, and still more preferably 85% by mass or less. By setting the content proportion to the upper limit value or less, there is a tendency that a coating film is easily formed. On the other hand, in consideration of the viscosity and the like that are suitable for coating, the content proportion is preferably 70% by mass, more preferably 75% by mass or more, and still more preferably 78% by mass or more.

The above-described upper limits and lower limits can be combined in any manner. For example, the content proportion of the solvent in the colored resin composition of the present invention is 70% to 99% by mass, preferably 75% to 90% by mass, and more preferably 78% to 85% by mass. 1-3 Binder resin (C)

The colored resin composition of the present invention contains a binder resin (C). Since the colored resin composition contains the binder resin (C), both of the film curability by photopolymerization and the solubility by a developer can be achieved. The binder resin (C) is preferably an alkali-soluble resin.

As the alkali-soluble resin, for example, the known polymer compounds described in Japanese Unexamined Patent Application, First Publication No. H7-207211, Japanese Unexamined Patent Application, First Publication No. H8-259876, Japanese Unexamined Patent Application, First Publication No. H10-300922, Japanese Unexamined Patent Application, First Publication No. H11-140144, Japanese Unexamined Patent Application, First Publication No. H11-174224, Japanese Unexamined Patent Application, First Publication No. 2000-56118, and Japanese Unexamined Patent Application, First Publication No. 2003-233179 can be used. Among those, preferred examples thereof include the resins of (C-1) to (C-5).
(C-1): A resin obtained by adding an unsaturated monobasic acid to at least a part of epoxy groups contained in a copolymer of an epoxy group-containing (meth)acrylate and another radically polymerizable monomer, or an alkali-soluble resin obtained by adding a polybasic acid anhydride to at least a part of hydroxyl groups generated by the addition reaction (which may be hereinafter referred to as a “resin (C-1)”).
(C-2) A linear alkali-soluble resin containing a carboxyl group in the main chain (which may be hereinafter referred to as a “resin (C-2)”).
(C-3) A resin obtained by adding an epoxy group-containing unsaturated compound to the carboxyl group portion of the resin (C-2) (which may be hereinafter referred to as a “resin (C-3)”).
(C-4) A (meth)acryl-based resin (which may be hereinafter referred to as a “resin (C-4)”).
(C-5) An epoxy (meth)acrylate resin having a carboxyl group (which may be hereinafter referred to as a “resin (C-5)”).

Among those, the resin (C-1) is particularly preferable.

The resins (C-2) to (C-5) can be any of the resins that are dissolved in an alkaline developer and have a solubility to the extent that a targeted development treatment is carried out, and the resins described as the same item in Japanese Unexamined Patent Application, First Publication No. 2009-025813 can be preferably employed.
(C-1) A resin obtained by adding an unsaturated monobasic acid to at least a part of epoxy groups contained in a copolymer of an epoxy group-containing (meth)acrylate and another radically polymerizable monomer, or an alkali-soluble resin obtained by adding a polybasic acid anhydride to at least a part of hydroxyl groups generated by the addition reaction

One of preferred aspects of the resin (C-1) may be “a resin obtained by adding an unsaturated monobasic acid to 10% to 100% by mole of epoxy groups contained in a copolymer of 5% to 90% by mole of an epoxy group-containing (meth)acrylate and 10% to 95% by mole of another radically polymerizable monomer, or an alkali-soluble resin obtained by adding a polybasic acid anhydride to 10% to 100% by mole of hydroxyl groups generated by the addition reaction”.

Examples of the epoxy group-containing (meth)acrylate include glycidyl (meth)acrylate, 3,4-epoxybutyl (meth)acrylate, (3,4-epoxycyclohexyl)methyl (meth)acrylate, and 4-hydroxybutyl (meth)acrylate glycidyl ether. Among these, glycidyl (meth)acrylate is preferable. The epoxy group-containing (meth)acrylate may be used alone or in a combination of two or more kinds thereof.

As the other radically polymerizable monomer to be copolymerized with the epoxy group-containing (meth)acrylate, a mono(meth)acrylate having a structure represented by General Formula (V) is preferable.

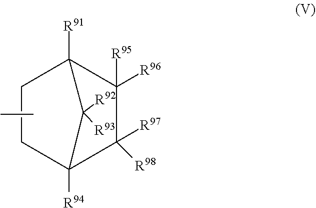

In Formula (V), R⁹¹ to R⁹⁸ each independently represent a hydrogen atom or an alkyl group having 1 to 3 carbon atoms. Further, R⁹⁶ and R⁹⁸, or R⁹⁵ and R⁹⁷ may be linked to each other to form a ring.

In Formula (V), when R⁹⁶ and R⁹⁸ or R⁹⁵ and R⁹⁷ are linked to each other to form a ring, the formed ring is preferably an aliphatic ring, may be either saturated or unsaturated, and preferably has 5 or 6 carbon atoms.

As the structure represented by Formula (V), a structure represented by Formula (Va), (Vb), or (Vc) is preferable.

By introducing these structures into the alkali-soluble resin, when the colored resin composition of the present invention is used to form a color filter, there is a tendency that the heat resistance of the colored resin composition is improved and the strength of a pixel formed using the colored resin composition is increased.

The mono(meth)acrylate having the structure represented by Formula (V) may be used alone or in combination of two or more kinds thereof.

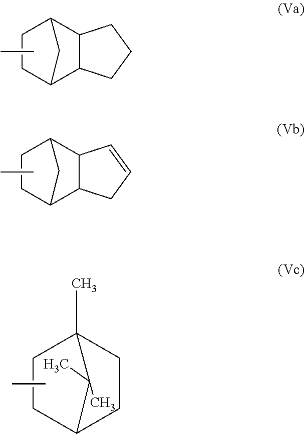

As the mono(meth)acrylate having the structure represented by Formula (V), various known mono(meth)acrylates having the structure represented by Formula (V) can be used, but in particular, a mono(meth)acrylate represented by General Formula (VI) is preferable.

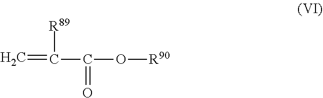

In Formula (VI), R⁸⁹ represents a hydrogen atom or a methyl group, and R⁹⁰ represents the structure represented by Formula (V).

When a repeating unit derived from a mono(meth)acrylate represented by Formula (VI) is included, the content proportion of the repeating unit derived from a mono(meth)acrylate represented by Formula (VI) in the copolymer of the epoxy group-containing (meth)acrylate and another radically polymerizable monomer is preferably 5% to 90% by mole, more preferably 10% to 70% by mole, and still more preferably 15% to 50% by mole in repeating units derived from other radically polymerizable monomers.

Such another radically polymerizable monomer other than the mono(meth)acrylate represented by Formula (VI) is not particularly limited. Examples thereof include vinyl aromatic compounds in which styrene, or the α-position, the ortho-position, the meta-position, or the para-position of styrene is substituted with alkyl, nitro, cyano, amide, ester, or the like; dienes such as butadiene, 2,3-dimethylbutadiene, isoprene, and chloroprene; (meth)acrylic acid esters such as methyl (meth)acrylate, ethyl (meth)acrylate, n-propyl (meth)acrylate, isopropyl (meth)acrylate, n-butyl (meth)acrylate, sec-butyl (meth)acrylate tert-butyl (meth)acrylate, pentyl (meth)acrylate, neopentyl (meth)acrylate, isoamyl (meth)acrylate, hexyl (meth)acrylate, 2-ethylhexyl (meth)acrylate, lauryl (meth)acrylate, dodecyl (meth)acrylate, cyclopentyl (meth)acrylate, cyclohexyl (meth)acrylate, 2-methylcyclohexyl (meth)acrylate, dicyclohexyl (meth)acrylate, isobornyl (meth)acrylate, adamantyl (meth)acrylate, propargyl (meth)acrylate, phenyl (meth)acrylate, naphthyl (meth)acrylate, anthracenyl (meth)acrylate, anthraninonyl (meth)acrylate, piperonyl (meth)acrylate, salicyl (meth)acrylate, furyl (meth)acrylate, furfuryl (meth)acrylate, tetrahydrofuryl (meth)acrylate, pyranyl (meth)acrylate, benzyl (meth)acrylate, phenethyl (meth)acrylate, cresyl (meth)acrylate, 1,1,1-trifluoroethyl (meth)acrylate, perfluoroethyl (meth)acrylate, perfluoro-n-propyl (meth)acrylate, perfluoro-isopropyl (meth)acrylate, triphenylmethyl (meth)acrylate, cumyl (meth)acrylate, 3-(N,N-dimethylamino)propyl (meth)acrylate, 2-hydroxyethyl (meth)acrylate, and 2-hydroxypropyl (meth)acrylate; (meth)acrylic acid amides such as (meth)acrylic acid amide, (meth)acrylic acid N,N-dimethylamide, (meth)acrylic acid N,N-diethylamide, (meth)acrylic acid N,N-dipropylamide, (meth)acrylic acid N,N-diisopropylamide, and (meth)acrylic acid anthracenyl amide; vinyl compounds such as (meth)acrylic acid anilide, (meth)acryloyl nitrile, acrolein, vinyl chloride, vinylidene chloride, vinyl fluoride, vinylidene fluoride, N-vinylpyrrolopyrrole dione, vinylpyridine, and vinyl acetate; unsaturated dicarboxylic acid diesters such as diethyl citraconate, diethyl maleate, diethyl fumarate, and diethyl itaconate; monomaleimides such as N-phenylmaleimide, N-cyclohexylmaleimide, N-laurylmaleimide, and N-(4-hydroxyphenyl)maleimide; and N-(meth)acryloylphthalimide.

Among such other radically polymerizable monomers, one or more kinds selected from the group consisting of styrene, benzyl (meth)acrylate, and monomaleimides are preferably contained from the viewpoint of imparting excellent heat resistance and strength to the colored resin composition. In particular, when repeating units derived from one or more kinds selected from the group consisting of styrene, benzyl (meth)acrylate, and monomaleimides are contained, the content proportion of the repeating units is preferably 1% to 70% by mole, 0061nd more preferably 3% to 50% by mole in repeating units derived from other radically polymerizable monomers.

In the copolymerization reaction between the epoxy group-containing (meth)acrylate and another radically polymerizable monomer, a known solution polymerization method can be used. A solvent to be used is not particularly limited as long as the solvent is inert to radical polymerization, and an organic solvent that is usually used can be used.

Examples thereof include ethylene glycol monoalkyl ether acetates such as ethyl acetate, isopropyl acetate, cellosolve acetate, and butyl cellosolve acetate; diethylene glycol monoalkyl ether acetates such as diethylene glycol monomethyl ether acetate, carbitol acetate, and butyl carbitol acetate; propylene glycol monoalkyl ether acetates; acetic acid esters such as dipropylene glycol monoalkyl ether acetates; ethylene glycol dialkyl ethers; diethylene glycol dialkyl ethers such as methyl carbitol, ethyl carbitol, and butyl carbitol; triethylene glycol dialkyl ethers; propylene glycol dialkyl ethers; dipropylene glycol dialkyl ethers; ethers such as 1,4-dioxane and tetrahydrofuran; ketones such as acetone, methyl ethyl ketone, methyl isobutyl ketone, and cyclohexanone; hydrocarbons such as benzene, toluene, xylene, octane, and decane; petroleum solvents such as petroleum ether, petroleum naphtha, hydrogenated petroleum naphtha, and solvent naphtha; lactic acid esters such as methyl lactate, ethyl lactate, and butyl lactate; and dimethylformamide, and N-methylpyrrolidone. These solvents may be used alone or in combination of two or more kinds thereof.

The amount of the solvent used is preferably 30 to 1,000 parts by mass, and more preferably 50 to 800 parts by mass with respect to 100 parts by mass of the obtained copolymer. By setting the amount of the solvent used to be within the ranges, there is a tendency that the molecular weight of the copolymer is easily controlled.

The radical polymerization initiator used for the copolymerization reaction is not particularly limited as long as it can initiate radical polymerization, and an organic peroxide catalyst or an azo compound catalyst which is usually used can be used. Examples thereof include those divided into known radical polymerization initiators classified into ketone peroxides, peroxyketals, hydroperoxides, diaryl peroxides, diacyl peroxides, peroxyesters, and peroxydicarbonates.

Examples of the organic peroxide catalyst include benzoyl peroxide, dicumyl peroxide, diisopropyl peroxide, di-t-butyl peroxide, t-butyl peroxybenzoate, t-hexyl peroxybenzoate, t-butylperoxy-2-ethylhexanoate, t-hexylperoxy-2-ethylhexanoate, 1,1-bis(t-butylperoxy)-3,3,5-trimethylcyclohexane, 2,5-dimethyl-2,5-bis(t-butylperoxy)hexyl-3,3-isopropyl hydroperoxide, t-butyl hydroperoxide, dicumyl peroxide, dicumyl hydroperoxide, acetyl peroxide, bis(4-t-butylcyclohexyl) peroxydicarbonate, diisopropyl peroxide dicarbonate, isobutyl peroxide, 3,3,5-trimethylhexanoyl peroxide, lauryl peroxide, 1,1-bis(t-butylperoxy)3,3,5-trimethylcyclohexane, and 1,1-bis(t-hexylperoxy)3,3,5-trimethylcyclohexane.

Examples of the azo compound catalyst include azobisisobutyronitrile and azobiscarboxylic amide.

According to the polymerization temperature, one kind or two or more kinds of radical polymerization initiators having an appropriate half-life period are used. The amount of the radical polymerization initiator used is preferably 0.5 to 20 parts by mass, and more preferably 1 to 10 parts by mass with respect to 100 parts by mass of the total monomers used in the copolymerization reaction.

The copolymerization reaction may be performed by dissolving monomers to be used in the copolymerization reaction and a radical polymerization initiator in a solvent, and raising the temperature while stirring; may be performed by adding monomers, to which a radical polymerization initiator has been added, dropwise into a solvent that has been subjected to a rise in temperature and stirred; or may performed by adding monomers dropwise to a solvent to which a radical polymerization initiator has been added, followed by a rise in temperature. The reaction conditions can be adjusted depending on a targeted molecular weight.

As the copolymer of the epoxy group-containing (meth)acrylate and another radically polymerizable monomer, a copolymer consisting of 5% to 90% by mole of repeating units derived from the epoxy group-containing (meth)acrylate and 95% to 10% by mole of repeating units derived from another radically polymerizable monomer is preferable, a copolymer consisting of 20% to 80% by mole of repeating units derived from the epoxy group-containing (meth)acrylate and 80% to 20% by mole of repeating units derived from another radically polymerizable monomer is more preferable, and a copolymer consisting of 30% to 70% by mole of repeating units derived from the epoxy group-containing (meth)acrylate and 70% to 30% by mole of repeating units derived from another radically polymerizable monomer is still more preferable.

By setting the content proportion of the repeating units derived from the epoxy group-containing (meth)acrylate to the lower limit value or more, there is a tendency that the addition amount of an unsaturated monobasic acid or a polybasic acid anhydride which will be described later is sufficient. By setting the content proportion of the repeating units derived from another radically polymerizable monomer set to the lower limit value or more, there is a tendency that the heat resistance or the strength is sufficiently improved.

Subsequently, the unsaturated monobasic acid (polymerizable component) and the polybasic acid anhydride (alkali-soluble component) are reacted with the epoxy group part of the copolymer of the epoxy resin-containing (meth)acrylate and another radically polymerizable monomer.

As the unsaturated monobasic acid to be added to the epoxy group, a known unsaturated monobasic acid can be used, and examples thereof include unsaturated carboxylic acids having an ethylenically unsaturated double bond.

Examples thereof include monocarboxylic acids such as (meth)acrylic acid, crotonic acid, o-vinylbenzoic acid, m-vinylbenzoic acid, p-vinylbenzoic acid, and a (meth)acrylic acid substituted with a haloalkyl group, an alkoxyl group, a halogen atom, a nitro group, a cyano group, or the like at the α-position. The (meth)acrylic acid is preferable. The unsaturated monobasic acid may be used alone or in combination of two or more kinds thereof.

Polymerizability can be imparted to the resin (C-1) by adding the unsaturated monobasic acid.

The unsaturated monobasic acid is added to preferably 10% to 100% by mole, more preferably 30% to 100% by mole, and still more preferably 50% to 100% by mole of the epoxy groups of the copolymer. By setting the amount to the lower limit value or more, there is a tendency that the stability over time of the colored resin composition is improved. As a method for adding the unsaturated monobasic acid to the epoxy group of the copolymer, a known method can be employed.

As the polybasic acid anhydride to be added to the hydroxyl groups generated when an unsaturated monobasic acid is added to the epoxy groups of the copolymer, a known polybasic acid anhydride can be used.

Examples of the polybasic acid anhydride include dibasic acid anhydrides such as maleic anhydride, succinic anhydride, itaconic anhydride, phthalic anhydride, tetrahydrophthalic anhydride, hexahydrophthalic anhydride, chlorendic anhydride; and tribasic or higher acid anhydrides such as trimellitic anhydride, pyromellitic anhydride, benzophenone tetracarboxylic anhydride, and biphenyltetracarboxylic anhydride. The tetrahydrophthalic anhydride or the succinic anhydride is preferable. The polybasic acid anhydride may be used alone or in combination of two or more kinds thereof.

Alkali solubility can be imparted to the resin (C-1) by adding the polybasic acid anhydride.

The polybasic acid anhydride is added to preferably 10% to 100% by mole, more preferably 20% to 90% by mole, and still more preferably 30% to 80% by mole of the hydroxyl groups generated when the unsaturated monobasic acid is added to the epoxy groups contained the copolymer. By setting the content proportion to the upper limit value or less, there is a tendency that the residual film ratio during development is improved. By setting the content proportion to the lower limit value or more, there is a tendency that the solubility is sufficient. As a method for adding the polybasic acid anhydride to the hydroxyl group, a known method can be employed.

In order to improve the light sensitivity, a glycidyl (meth)acrylate or a glycidyl ether compound having a polymerizable unsaturated group may be added to some of carboxyl groups generated after adding the polybasic acid anhydride. In order to improve the developability, a glycidyl ether compound not having a polymerizable unsaturated group may be added to some of carboxyl groups generated after adding the polybasic acid anhydride. Any of these may be added.

Examples of the glycidyl ether compound not having a polymerizable unsaturated group include glycidyl ether compounds having a phenyl group or an alkyl group. Examples of commercially available products thereof include product names “DENACOL EX-111”, “DENACOL EX-121”, “DENACOL EX-141”, “DENACOL EX-145”, “DENACOL EX-146”, “DENACOL EX-171” and “DENACOL EX-192”, each manufactured by Nagase ChemteX Corporation.

The structure of the resin (C-1) is described, for example, in Japanese Unexamined Patent Application, First Publication No. H8-297366 and Japanese Unexamined Patent Application, First Publication No. 2001-89533.

The polystyrene-equivalent weight-average molecular weight (Mw) of the resin (C-1) as measured by GPC is not particularly limited, but is preferably 3,000 to 100,000, and particularly preferably 5,000 to 50,000. By setting the weight-average molecular weight to the lower limit value or more, there is a tendency that the heat resistance and the film strength are improved. By setting the weight-average molecular weight to the upper limit value or less, there is a tendency that the solubility in a developer is improved. As a guide of the molecular weight distribution, the weight-average molecular weight (Mw)/the number-average molecular weight (Mn) is preferably 2.0 to 5.0.

From the viewpoint of the coating film curability at the time of ultraviolet exposure, among the binder resins (C), an acrylic copolymer resin having an ethylenically unsaturated group in a side chain (ci) is preferable.

A partial structure including a side chain having an ethylenically unsaturated group contained in the acrylic copolymer resin, having an ethylenically unsaturated group in the side chain (c1) is not particularly limited. From the viewpoint of achieving both the coating film curability during ultraviolet exposure and the alkali solubility during alkali development, it is preferable to have a partial structure represented by General Formula (I), for example.

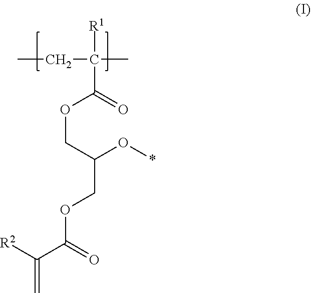

In Formula (I), R¹ and R² each independently represent a hydrogen atom or a methyl group. * represents a binding site.

Among the partial structures represented by Formula (I), a partial structure represented by General Formula (I′) is preferable from the viewpoint of a sensitivity and an alkali developability.

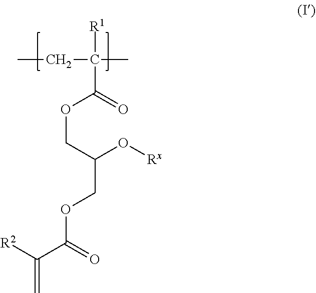

In Formula (I′), R¹ and R² each independently represent a hydrogen atom or a methyl group. RX represents a hydrogen atom or a polybasic acid residue.

The polybasic acid residue means a monovalent or divalent group obtained by removing one or two OH groups from a polybasic acid. Examples of the polybasic acid include maleic acid, succinic acid, itaconic acid, phthalic acid, tetrahydrophthalic acid, hexahydrophthalic acid, pyromellitic acid, trimellitic acid, benzophenone tetracarboxylic acid, methyl hexahydrophthalic acid, endomethylene tetrahydrophthalic acid, chlorendic acid, methyl tetrahydrophthalic acid, and biphenyl tetracarboxylic acid. The polybasic acid may be used alone or in combination of two or more kinds thereof.

From the viewpoint of patterning characteristics, maleic acid, succinic acid, itaconic acid, phthalic acid, tetrahydrophthalic acid, hexahydrophthalic acid, pyromellitic acid, trimellitic acid, or biphenyl tetracarboxylic acid is preferable, and tetrahydrophthalic acid or biphenyl tetracarboxylic acid is more preferable.

When the acrylic copolymer resin having an ethylenically unsaturated group in the side chain (c1) includes a partial structure represented by Formula (I), a content proportion of the partial structure represented by Formula (I) in the acrylic copolymer resin having an ethylenically unsaturated group in the side chain (ci) is not particularly limited. However, the content proportion is preferably 10% by mole or more, more preferably 20% by mole or more, still more preferably 30% by mole or more, even still more preferably 40% by mole or more, particularly preferably 50% by mole or more, and most preferably 65% by mole or more, and preferably 95% by mole or less, more preferably 90% by mole or less, still more preferably 85% by mole or less, even still more preferably 80% by mole or less, particularly preferably 75% by mole or less, and most preferably 70% by mole or less. By setting the content proportion to the lower limit value or more, there is a tendency that the coating film curability during ultraviolet exposure is improved. By setting the content proportion to the upper limit value or less, there is a tendency that the alkali solubility during alkali development is improved.

The above-described upper limits and lower limits can be combined in any manner. For example, the content proportion of the partial structure represented by Formula (I) in the acrylic copolymer resin having an ethylenically unsaturated group in the side chain (c1) is preferably 10% to 95% by mole, more preferably 20% to 90% by mole, still more preferably 30% to 85% by mole, even still more preferably 40% to 80% by mole, particularly preferably 50% to 75% by mole, and most preferably 65% to 70% by mole.

When the acrylic copolymer resin having an ethylenically unsaturated group in the side chain (c1) includes a partial structure represented by Formula (I′), a content proportion of the partial structure represented by Formula (I′) in the acrylic copolymer resin having an ethylenically unsaturated group in the side chain (ci) is not particularly limited. However, the content proportion is preferably 10% by mole or more, more preferably 20% by mole or more, still more preferably 30% by mole or more, even still more preferably 40% by mole or more, particularly preferably 50% by mole or more, and most preferably 65% by mole or more. In addition, the content proportion is preferably 95% by mole or less, more preferably 90% by mole or less, still more preferably 85% by mole or less, even still more preferably 80% by mole or less, particularly preferably 75% by mole or less, and most preferably 70% by mole or less. By setting the content proportion to the lower limit value or more, there is a tendency that the coating film curability during ultraviolet exposure is improved. By setting the content proportion to the upper limit value or less, there is a tendency that the alkali solubility during alkali development is improved.

The above-described upper limits and lower limits can be combined in any manner. For example, the content proportion of the partial structure represented by Formula (I) in the acrylic copolymer resin having an ethylenically unsaturated group in the side chain (c1) is preferably 10% to 95% by mole, more preferably 20% to 90% by mole, still more preferably 30% to 85% by mole, even still more preferably 40% to 80% by mole, particularly preferably 50% to 75% by mole, and most preferably 65% to 70% by mole.

When the acrylic copolymer resin having an ethylenically unsaturated group in the side chain (c1) includes the partial structure represented by Formula (I), other partial structures included are not particularly limited, but from the viewpoint of the alkali solubility during alkali development, it is also preferable to have a partial structure represented by General Formula (II), for example.

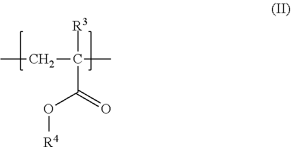

In Formula (II), R³ represents a hydrogen atom or a methyl group, and R⁴ represents an alkyl group which may have a substituent, an aromatic ring group which may have a substituent, or an alkenyl group which may have a substituent.

### R⁴

In Formula (II), R⁴ represents an alkyl group which may have a substituent, an aromatic ring group which may have a substituent, or an alkenyl group which may have a substituent.

Examples of the alkyl group for R⁴ include a linear, branched, or cyclic alkyl group. The number of carbon atoms thereof is preferably 1 or more, more preferably 3 or more, still more preferably 5 or more, and particularly preferably 8 or more. In addition, the number of carbon atoms is preferably 20 or less, more preferably 18 or less, still more preferably 16 or less, even still more preferably 14 or less, and particularly preferably 12 or less. By setting the number of carbon atoms to the lower limit value or more, there is a tendency that the lipophilicity is improved and the solubility in a solvent is improved. By setting the number of carbon atoms to the upper limit value or less, there is a tendency that the hydrophilicity is improved and the alkali solubility is improved.

The above-described upper limits and lower limits can be combined in any manner. For example, the number of carbon atoms of the alkyl group for R⁴ is preferably 1 to 20, more preferably 1 to 18, still more preferably 3 to 16, even still more preferably 5 to 14, and particularly preferably 8 to 12.

Examples of the alkyl group include a methyl group, an ethyl group, a cyclohexyl group, a dicyclopentanyl group, and a dodecanyl group. From the viewpoint of the developability, the dicyclopentanyl group and the dodecanyl group are preferable, and the dicyclopentanyl group is more preferable.

Examples of the substituent that the alkyl group may have include a methoxy group, an ethoxy group, a chloro group, a bromo group, a fluoro group, a hydroxy group, an amino group, an epoxy group, an oligoethylene glycol group, a phenyl group, a carboxyl group, an acryloyl group, and a methacryloyl group. From the viewpoint of the developability, the hydroxy group and the oligoethylene glycol group are preferable.

Examples of the aromatic ring group for R⁴ include a monovalent aromatic hydrocarbon ring group and a monovalent aromatic heterocyclic group. The number of carbon atoms thereof is preferably 6 or more. In addition, the number of carbon atoms is preferably 24 or less, more preferably 22 or less, still more preferably 20 or less, and particularly preferably 18 or less. For example, the number of carbon atoms is preferably 6 to 24, more preferably 6 to 22, still more preferably 6 to 20, and particularly preferably 6 to 18. By setting the number of carbon atoms to the lower limit value or more, there is a tendency that the lipophilicity is improved and the solubility in a solvent is improved. By setting the number of carbon atoms to the upper limit value or less, there is a tendency that the hydrophilicity is improved and the alkali solubility is improved.

The aromatic hydrocarbon ring in the aromatic hydrocarbon ring group may be a monocyclic ring or a fused ring, and examples thereof include a benzene ring, a naphthalene ring, an anthracene ring, a phenanthrene ring, a perylene ring, a tetracene ring, a pyrene ring, a benzopyrene ring, a chrysene ring, a triphenylene ring, an acenaphthene ring, a fluoranthene ring, and a fluorene ring.

The aromatic heterocyclic group in the aromatic heterocyclic group may be a monocyclic ring or a fused ring, and examples thereof include a furan ring, a benzofuran ring, a thiophene ring, a benzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzisoxazole ring, a benzisothiazole ring, a benzimidazole ring, a pyridine ring, a pyrazine ring, a pyridazine ring, a pyrimidine ring, a triazine ring, a quinoline ring, an isoquinoline ring, a cinnoline ring, a quinoxaline ring, a phenanthridine ring, a perimidine ring, a quinazoline ring, a quinazolinone ring, and an azulene ring.

From the viewpoint of the developability, the benzene ring or the naphthalene ring is preferable, and the benzene ring is more preferable.

Examples of the substituent that the aromatic ring group may have include a methyl group, an ethyl group, a propyl group, a methoxy group, an ethoxy group, a chloro group, a bromine group, a fluoro group, a hydroxy group, an amino group, an epoxy group, an oligoethylene glycol group, a phenyl group, and a carboxyl group. From the viewpoint of the developability, the hydroxy group and the oligoethylene glycol group are preferable.

Examples of the alkenyl group for R⁴ include a linear, branched, or cyclic alkenyl group. The number of carbon atoms thereof is preferably 2 or more, and preferably 22 or less, more preferably 20 or less, still more preferably 18 or less, even still more preferably 16 or less, and particularly preferably 14 or less. For example, the number of carbon atoms is preferably 2 to 22, more preferably 2 to 20, still more preferably 2 to 18, even still more preferably 2 to 16, and particularly preferably 2 to 14. By setting the number of carbon atoms to the lower limit value or more, there is a tendency that the lipophilicity is improved and the solubility in a solvent is improved. By setting the number of carbon atoms to the upper limit value or less, there is a tendency that the hydrophilicity is improved and the alkali solubility is improved.

Examples of the alkenyl group include a vinyl group, an allyl group, a 2-propen-2-yl group, a 2-buten-1-yl group, a 3-buten-1-yl group, a 2-penten-1-yl group, a 3-penten-2-yl group, a hexenyl group, a cyclobutenyl group, a cyclopentenyl group, and cyclohexenyl. From the viewpoint of the developability, the vinyl group and the allyl group are preferable, and the vinyl group is more preferable.

Examples of the substituent that the alkenyl group may have include a methoxy group, an ethoxy group, a chloro group, a bromine group, a fluoro group, a hydroxy group, an amino group, an epoxy group, an oligoethylene glycol group, a phenyl group, and a carboxyl group. From the viewpoint of the developability, the hydroxy group and the oligoethylene glycol group are preferable.

From the viewpoints of a developability and a film strength, R⁴ is preferably the alkyl group and the alkenyl group, and more preferably the alkyl group.

When the acrylic copolymer resin having an ethylenically unsaturated group in the side chain (c1) includes a partial structure represented by Formula (II), a content proportion of the partial structure represented by Formula (II) in the acrylic copolymer resin having an ethylenically unsaturated group in the side chain (ci) is not particularly limited, but is preferably 1% by mole or more, more preferably 5% by mole or more, still more preferably 10% by mole or more, and particularly preferably 20% by mole or more. In addition, the content proportion is preferably 70% by mole or less, more preferably 60% by mole or less, still more preferably 50% by mole or less, and particularly preferably 40% by mole or less. By setting the content proportion to the lower limit value or more, there is a tendency that the alkali solubility is improved. By setting the content proportion to the upper limit value or less, there is a tendency that the storage stability of the colored resin composition is improved.

The above-described upper limits and lower limits can be combined in any manner. For example, the content proportion of the partial structure represented by Formula (II) in the acrylic copolymer resin having an ethylenically unsaturated group in the side chain (c1) is preferably 1% to 70% by mole, more preferably 5% to 60% by mole, still more preferably 10% to 50% by mole, and particularly preferably 20% to 40% by mole.

When the acrylic copolymer resin having an ethylenically unsaturated group in the side chain (c1) includes the partial structure represented by Formula (I), it is preferable to have, for example, a partial structure represented by General Formula (III) as other partial structures included from the viewpoint of suppressing a decrease in luminance by improving the heat resistance.

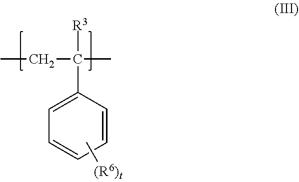

In Formula (III), R⁵ represents a hydrogen atom or a methyl group, and R⁶ represents an alkyl group which may have a substituent, an alkenyl group which may have a substituent, an alkynyl group which may have a substituent, a hydroxyl group, a carboxyl group, a halogen atom, an alkoxy group which may have a substituent, a thiol group, or an alkyl sulfide group which may have a substituent. t represents an integer of 0 to 5.

### R⁶

In Formula (III), R⁶ represents an alkyl group which may have a substituent, an alkenyl group which may have a substituent, an alkynyl group which may have a substituent, a hydroxyl group, a carboxyl group, a halogen atom, an alkoxy group which may have a substituent, a thiol group, or an alkyl sulfide group which may have a substituent.

Examples of the alkyl group for R⁶ include a linear, branched, or cyclic alkyl group. The number of carbon atoms thereof is preferably 1 or more, more preferably 3 or more, and still more preferably 5 or more. In addition, the number of carbon atoms is preferably 20 or less, more preferably 18 or less, still more preferably 16 or less, even still more preferably 14 or less, and particularly preferably 12 or less. By setting the number of carbon atoms to the lower limit value or more, there is a tendency that the lipophilicity is improved and the solubility in a solvent is improved. By setting the number of carbon atoms to the upper limit value or less, there is a tendency that the hydrophilicity is improved and the alkali solubility is improved.

The above-described upper limits and lower limits can be combined in any manner. For example, the number of carbon atoms of the alkyl group for R⁴ is preferably 1 to 20, more preferably 1 to 18, still more preferably 3 to 16, even still more preferably 3 to 14, and particularly preferably 5 to 12.

Examples of the alkyl group include a methyl group, an ethyl group, a cyclohexyl group, a dicyclopentanyl group, and a dodecanyl group. From the viewpoint of the heat resistance, the dicyclopentanyl group and the dodecanyl group are preferable, and the dicyclopentanyl group is more preferable.

Examples of the substituent that the alkyl group may have include a methoxy group, an ethoxy group, a chloro group, a bromo group, a fluoro group, a hydroxy group, an amino group, an epoxy group, an oligoethylene glycol group, a phenyl group, a carboxyl group, an acryloyl group, and a methacryloyl group. From the viewpoint of the developability, the hydroxy group and the oligoethylene glycol group are preferable.

Examples of the alkenyl group for R⁶ include a linear, branched, or cyclic alkenyl group. The number of carbon atoms thereof is preferably 2 or more. In addition, the number of carbon atoms is preferably 22 or less, more preferably 20 or less, still more preferably 18 or less, even still more preferably 16 or less, and particularly preferably 14 or less. For example, the number of carbon atoms is preferably 2 to 22, more preferably 2 to 20, still more preferably 2 to 18, even still more preferably 2 to 16, and particularly preferably 2 to 14. By setting the number of carbon atoms to the lower limit value or more, there is a tendency that the lipophilicity is improved and the solubility in a solvent is improved. By setting the number of carbon atoms to the upper limit value or less, there is a tendency that the hydrophilicity is improved and the alkali solubility is improved.

Examples of the alkenyl group include a vinyl group, an allyl group, a 2-propen-2-yl group, a 2-buten-1-yl group, a 3-buten-1-yl group, a 2-penten-1-yl group, a 3-penten-2-yl group, a hexenyl group, a cyclobutenyl group, a cyclopentenyl group, and cyclohexenyl. From the viewpoint of the exposure sensitivity during ultraviolet exposure, the vinyl group and the allyl group are preferable, and the vinyl group is more preferable.

Examples of the substituent that the alkenyl group may have include a methoxy group, an ethoxy group, a chloro group, a bromine group, a fluoro group, a hydroxy group, an amino group, an epoxy group, an oligoethylene glycol group, a phenyl group, and a carboxyl group. From the viewpoint of the developability, the hydroxy group and the oligoethylene glycol group are preferable.

Examples of the alkynyl group for R⁶ include a linear, branched, or cyclic alkynyl group. The number of carbon atoms thereof is preferably 2 or more. In addition, the number of carbon atoms is preferably 22 or less, more preferably 20 or less, still more preferably 18 or less, even still more preferably 16 or less, and particularly preferably 14 or less. For example, the number of carbon atoms is preferably 2 to 22, more preferably 2 to 20, still more preferably 2 to 18, even still more preferably 2 to 16, and particularly preferably 2 to 14. By setting the number of carbon atoms to the lower limit value or more, there is a tendency that the lipophilicity is improved and the solubility in a solvent is improved. By setting the number of carbon atoms to the upper limit value or less, there is a tendency that the hydrophilicity is improved and the alkali solubility is improved.

Examples of the alkynyl group include a 1-propyn-3-yl group, a 1-butyn-4-yl group, a 1-pentyn-5-yl group, a 2-methyl-3-butyn-2-yl group, a 1,4-pentadiyn-3-yl group, a 1,3-pentadiyn-5-yl group, and a 1-hexyn-6-yl group.

Examples of the substituent that the alkynyl group may have include a methoxy group, an ethoxy group, a chloro group, a bromine group, a fluoro group, a hydroxy group, an amino group, an epoxy group, an oligoethylene glycol group, a phenyl group, and a carboxyl group. From the viewpoint of the developability, the hydroxy group and the oligoethylene glycol group are preferable.

Examples of the halogen atom for R⁶ include a fluorine atom, a chlorine atom, a bromine atom, and an iodine atom. From the viewpoint of the storage stability of an acrylic copolymer resin, the fluorine atom is preferable.

Examples of the alkoxy group for R⁶ include a linear, branched, or cyclic alkoxy group. The number of carbon atoms thereof is preferably 1 or more. In addition, the number of carbon atoms is preferably 20 or less, more preferably 18 or less, still more preferably 16 or less, even still more preferably 14 or less, and particularly preferably 12 or less. For example, the number of carbon atoms is preferably 1 to 20, more preferably 1 to 18, still more preferably 1 to 16, even still more preferably 1 to 14, and particularly preferably 1 to 12. By setting the number of carbon atoms to the lower limit value or more, there is a tendency that the lipophilicity is improved and the solubility in a solvent is improved. By setting the number of carbon atoms to the upper limit value or less, there is a tendency that the hydrophilicity is improved and the alkali solubility is improved.

Examples of the alkoxy group include a methoxy group, an ethoxy group, a propoxy group, an isopropoxy group, a butoxy group, and an isobutoxy group.

Examples of the substituent that the alkoxy group may have include a methoxy group, an ethoxy group, a chloro group, a bromine group, a fluoro group, a hydroxy group, an amino group, an epoxy group, an oligoethylene glycol group, a phenyl group, a carboxyl group, an acryloyl group, and a methacryloyl group. From the viewpoint of the developability, the hydroxy group and the oligoethylene glycol group are preferable.

Examples of the alkyl sulfide group for R⁶ include a linear, branched, or cyclic alkyl sulfide group. The number of carbon atoms thereof is preferably 1 or more. In addition, the number of carbon atoms is preferably 20 or less, more preferably 18 or less, still more preferably 16 or less, even still more preferably 14 or less, and particularly preferably 12 or less. For example, the number of carbon atoms is preferably 1 to 20, more preferably 1 to 18, still more preferably 1 to 16, even still more preferably 1 to 14, and particularly preferably 1 to 12. By setting the number of carbon atoms to the lower limit value or more, there is a tendency that the lipophilicity is improved and the solubility in a solvent is improved. By setting the number of carbon atoms to the upper limit value or less, there is a tendency that the hydrophilicity is improved and the alkali solubility is improved.

Examples of the alkyl sulfide group include a methyl sulfide group, an ethyl sulfide group, a propyl sulfide group, and a butyl sulfide group.

From the viewpoint of the developability, the methyl sulfide group and the ethyl sulfide group are preferable.

Examples of the alkyl sulfide group include a methyl sulfide group, an ethyl sulfide group, a propyl sulfide group, and a butyl sulfide group. From the viewpoint of the developability, the methyl sulfide group and the ethyl sulfide group are preferable.

Examples of the substituent that the alkyl group in the alkyl sulfide group may have include a methoxy group, an ethoxy group, a chloro group, a bromine group, a fluoro group, a hydroxy group, an amino group, an epoxy group, an oligoethylene glycol group, a phenyl group, a carboxyl group, an acryloyl group, and a methacryloyl group. From the viewpoint of the developability, the hydroxy group and the oligoethylene glycol group are preferable.

From the viewpoint of the developability, R⁶ is preferably the hydroxyl group or the carboxyl group, and more preferably the carboxyl group.

From the viewpoint of an ease in production, it is preferable that t is 0 in Formula (III).

When the acrylic copolymer resin having an ethylenically unsaturated group in the side chain (c1) includes a partial structure represented by Formula (III), a content proportion of the partial structure represented by Formula (III) in the acrylic copolymer resin having an ethylenically unsaturated group in the side chain (c1) is not particularly limited. However, the content proportion is preferably 1% by mole or more, more preferably 2% by mole or more, still more preferably 5% by mole or more, and particularly preferably 8% by mole or more. In addition, the content proportion is preferably 50% by mole or less, more preferably 40% by mole or less, still more preferably 30% by mole or less, and particularly preferably 20% by mole or less. By setting the number of carbon atoms to the lower limit value or more, there is a tendency that the heat resistance is improved and a decrease in luminance is suppressed. By setting the number of carbon atoms to the upper limit value or less, there is a tendency that the content proportion of the other partial structure is increased and the alkali solubility is improved.

The above-described upper limits and lower limits can be combined in any manner. For example, the content proportion of the partial structure represented by Formula (III) in the acrylic copolymer resin having an ethylenically unsaturated group in the side chain (c1) is preferably 1% to 50% by mole, more preferably 2% to 40% by mole, still more preferably 5% to 30% by mole, and particularly preferably 8% to 20% by mole.

When the acrylic copolymer resin having an ethylenically unsaturated group in the side chain (c1) contains the partial structure represented by Formula (I), it is preferable to have, for example, a partial structure represented by General Formula (IV) as other partial structures included from the viewpoint of the developability.

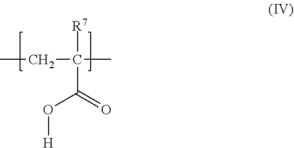

In Formula (IV), R⁷ represents a hydrogen atom or a methyl group.

When the acrylic copolymer resin having an ethylenically unsaturated group in the side chain (c1) includes a partial structure represented by Formula (IV), a content proportion of the partial structure represented by Formula (IV) in the acrylic copolymer resin having an ethylenically unsaturated group in the side chain (ci) is not particularly limited, but is preferably 5% by mole or more, more preferably 10% by mole or more, and still more preferably 20% by mole or more. In addition, the content proportion is preferably 80% by mole or less, more preferably 70% by mole or less, and still more preferably 60% by mole or less. By setting the content proportion to the lower limit value or more, there is a tendency that the alkali solubility is improved. By setting the content proportion to the upper limit value or less, there is a tendency that the storage stability of the colored resin composition is improved.

The above-described upper limits and lower limits can be combined in any manner. For example, the content proportion of the partial structure represented by Formula (IV) in the acrylic copolymer resin having an ethylenically unsaturated group in the side chain (c1) is preferably 5% to 80% by mole, more preferably 10% to 70% by mole, and still more preferably 20% to 60% by mole.

The acid value of the binder resin (C) is not particularly limited, but is preferably 10 mgKOH/g or more, more preferably 30 mgKOH/g or more, still more preferably 40 mgKOH/g or more, even still more preferably 50 mgKOH/g or more, and particularly preferably 60 mgKOH/g or more. In addition, the acid value is preferably 300 mgKOH/g or less, more preferably 250 mgKOH/g or less, still more preferably 200 mgKOH/g or less, and even still more preferably 150 mgKOH/g or less. By setting the content proportion to the lower limit value or more, there is a tendency that the alkali solubility is improved. By setting the content proportion to the upper limit value or less, there is a tendency that the storage stability of the colored resin composition is improved.

The above-described upper limits and lower limits can be combined in any manner. For example, the acid value of the binder resin (C) is preferably 10 to 300 mgKOH/g, more preferably 30 to 300 mgKOH/g, still more preferably 40 to 250 mgKOH/g, even still more preferably 50 to 200 mgKOH/g, and particularly preferably 60 to 150 mgKOH/g.

The acid value represents the number of mg of KOH required to neutralize 1 g of a solid content.

The weight-average molecular weight (Mw) of the binder resin (C) is not particularly limited, and is preferably 1,000 or more, more preferably 2,000 or more, still more preferably 4,000 or more, even still more preferably 6,000 or more, further more preferably 7,000 or more, and particularly preferably 8,000 or more. In addition, the weight-average molecular weight is preferably 30,000 or less, more preferably 20,000 or less, still more preferably 15,000 or less, and particularly preferably 10,000 or less. By setting the weight-average molecular weight to the lower limit value or more, there is a tendency that the heat resistance and the coating film curability are improved. By setting the weight-average molecular weight to the upper limit value or less, there is a tendency that the alkali solubility is improved.

The above-described upper limits and lower limits can be combined in any manner. For example, the weight-average molecular weight (Mw) of the binder resin (C) is preferably 1,000 to 30,000, more preferably 2,000 to 30,000, still more preferably 4,000 to 20,000, even still more preferably 6,000 to 20,000, particularly preferably 7,000 to 15,000, and most preferably 8,000 to 10,000.

A content proportion of the binder resin (C) in the colored resin composition of the present invention is not particularly limited, but is preferably 5% by mass or more, more preferably 10% by mass or more, still more preferably 20% by mass or more, and particularly more preferably 30% by mass or more in the total solid content of the colored resin composition. In addition, the content proportion is preferably 80% by mass or less, more preferably 70% by mass or less, still more preferably 60% by mass or less, and particularly preferably 50% by mass or less. By setting the content proportion to the lower limit value or more, there is a tendency that the coating film curability during ultraviolet exposure is improved. By setting the content proportion to the upper limit value or less, there is a tendency that the solubility in a developer is improved and residue is suppressed.

The above-described upper limits and lower limits can be combined in any manner. For example, the content proportion of the binder resin (C) in the total solid content of the colored resin composition is preferably 5% to 80% by mass, more preferably 10% to 70% by mass, still more preferably 20% to 60% by mass, and particularly preferably 30% to 50% by mass.

### 1-4 Other Solid Contents

Solid contents other than the components can be further blended into the colored resin composition of the present invention, as necessary. Examples of such components include a photopolymerization initiator, a photopolymerizable monomer, a dispersant, a dispersion aid, a surfactant, and an antioxidant.

1-4-1 Photopolymerization initiator (D)

The colored resin composition of the present invention may contain a photopolymerization initiator (D). Film curability through photopolymerization can be obtained by incorporating the photopolymerization initiator (D).

The photopolymerization initiator (D) can also be used as a mixture (photopolymerization initiating system) of an acceleration agent (chain transfer agent), and an additive to be added as necessary, such as a sensitizing dye. The photopolymerization initiating system is a component having a function of generating a polymerizable active radical by directly absorbing light or being photosensitized to cause a decomposition reaction or a hydrogen abstracting reaction.

Examples of the photopolymerization initiator include the metallocene compounds including titanocene compounds described in each of Japanese Unexamined Patent Application, First Publication No. S59-152396 and Japanese Unexamined Patent Application, First Publication No. S61-151197, radical activators such as N-aryl-α-amino acids such as the hexaarylbiimidazole derivative described in Japanese Unexamined Patent Application, First Publication No. H10-39503, a halomethyl-s-triazine derivative, and N-phenylglycine, N-aryl-α-amino acid salts, and N-aryl-α-amino acid esters, α-aminoalkylphenone-based compounds, and the oxime ester-based initiators described in Japanese Unexamined Patent Application, First Publication No. 2000-80068.

Examples of the photopolymerization initiator that can be used in the present invention include the following photopolymerization initiators.

Halomethylated triazine derivatives such as 2-(4-methoxyphenyl)-4,6-bis(trichloromethyl)-s-triazine, 2-(4-methoxynaphthyl)-4,6-bis(trichloromethyl)-s-triazine, 2-(4-ethoxynaphthyl)-4,6-bis(trichloromethyl)-s-triazine, and 2-(4-ethoxycarbonylnaphthyl)-4,6-bis(trichloromethyl)-s-triazine;
halomethyl oxadiazole derivatives such as 2-trichloromethyl-5-(2′-benzofuryl)-1,3,4-oxadiazole, 2-trichloromethyl-5-[β-(2′-benzofuryl)vinyl]-1,3,4-oxadiazole, 2-trichloromethyl-5-[β-(2′-(6″-benzofuryl)vinyl)]-1,3,4-oxadiazole, and 2-trichloromethyl-5-furyl-1,3,4-oxadiazole;
imidazole derivatives such as a 2-(2′-chlorophenyl)-4,5-diphenylimidasole dimer, a 2-(2′-chlorophenyl)-4,5-bis(3′-methoxyphenyl)imidazole dimer, a 2-(2′-fluorophenyl)-4,5-diphenylimidazole dimer, a 2-(2′-methoxyphenyl)-4,5-diphenylimidazole dimer, and a (4′-methoxyphenyl)-4,5-diphenylimidazole dimer; benzoin alkyl ethers such as a benzoin methyl ether, a benzoin phenyl ether, a benzoin isobutyl ether, and a benzoin isopropyl ether;
anthraquinone derivatives such as 2-methylanthraquinone, 2-ethylanthraquinone, 2-t-butylanthraquinone, and 1-chloroanthraquinone;
benzophenone derivatives such as benzophenone, Michler's ketone, 2-methylbenzophenone, 3-methylbenzophenone, 4-methylbenzophenone, 2-chlorobenzophenone, 4-bromobenzophenone, and 2-carboxybenzophenone;
acetophenone derivatives such as 2,2-dimethoxy-2-phenylacetophenone, 2,2-diethoxyacetophenone, 1-hydroxycyclohexylphenyl ketone, α-hydroxy-2-methylphenylpropanone, 1-hydroxy-1-methylethyl-(p-isopropylphenyl)ketone, 1-hydroxy-1-(p-dodecylphenyl)ketone, 2-methyl-1-[4-(methylthio)phenyl]-2-morpholinopropan-1-one, and 1,1,1-trichloromethyl-(p-butylphenyl)ketone;
thioxanthone derivatives such as thioxanthone, 2-ethylthioxanthone, 2-isopropylthioxanthone, 2-chlorothioxanthone, 2,4-dimethylthioxanthone, 2,4-diethylthioxanthone, and 2,4-diisopropylthioxanthone;
benzoic acid ester derivatives such as ethyl p-dimethylaminobenzoate and ethyl p-diethylaminobenzoate;
acridine derivatives such as 9-phenylacridine and 9-(p-methoxyphenyl)acridine;
phenazine derivatives such as 9,10-dimethylbenzophenazine;
anthone derivatives such as benzoanthone;
titanocene derivatives such as dicyclopentadienyl-Ti-dichloride, dicyclopentadienyl-Ti-bisphenyl, dicyclopentadienyl-Ti-bis-2,3,4,5,6-pentafluorophenyl, dicyclopentadienyl —Ti-bis-2,3,5,6-tetrafluorophenyl, dicyclopentadienyl-Ti-bis-2,4,6-trifluorophenyl, dicyclopentadienyl-Ti-2,6-difluorophenyl, dicyclopentadienyl-Ti-2,4-difluorophenyl, dimethylcyclopentadienyl-Ti-bis-2,3,4,5,6-pentafluorophenyl, dimethylcyclopentadienyl-Ti-bis-2,6-difluorophenyl, and dicyclopentadienyl-Ti-2,6-difluoro-3-(pyrrol-1-yl)-phenyl;
α-aminoalkylphenone-based compounds such as 2-methyl-1[4-(methylthio)phenyl]-2-morpholinopropan-1-one, 2-benzyl-2-dimethylamino-1-(4-morpholinophenyl)-butan-1-one, 2-benzyl-2-dimethylamino-1-(4-morpholinophenyl)butan-1-one, 4-dimethylaminoethylbenzoate, 4-dimethylaminoisoamylbenzoate, 4-diethylaminoacetophenone, 4-dimethylaminopropiophenone, 2-ethylhexyl-1,4-dimethylaminobenzoate, 2,5-bis(4-diethylaminobenzal)cyclohexanone, 7-diethylamino-3-(4-diethylaminobenzoyl)coumarin, and 4-(diethylamino)chalcone; and
oxime ester-based compounds such as 1,2-octanedione-1-[4-(phenylthio)phenyl]-2-(O-benzoyloxime)ethanone and 1-[9-ethyl-6-(2-methylbenzoyl)-9H-carbazol-3-yl]-1-(O-acetyloxime).

Among these, the oxime ester-based compounds are preferable from the viewpoint of a sensitivity and surface properties.

Since the oxime ester-based compounds have, in the structure thereof, both of a structure that absorbs ultraviolet rays, a structure that transmits light energy, and a structure that generates radicals, they have a high sensitivity in a small amount, have a maintained stability with respect to a thermal reaction, and make it possible to design a colored resin composition with a high sensitivity in a small amount. In particular, from the viewpoint of the light absorbing properties of an exposure light source with respect to i-ray (365 nm), an oxime ester-based compound having a carbazole ring, which may have a substituent, is preferable.

Examples of the oxime ester-based compounds include a compound represented by General Formula (I-1).

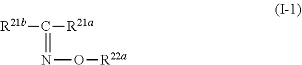

In Formula (I-1), R^{21a} represents a hydrogen atom, an alkyl group which may have a substituent, or an aromatic ring group which may have a substituent.

R^{21b} represents any substituent including an aromatic ring or a heteroaromatic ring.

R^{22a} represents an alkanoyl group which may have a substituent, or an aryloyl group which may have a substituent.

The number of carbon atoms of the alkyl group for R^{21a} is not particularly limited, but is preferably 1 or more, and more preferably 2 or more from the viewpoints of the solubility in a solvent and the sensitivity to an exposure. In addition, the number of carbon atoms is preferably 20 or less, more preferably 15 or less, still more preferably or less, and particularly preferably 5 or less. The above-described upper limits and lower limits can be combined in any manner. For example, the number of carbon atoms is preferably 1 to 20, more preferably 1 to 15, still more preferably 2 to 10, and particularly preferably 2 to 5. Examples of the alkyl group include a methyl group, an ethyl group, a propyl group, and a cyclopentylethyl group.

Examples of the substituent that the alkyl group may have include an aromatic ring group, a hydroxyl group, a carboxy group, a halogen atom, an amino group, an amide group, a 4-(2-methoxy-1-methyl)ethoxy-2-methylphenyl group, or a N-acetyl-N-acetoxyamino group, and from the viewpoint of an ease in synthesis, no substitution is preferable.

Examples of the aromatic ring group for R^{21a} include an aromatic hydrocarbon ring group and an aromatic heterocyclic group. The number of carbon atoms of the aromatic ring group is not particularly limited, but is preferably 5 or more from the viewpoint of the solubility in the colored resin composition. In addition, from the viewpoint of the developability, the number of carbon atoms is preferably 30 or less, more preferably 20 or less, still more preferably 12 or less, and particularly preferably 8 or less. For example, the number of carbon atoms is preferably 5 to 30, more preferably to 20, still more preferably 5 to 12, and particularly preferably 5 to 8.

Examples of the aromatic ring group include a phenyl group, a naphthyl group, a pyridyl group, a furyl group, and a fluorenyl group. Among these, the phenyl group, the naphthyl group, or the fluorenyl group is preferable, and the phenyl group or the fluorenyl group is more preferable from the viewpoint of the developability.

Examples of the substituent that the aromatic ring group may have include a hydroxyl group, an alkyl group which may have a substituent, an alkoxy group which may have a substituent, a carboxy group, a halogen atom, an amino group, an amide group, and an alkyl group, and from the viewpoint of the developability, the hydroxyl group and the carboxy group are preferable, and the carboxy group is more preferable. In addition, examples of the substituent in the alkyl group which may have a substituent and the alkoxy group which may have a substituent include a hydroxyl group, an alkoxy group, a halogen atom, and a nitro group.

Among these, R^{21a} is preferably the alkyl group which may have a substituent, more preferably the unsubstituted alkyl group, and still more preferably a methyl group from the viewpoint of the developability.

R^{21b} is any substituent including an aromatic ring or a heteroaromatic ring, but from the viewpoints of the solubility in a solvent and the sensitivity to an exposure, preferred examples of the substituent include a carbazolyl group which may have a substituent, a thioxanthyl group which may have a substituent, a diphenyl sulfide group which may have a substituent, a fluorenyl group which may have a substituent, and a group in which these groups are linked to a carbonyl group. Among these, the carbazolyl group which may have a substituent, or a group in which the carbazolyl group which may have a substituent and a carbonyl group may be linked to each other is preferable from the viewpoint of the light absorption properties of an exposure light source with respect to i-ray (365 nm).

The number of carbon atoms of the alkanoyl group for R^{22a} is not particularly limited, but is preferably 2 or more, and more preferably 3 or more from the viewpoints of the solubility in a solvent and the sensitivity. In addition, the number of carbon atoms is preferably 20 or less, more preferably 15 or less, still more preferably 10 or less, and particularly preferably 5 or less. The above-described upper limits and lower limits can be combined in any manner. For example, the number of carbon atoms is preferably 2 to 20, more preferably 2 to 15, still more preferably 3 to 10, and particularly preferably 3 to 5. Examples of the alkanoyl group include an acetyl group, a propanoyl group, and a butanoyl group.

Examples of the substituent that the alkanoyl group may have include an aromatic ring group, a hydroxyl group, a carboxy group, a halogen atom, an amino group, and an amide group, and from the viewpoint of an ease in synthesis, no substitution is preferable.

The number of carbon atoms of the aryloyl group for R^{22a} is not particularly limited, but is preferably 7 or more, and more preferably 8 or more from the viewpoints of the solubility in a solvent and the sensitivity. In addition, the number of carbon atoms is preferably 20 or less, more preferably 15 or less, and still more preferably 10 or less. The above-described upper limits and lower limits can be combined in any manner. For example, the number of carbon atoms is preferably 7 to 20, more preferably 7 to 15, and still more preferably 8 to 10. Examples of the aryloyl group include a benzoyl group and a naphthyl group.

Examples of the substituent that the aryloyl group may have include a hydroxyl group, a carboxy group, a halogen atom, an amino group, an amide group, and an alkyl group, and from the viewpoint of an ease in synthesis, no substitution is preferable.

Among the compounds represented by Formula (I-1), a compound represented by General Formula (I-2) or (I-3) may be mentioned from the viewpoint of the light absorbing properties of an exposure light source with respect to i-ray (365 nm).

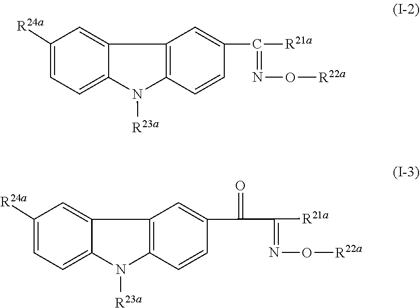

In Formula (I-2) or (I-3), R^{21a} and R^{22a} each have the same definitions as those in Formula (I-1).

R^{23a} represents an alkyl group which may have a substituent.

R^{24a} represents an alkyl group which may have a substituent, an aryloyl group which may have a substituent, a heteroaryl group which may have a substituent, or a nitro group.

The benzene ring constituting the carbazole ring may be further fused with an aromatic ring to form a polycyclic aromatic ring.

The number of carbon atoms of the alkyl group for R^{23a} or R^{24a} is not particularly limited, but is preferably 1 or more, and more preferably 2 or more from the viewpoint of the solubility in a solvent. In addition, the number of carbon atoms is preferably 20 or less, more preferably 15 or less, still more preferably 10 or less, and particularly preferably 5 or less. The above-described upper limits and lower limits can be combined in any manner. For example, the number of carbon atoms is preferably 1 to 20, more preferably 1 to 15, still more preferably 2 to 10, and particularly preferably 2 to 5. Examples of the alkyl group include a methyl group, an ethyl group, a propyl group, a butyl group, and a cyclohexyl group.

Examples of the substituent that the alkyl group may have include a carboxy group, a hydroxy group, a phenyl group, a benzyl group, a cyclohexyl group, or a nitro group, and from the viewpoint of an ease in synthesis, no substitution is preferable.

Among these, the alkyl group is preferable, and an ethyl group is more preferable as R^{23a} from the viewpoints of the solubility in a solvent and an ease in synthesis.

The number of carbon atoms of the aryloyl group for R^{24a} is not particularly limited, but is preferably 7 or more, more preferably 8 or more, and still more preferably 9 or more from the viewpoint of the solubility in a solvent. In addition, the number of carbon atoms is preferably 20 or less, more preferably 15 or less, still more preferably 10 or less, and particularly preferably 9 or less. The above-described upper limits and lower limits can be combined in any manner. For example, the number of carbon atoms is preferably 7 to 20, more preferably 8 to 15, still more preferably 9 to 10, and particularly preferably 9. Examples of the aryloyl group include a benzoyl group and a naphthyl group.

Examples of the substituent that the aryloyl group may have include a carboxy group, a hydroxy group, a phenyl group, a benzyl group, a cyclohexyl group, or a nitro group, and from the viewpoint of an ease in synthesis, an ethyl group is preferable.

The number of carbon atoms of the heteroaryl group for R^{24a} is not particularly limited, but is preferably 7 or more, more preferably 8 or more, and still more preferably 9 or more from the viewpoint of the solubility in a solvent. In addition, the number of carbon atoms is preferably 20 or less, more preferably 15 or less, still more preferably 10 or less, and particularly preferably 9 or less. The above-described upper limits and lower limits can be combined in any manner. For example, the number of carbon atoms is preferably 7 to 20, more preferably 8 to 15, still more preferably 9 to 10, and particularly preferably 9. Examples of the heteroaryloyl group include a furancarbonyl group, a thiophenecarbonyl group, a pyrroylcarbonyl group, and a pyridinecarbonyl group.

Examples of the substituent that the heteroaryl group may have include a carboxy group, a hydroxy group, a phenyl group, a benzyl group, a cyclohexyl group, or a nitro group, and from the viewpoint of an ease in synthesis, no substitution is preferable.

The benzene ring constituting the carbazole ring may be further fused with an aromatic ring to form a polycyclic aromatic ring.

Examples of commercially available products of such oxime ester-based compounds include OXE-02 and OXE-03 manufactured by BASF SE, TR-PBG-304 and TR-PBG-314 manufactured by Changzhou Tronly New Electronic Materials Co., Ltd., or N-1919, NCI-930, and NCI-831 manufactured by ADEKA Corporation.

Examples of the oxime ester-based compounds include the following compounds.

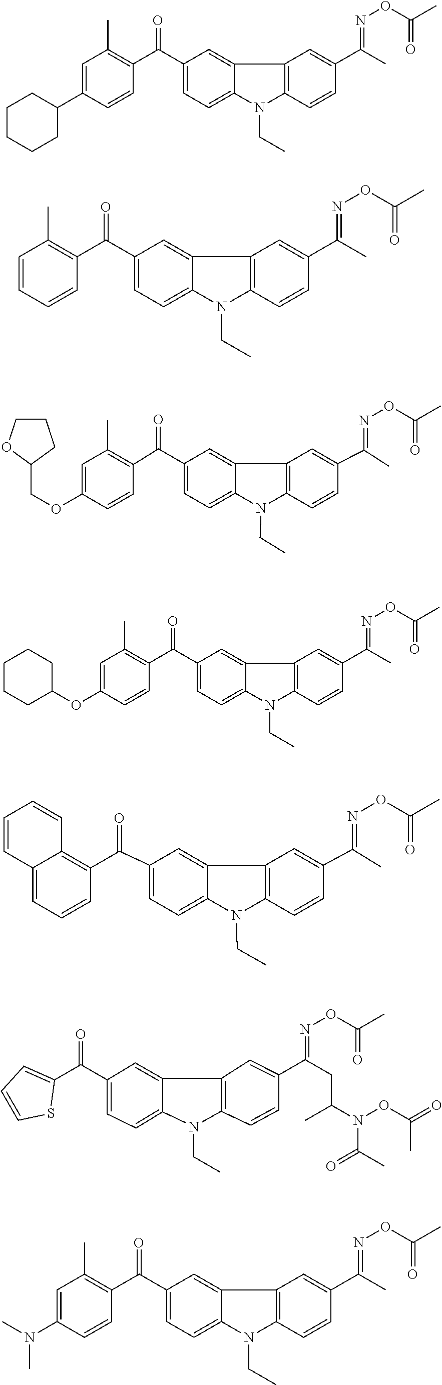

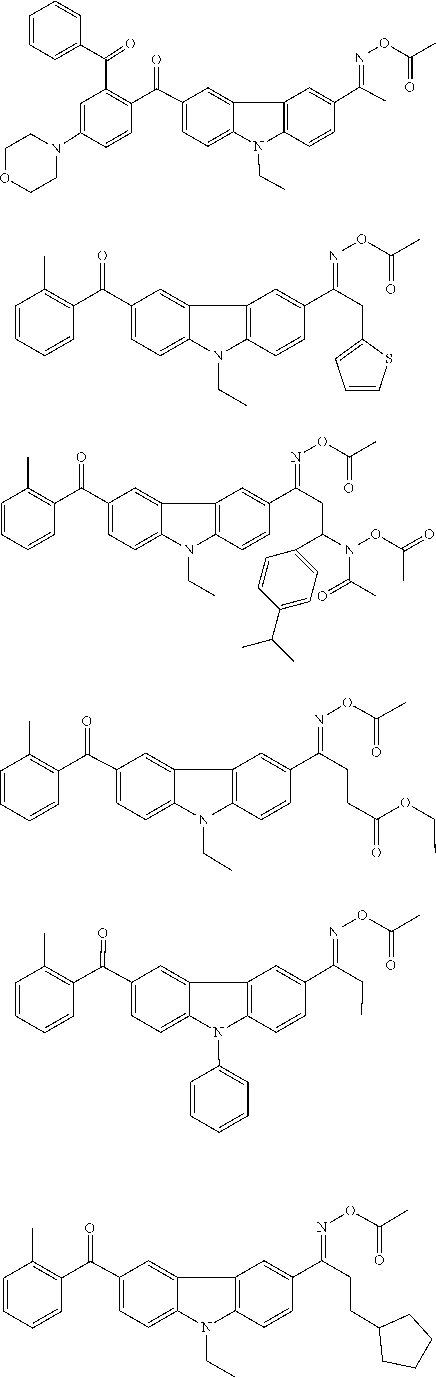 [SMILES: CCn1c2ccc(C(=O)c3ccc(N4CCOCC4)cc3C(=O)c3ccccc3)cc2c2cc(/C(C)=N/OC(C)=O)ccc21 ; CCn1c2ccc(C(=O)c3ccccc3C)cc2c2cc(/C(Cc3cccs3)=N/OC(C)=O)ccc21 ; CCn1c2ccc(C(=O)c3ccccc3C)cc2c2cc(/C(CC(c3ccc(C(C)C)cc3)N(OC(C)=O)C(C)=O)=N/OC(C)=O)ccc21 ; CCOC(=O)CC/C(=N\OC(C)=O)c1ccc2c(c1)c1cc(C(=O)c3ccccc3C)ccc1n2CC ; CC/C(=N\OC(C)=O)c1ccc2c(c1)c1cc(C(=O)c3ccccc3C)ccc1n2-c1ccccc1 ; CCn1c2ccc(C(=O)c3ccccc3C)cc2c2cc(/C(CCC3CCCC3)=N/OC(C)=O)ccc21]

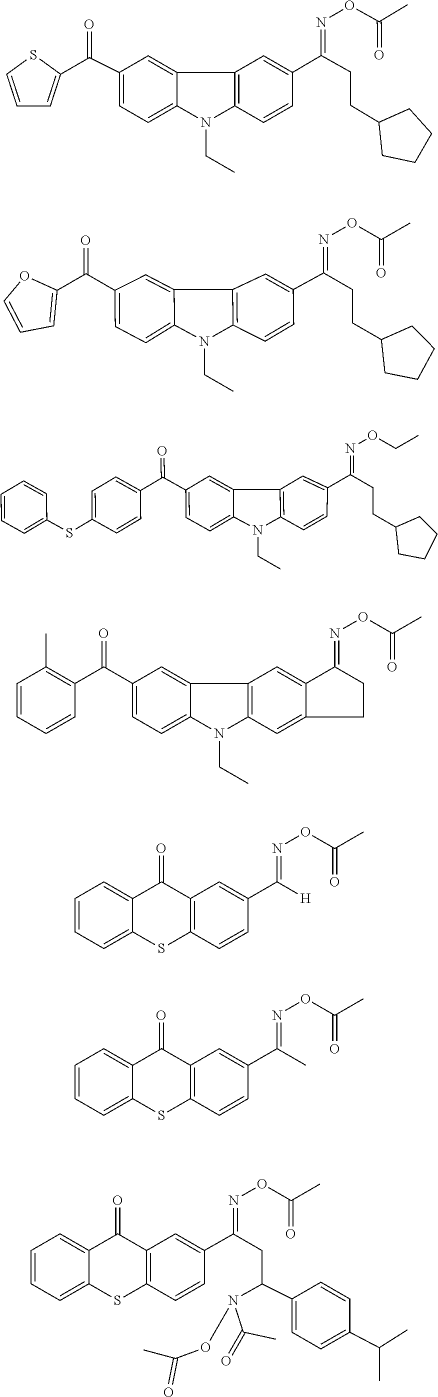

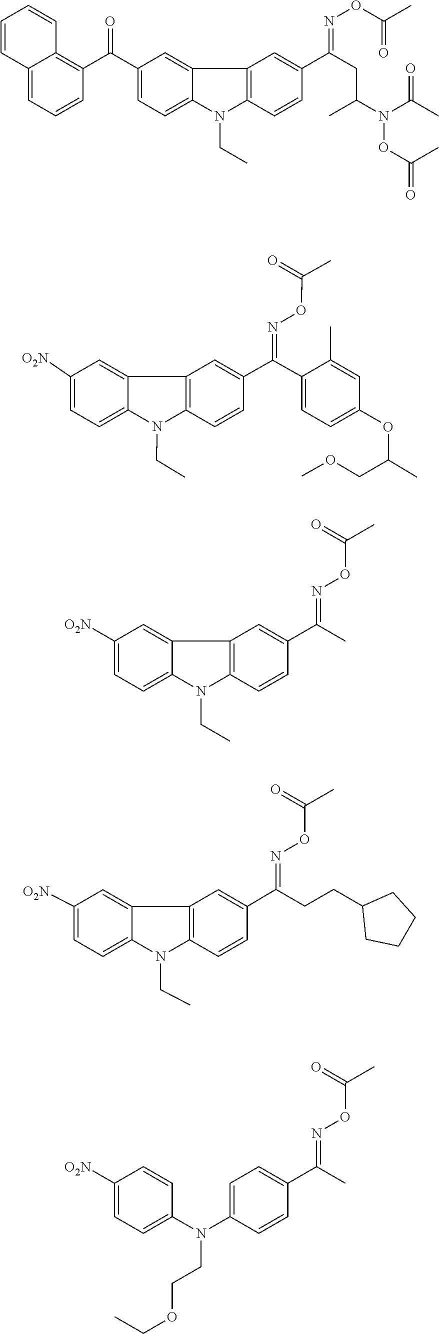 [SMILES: CCn1c2ccc(C(=O)c3cccc4ccccc34)cc2c2cc(/C(CC(C)N(OC(C)=O)C(C)=O)=N/OC(C)=O)ccc21 ; CCn1c2ccc(/C(=N/OC(C)=O)c3ccc(OC(C)COC)cc3C)cc2c2cc([N+](=O)[O-])ccc21 ; CCn1c2ccc(/C(C)=N/OC(C)=O)cc2c2cc([N+](=O)[O-])ccc21 ; CCn1c2ccc(/C(CCC3CCCC3)=N/OC(C)=O)cc2c2cc([N+](=O)[O-])ccc21 ; CCOCCN(c1ccc(/C(C)=N/OC(C)=O)cc1)c1ccc([N+](=O)[O-])cc1]

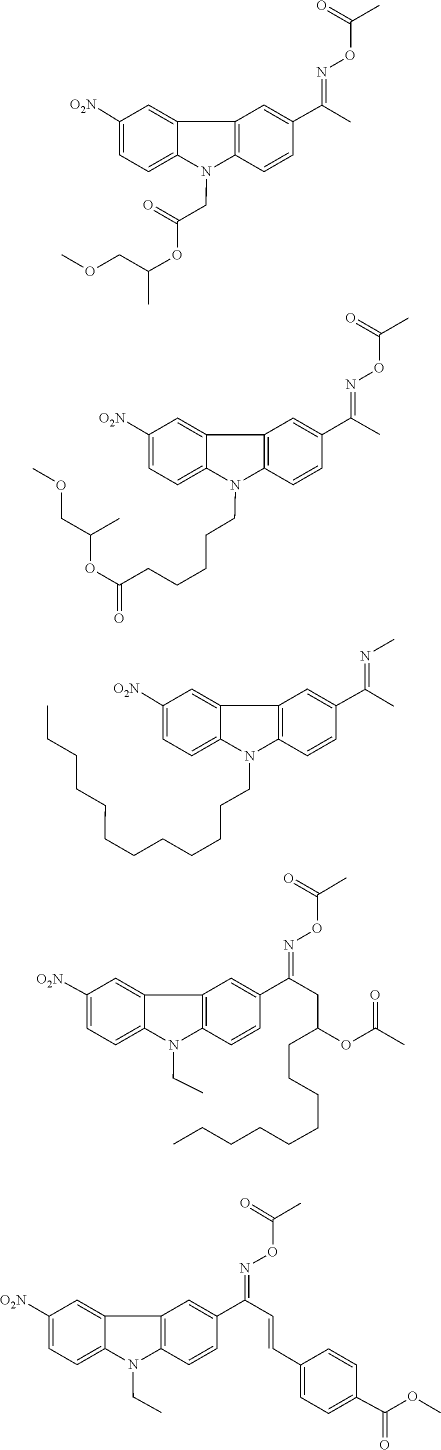

These photopolymerization initiators may be used alone or in a mixture of two or more kinds thereof.

A chain transfer agent may be used in addition to the photopolymerization initiator (D). The chain transfer agent is a compound having a function of receiving a generated radical and transferring the received radical to another compound.

When the chain transfer agent is a compound having the function, various chain transfer agents can be used as the chain transfer agent, but examples thereof include a mercapto group-containing compound and carbon tetrachloride. Since bond cleavage is likely to occur due to the small S—H bond energy, and a hydrogen abstraction reaction or a chain transfer reaction is likely to occur, there is a tendency that the chain transfer effect tends to be high. Therefore, a mercapto group-containing compound is more preferably used.

The mercapto group-containing compound is effective in improving the sensitivity and the surface curability.

Examples of the mercapto group-containing compound include mercapto group-containing compounds having an aromatic ring, such as 2-mercaptobenzothiazole, 2-mercaptobenzimidazole, 2-mercaptobenzoxazole, 3-mercapto-1,2,4-triazole, 2-mercapto-4(3H)-quinazoline, β-mercaptonaphthalene, and 1,4-dimethylmercaptobenzene; and aliphatic mercapto group-containing compounds such as hexanedithiol, decanedithiol, butanediol bis(3-mercaptopropionate), butanediol bisthioglycolate, ethylene glycol bis(3-mercaptopropionate), ethylene glycol bisthioglycolate, trimethylolpropane tris(3-mercaptopropionate), trimethylolpropane tristhioglycolate, trishydroxyethyltristhiopropionate, pentaerythritol tetrakis(3-mercaptopropionate), pentaerythritol tris(3-mercaptopropionate), butanediol bis(3-mercaptobutyrate), ethylene glycol bis(3-mercaptobutyrate), trimethylolpropane tris(3-mercaptobutyrate), pentaerythritol tetrakis(3-mercaptobutyrate), pentaerythritol tris(3-mercaptobutyrate), and 1,3,5-tris(3-mercaptobutyloxyethyl)-1,3,5-triazine-2,4,6(1H,3H,5H)-trione. In particular, from the viewpoint of a surface smoothness, the compound having a plurality of mercapto groups is preferable.

Among these, 2-mercaptobenzothiazole and 2-mercaptobenzimidazole are preferable among the mercapto group-containing compounds having an aromatic ring, and trimethylolpropane tris(3-mercaptopropionate), pentaerythritol tetrakis(3-mercaptopropionate), pentaerythritol tris(3-mercaptopropionate), trimethylolpropane tris(3-mercaptobutyrate), pentaerythritol tetrakis(3-mercaptobutyrate), pentaerythritol tris(3-mercaptobutyrate), and 1,3,5-tris(3-mercaptobutyloxyethyl)-1,3,5-triazine-2,4,6 (1H,3H,5H)-trione are preferable among the aliphatic mercapto group-containing compounds.

In addition, from the viewpoint of a sensitivity, the aliphatic mercapto group-containing compounds are preferable, and specifically, trimethylolpropane tris(3-mercaptopropionate), pentaerythritol tetrakis(3-mercaptopropionate), pentaerythritol tris(3-mercaptopropionate), trimethylolpropane tris(3-mercaptobutyrate), pentaerythritol tetrakis(3-mercaptobutyrate), pentaerythritol tris(3-mercaptobutyrate), 1,3,5-tris(3-mercaptobutyloxyethyl)-1,3,5-triazine-2,4,6(1H,3H,5H)-trione are preferable, and pentaerythritol tetrakis(3-mercaptopropionate) and pentaerythritol tetrakis(3-mercaptobutyrate) are more preferable.

These may be used alone or in combination of two or more kinds thereof.

In the colored resin composition of the present invention, the content proportion of the photopolymerization initiator (D) is not particularly limited, but when the colored resin composition includes the photopolymerization initiator (D), the content proportion of the photopolymerization initiator (D) is preferably 1% by mass or more, more preferably 2% by mass or more, still more preferably 3% by mass or more, even still more preferably 4% by mass or more, particularly preferably 6% by mass or more, and most preferably 7% by mass or more in the total solid content of the colored resin composition. In addition, the content proportion is preferably 20% by mass or less, more preferably 15% by mass or less, still more preferably 12% by mass or less, and particularly preferably 10% by mass or less. By setting the content proportion to the lower limit value or more, there is a tendency that patterning characteristics after development can be secured, and by setting the content proportion to the upper limit value or less, there is a tendency that a decrease in transmittance due to the excessive addition of the photopolymerization initiator is suppressed.

The above-described upper limits and lower limits can be combined in any manner. For example, the content proportion of the photopolymerization initiator (D) is preferably 1% to 20% by mass, more preferably 2% to 20% by mass, still more preferably 3% to 15% by mass, even still more preferably 4% to 15% by mass, particularly preferably 6% to 12% by mass, and most preferably 7% to 10% by mass.

When the colored resin composition of the present invention includes a chain transfer agent, a content proportion thereof is not particularly limited, but is preferably 0.01% by mass or more, more preferably 0.1% by mass or more, still more preferably 0.2% by mass or more, even still more preferably 0.5% by mass or more, further more preferably 1% by mass or more, and particularly preferably 1.5% by mass or more in the total solid content of the colored resin composition. In addition, the content proportion is preferably 5% by mass or less, more preferably 3% by mass or less, and still more preferably 2% by mass or less. By setting it to be within the ranges, there is a tendency that storage stability and pattern forming performance during alkali development can be secured.

The above-described upper limits and lower limits can be combined in any manner. For example, the content proportion thereof is preferably 0.01% to 5% by mass, more preferably 0.1% to 5% by mass, still more preferably 0.2% to 3% by mass, even still more preferably 0.5% to 3% by mass, further more preferably 1% to 2% by mass, and particularly preferably 1.5% to 2% by mass.

### 1-4-2 Photopolymerizable Monomer

The colored resin composition of the present invention may contain a photopolymerizable monomer.

The photopolymerizable monomer is not particularly limited as long as it is a polymerizable low-molecular-weight compound, but an addition-polymerizable compound having at least one ethylenic double bond (hereinafter referred to as an “ethylenic compound”) is preferable. The ethylenic compound refers to a compound having an ethylenic double bond, which is capable of being addition-polymerized and cured by an action of a photopolymerization initiator when the colored resin composition of the present invention is irradiated with active rays. Furthermore, the monomer in the present invention means a notion relative to a so-called high-molecular-weight substance, and means a notion of also containing a dimer, a trimer, and an oligomer in addition to a monomer in a narrow sense.

In the present invention, in particular, it is desirable to use a polyfunctional ethylenic monomer having two or more ethylenic double bonds in one molecule. The number of the ethylenic double bonds in the polyfunctional ethylenic monomer is not particularly limited, but is preferably 2 or more, more preferably 4 or more, and still more preferably 5 or more. In addition, the number of the ethylenic double bonds is preferably 8 or less, and more preferably 7 or less. The above-described upper limits and lower limits can be combined in any manner. For example, the number of the ethylenic double bonds is preferably 2 to 8, more preferably 4 to 8, and still more preferably 5 to 7. By setting the number of the ethylenic double bonds to the lower limit value or more, there is a tendency that the sensitivity is high. By setting the number of the ethylenic double bonds to the upper limit value or less, there is a tendency that the solubility in a solvent is improved.

Examples of the ethylenic compound include an unsaturated carboxylic acid, an ester of an unsaturated carboxylic acid with a monohydroxy compound, an ester of an aliphatic polyhydroxy compound with an unsaturated carboxylic acid, an ester of an aromatic polyhydroxy compound with an unsaturated carboxylic acid, an ester obtained by an esterification reaction of an unsaturated carboxylic acid with a polyvalent carboxylic acid and a polyvalent hydroxy compound such as the above-described aliphatic polyhydroxy compound and an aromatic polyhydroxy compound, and an ethylenic compound having a urethane skeleton obtained by reacting a polyisocyanate compound with a (meth)acryloyl-containing hydroxy compound.

Examples of the ester of the aliphatic polyhydroxy compound with the unsaturated carboxylic acid include acrylic acid esters such as ethylene glycol diacrylate, triethylene glycol diacrylate, trimethylolpropane triacrylate, trimethylolethane triacrylate, pentaerythritol diacrylate, pentaerythritol triacrylate, pentaerythritol tetraacrylate, dipentaerythritol tetraacrylate, dipentaerythritol pentaacrylate, dipentaerythritol hexaacrylate, and glycerol acrylate. Additional examples thereof include a methacrylic acid ester obtained by replacing the acrylic acid portion of the acrylate with a methacrylic acid portion, an itaconic acid ester obtained by replacing the acrylic acid portion of the acrylate with an itaconic acid portion, a crotonic acid ester obtained by replacing obtained by replacing the acrylic acid portion of the acrylate with a crotonic acid portion, and a maleic acid ester obtained by replacing obtained by replacing the acrylic acid portion of the acrylate with a maleic acid portion.

Examples of the ester of the aromatic polyhydroxy compound with the unsaturated carboxylic acid include hydroquinone diacrylate, hydroquinone dimethacrylate, resorcin diacrylate, resorcin dimethacrylate, and pyrogallol triacrylate. The ester obtained by the esterification reaction of the unsaturated carboxylic acid with the polyvalent carboxylic acid and the polyvalent hydroxy compound is not necessarily a single substance and may be a mixture. Typical examples thereof include a fused product of acrylic acid, phthalic acid, and ethylene glycol, a fused product of acrylic acid, maleic acid, and diethylene glycol, a fused product of methacrylic acid, terephthalic acid, and a fused product of pentaerythritol, acrylic acid, adipic acid, butanediol, and glycerin.

Examples of the ethylenic compound having a urethane skeleton obtained by reacting a polyisocyanate compound with a (meth)acryloyl group-containing hydroxy compound include aliphatic diisocyanates such as hexamethylene diisocyanate and trimethyl hexamethylene diisocyanate; alicyclic diisocyanates such as cyclohexane diisocyanate and isophorone diisocyanate; and reaction products of aromatic diisocyanates such as tolylene diisocyanate and diphenylmethane diisocyanate with (meth)acryloyl group-containing hydroxy compounds such as 2-hydroxyethyl acrylate, 2-hydroxyethyl methacrylate, 3-hydroxy(1,1,1-triacryloyloxymethyl)propane, and 3-hydroxy(1,1,1-trimethacryloyloxymethyl)propane.

In addition, as the ethylenic compound used in the present invention, for example, acrylamides such as ethylenebisacrylamide; allyl esters such as diaryl phthalate; and vinyl group-containing compounds such as divinyl phthalate are also useful.

The ethylenic compound may be a monomer having an acid value. The monomer having an acid value is preferably an ester of an aliphatic polyhydroxy compound with an unsaturated carboxylic acid, which is a polyfunctional monomer having an acid group obtained by reacting a non-aromatic carboxylic anhydride with an unreacted hydroxyl group of an aliphatic polyhydroxy compound, and particularly preferably an ester of an aliphatic polyhydroxy compound with an unsaturated carboxylic acid, which is a polyfunctional monomer having an acid group obtained by reacting a non-aromatic carboxylic anhydride with an unreacted hydroxyl group of pentaerythritol and/or dipentaerythritol.

These monomers may be used alone, but from the viewpoint that it is less likely to use a single compound in terms of production, two or more kinds of the monomers may be mixed and used.

As necessary, a polyfunctional monomer having no acid group and a polyfunctional monomer having an acid group may be used in combination.

A preferred acid value of the polyfunctional monomer having an acid group is 0.1 to 40 mgKOH/g, and particularly preferably 5 to 30 mgKOH/g. By setting the acid value to the lower limit value or more, there is a tendency that the development and the dissolution characteristics can be favorable. By setting the acid value to the upper limit value or less, there is a tendency that the production and the handling are favorable, and curability such as photopolymerization performance and surface smoothness of a pixel are likely to be favorable. Accordingly, when two or more kinds of polyfunctional monomers having different acid groups are used in combination, or when a polyfunctional monomer having no acid group is used in combination, it is preferable that an acid group as the entire polyfunctional monomer is adjusted to be within the ranges.

When the colored resin composition of the present invention includes a photopolymerizable monomer, it is preferable that the colored resin composition contains a photopolymerizable monomer having a partial structure represented by General Formula (9), and in particular, when the colorant (A) includes the compound represented by Formula (8), it is preferable that the colored resin composition contains a photopolymerizable monomer having a partial structure represented by General Formula (9).

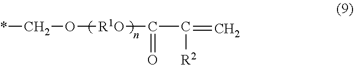

In Formula (9), R¹ represents an alkylene group having 2 or more carbon atoms;
R² represents a hydrogen atom or a methyl group;
n represents an integer of 1 or more, and
* represents a binding site.

### R¹

In Formula (9), R¹ represents an alkylene group having 2 or more carbon atoms. The alkylene group has no substituent.

The alkylene group may be linear, branched, or cyclic, or in combination of these. From the viewpoints of the solvent solubility and the solvent resistance, the linear alkylene group is preferable.

The number of carbon atoms of the alkylene group is not particularly limited as long as it has 2 or more carbon atoms, but the number of carbon atoms is preferably 4 or less, more preferably 3 or less, and still more preferably 2. By setting the number of carbon atoms to the upper limit value or less, there is a tendency that the coating film sensitivity and the solvent resistance are improved. For example, the number of carbon atoms of the alkylene group is preferably 2 to 4, more preferably 2 to 3, and still more preferably 2.

Examples of the alkylene group include an ethylene group, an n-propylene group, an n-butylene group, and an isopropylene group. From the viewpoint of the coating film curability, the ethylene group or the n-propylene group is preferable, and the ethylene group is more preferable.

n

In Formula (9), n represents an integer of 1 or more, and is preferably 4 or less, more preferably 3 or less, and still more preferably 2 or less. By setting the number of carbon atoms to the upper limit value or less, there is a tendency that the coating film curability is improved. For example, n is preferably 1 to 4, more preferably 1 to 3, and still more preferably 1 or 2.

When the colored resin composition of the present invention includes a photopolymerizable monomer, from the viewpoint of the coating film curability, it is more preferable that the colored resin composition contains a photopolymerizable monomer having a partial structure represented by General Formula (10).

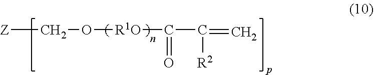

In Formula (10), R¹ represents an alkylene group having 2 or more carbon atoms.
R² represents a hydrogen atom or a methyl group,
n represents an integer of 1 or more,
Z is a direct bond, an oxygen atom, a sulfur atom, a divalent to tetravalent aliphatic hydrocarbon group, a tetravalent carbon atom, a divalent to tetravalent non-aromatic heterocyclic group, a divalent to tetravalent aromatic ring group, or a partial structure represented by General Formula (12),
p represents an integer of 2 to 6, and a plurality of structures represented by General Formula (11), which are included in one molecule, may each independently have the same structure or may be different structures,
R¹, R², and n in Formula (11) each have the same definitions as R¹, R², and n in Formula (10), and * represents a binding site, and * in Formula (12) represents a binding site.

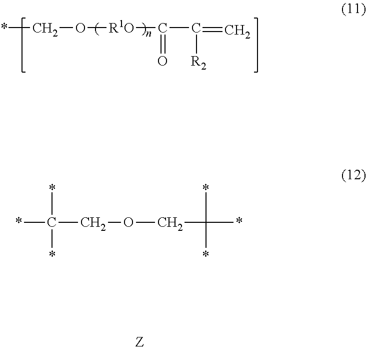

In Formula (10), X is a direct bond, an oxygen atom, a sulfur atom, a divalent to tetravalent aliphatic hydrocarbon group, a tetravalent carbon atom, a divalent to tetravalent non-aromatic heterocyclic group, a divalent to tetravalent aromatic ring group, or a partial structure represented by Formula (10).

The divalent to tetravalent aliphatic hydrocarbon group may be linear, branched, cyclic, or in combination of these. The number of carbon atoms of the divalent to tetravalent aliphatic hydrocarbon group is not particularly limited, but is preferably 10 or less, more preferably 9 or less, and still more preferably 8 or less. In addition, the number of carbon atoms is preferably 1 or more. By setting the number of carbon atoms to the upper limit value or less, there is a tendency that the coating film curability is improved and the solvent resistance is improved. For example, the number of carbon atoms of the divalent to tetravalent aliphatic hydrocarbon group is preferably 1 to 10, more preferably 1 to 9, and still more preferably 1 to 8.

Examples of the divalent to tetravalent aliphatic hydrocarbon groups include methane, ethane, propane, and butane, each of which has 2 to 4 free valences.

The non-aromatic heterocyclic ring in the divalent to tetravalent non-aromatic heterocyclic group may be a monocyclic ring or a fused ring. The non-aromatic heterocyclic ring is a non-aromatic ring including any one of a nitrogen atom, a sulfur atom, and an oxygen atom as a heteroatom. When a plurality of heteroatoms are included in the non-aromatic heterocyclic ring, they may be the same as or different from each other.

The number of carbon atoms of the divalent to tetravalent non-aromatic heterocyclic group is not particularly limited, but is preferably 3 or more, and more preferably 4 or more. In addition, the number of carbon atoms is preferably 8 or less and more preferably 6 or less. By setting the number of carbon atoms to the lower limit value or more, there is a tendency that the heat resistance is improved, and by setting the number of carbon atoms to the upper limit value or less, there is a tendency that the solubility in a solvent is improved. The above-described upper limits and lower limits can be combined in any manner. For example, the number of carbon atoms of the divalent to tetravalent non-aromatic heterocyclic group is preferably 3 to 8, more preferably 3 to 6, and still more preferably 4 to 6.

Examples of the divalent to tetravalent non-aromatic heterocyclic groups include a piperidine ring and a pyrrolidine ring, each of which has 2 to 4 free valences.

Examples of the divalent to tetravalent aromatic ring groups include divalent to tetravalent aromatic hydrocarbon ring groups and divalent to tetravalent aromatic heterocyclic groups.

The aromatic hydrocarbon ring in the divalent to tetravalent aromatic hydrocarbon ring groups may be a monocyclic ring or a fused ring. The number of carbon atoms of the aromatic hydrocarbon ring group is not particularly limited, but is preferably 3 or more, more preferably 4 or more, and still more preferably 5 or more. In addition, the number of carbon atoms is preferably 15 or less, more preferably 12 or less, and still more preferably 9 or less. By setting the number of carbon atoms to the lower limit value or more, there is a tendency that the heat resistance is improved, and by setting the number of carbon atoms to the upper limit value or less, there is a tendency that the luminance is improved. The above-described upper limits and lower limits can be combined in any manner. For example, the number of carbon atoms of the divalent to tetravalent aromatic hydrocarbon ring groups is preferably 3 to 15, more preferably 4 to 12, and still more preferably 5 to 9.

Examples of the divalent to tetravalent aromatic hydrocarbon ring groups include a benzene ring, a naphthalene ring, an anthracene ring, a phenanthrene ring, a perylene ring, a tetracene ring, a pyrene ring, a benzopyrene ring, a chrysene ring, a triphenylene ring, an acenaphthene ring, a fluoranthene ring, and a fluorene ring, each of which has 2 to 4 free valences.

The aromatic heterocyclic ring in the divalent to tetravalent aromatic heterocyclic groups may be a monocyclic ring or a fused ring. The number of carbon atoms of the aromatic heterocyclic group is not particularly limited, but is preferably 3 or more, more preferably 4 or more, and still more preferably 5 or more. In addition, the number of carbon atoms is preferably 15 or less, more preferably 12 or less, and still more preferably 9 or less. By setting the number of carbon atoms to the lower limit value or more, there is a tendency that the heat resistance is improved, and by setting the number of carbon atoms to the upper limit value or less, there is a tendency that the luminance is improved. The above-described upper limits and lower limits can be combined in any manner. For example, the number of carbon atoms of the divalent to tetravalent aromatic heterocyclic groups is preferably 3 to 15, more preferably 4 to 12, and still more preferably 5 to 9.

Examples of the divalent to tetravalent aromatic heterocyclic groups include a furan ring, a benzofuran ring, a thiophene ring, a benzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzisoxazole ring, a benzisothiazole ring, a benzimidazole ring, a pyridine ring, a pyrazine ring, a pyridazine ring, a pyrimidine ring, a triazine ring, a quinoline ring, an isoquinoline ring, a cinnoline ring, a quinoxaline ring, a phenanthridine ring, a perimidine ring, a quinazoline ring, a quinazolinone ring, and an azulene ring, each of which has 2 to 4 free valences.

From the viewpoints of the curability and the patterning characteristics, Z is preferably the oxygen atom, the sulfur atom, or the tetravalent carbon atom, and more preferably the tetravalent carbon atom.

p

In Formula (10), p represents an integer of 2 to 6. p is preferably 3 or more, and preferably 5 or less, and more preferably 4 or less. By setting p to the lower limit value or more, there is a tendency that the electrical reliability is improved, and by setting p to the upper limit value or less, there is a tendency that the coating film curability is improved. The above-described upper limits and lower limits can be combined in any manner. For example, p is preferably 3 to 5, and more preferably 3 or 4.

Examples of the photopolymerizable monomer having a partial structure represented by General Formula (9) include the following monomers.

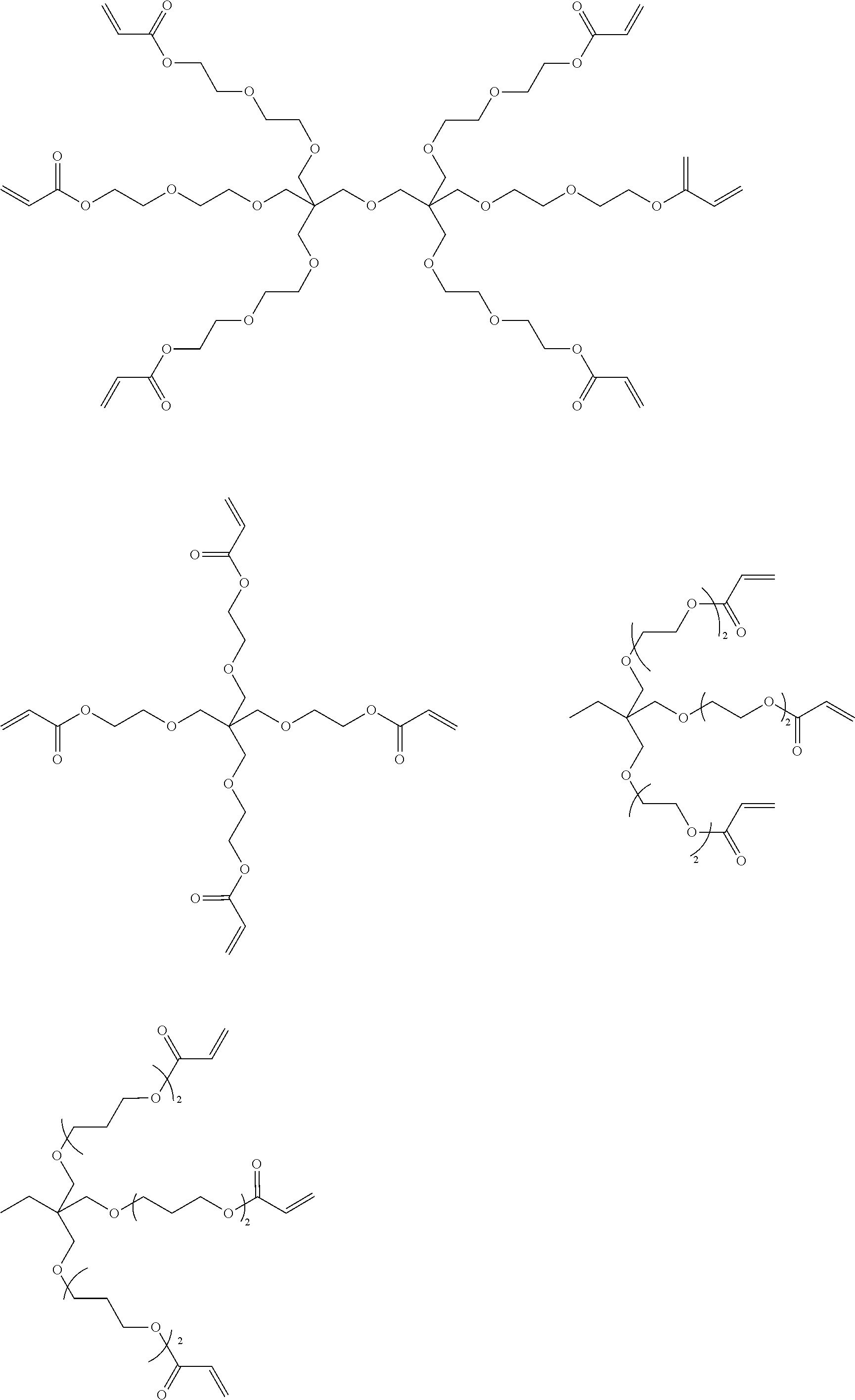

When the colored resin composition of the present invention includes a photopolymerizable monomer, a mixture of dipentaerythritol hexaacrylate and dipentaerythritol pentaacrylate (for example, A-9550 manufactured by Shin-Nakamura Chemical Co., Ltd.), trimethylolpropane triacrylate (for example, Light Acrylate TMP-A manufactured by Kyoeisha Chemical Co., Ltd.), or a monomer with a urethane skeleton in which hexamethylene diisocyanate is bonded to dipentaerythritol pentaacrylate (for example, DPHA-40H manufactured by Nippon Kayaku Co., Ltd.) is preferably used.

A combination of these polyfunctional monomers and other polyfunctional monomers can also be used.

In addition, the polyfunctional monomers described in paragraphs 0056 and 0057 of Japanese Unexamined Patent Application, First Publication No. 2013-140346 can also be used.

In the present invention, from the viewpoint of improving the chemical resistance of a pixel and the straightness of an edge of the pixel, it is preferable to use the polymerizable monomers described in Japanese Unexamined Patent Application, First Publication No. 2013-195971. From the viewpoint of achieving both the sensitivity of a coating film and the shortening of a developing time, it is preferable to use the polymerizable monomers described in Japanese Unexamined Patent Application, First Publication No. 2013-195974.

When the colored resin composition of the present invention includes a photopolymerizable monomer, a content proportion of the photopolymerizable monomer is not particularly limited, but is preferably 1% by mass or more, more preferably 5% by mass or more, still more preferably 8% by mass or more, even still more preferably 10% by mass or more, and particularly preferably 12% by mass or more in the total solid content of the colored resin composition. In addition, the content proportion is preferably 60% by mass or less, more preferably 50% by mass or less, still more preferably 45% by mass or less, and particularly preferably 40% by mass or less. By setting the content proportion to the lower limit value or more, there is a tendency that the curability of the coating film is improved. By setting the content proportion to the upper limit value or less, there is a tendency that the flatness of the coating film surface can be ensured. In addition, when the colorant (A) includes the compound represented by General Formula (8), the content proportion of the compound is preferably 60% by mass or less, more preferably 40% by mass or less, still more preferably 20% by mass or less, and particularly preferably 10% by mass or less from the viewpoint of improving the visible shielding properties of the coating film.

The above-described upper limits and lower limits can be combined in any manner. For example, the content proportion of the photopolymerizable monomer in the total solid content of the colored resin composition is preferably 1% to 60% by mass, more preferably 5% to 60% by mass, still more preferably 8% to 50% by mass, even still more preferably 10% to 45% by mass, and particularly preferably 12% to 40% by mass.

### 1-4-3 Dispersant and Dispersion Aid

When the colored resin composition of the present invention includes a pigment as the colorant (A), it preferably includes a dispersant for the purpose of stably dispersing the pigment. When a polymer dispersant among the dispersants is used, the dispersion stability over time is excellent, which is thus preferable.

Examples of the polymer dispersant include a urethane-based dispersant, a polyethyleneimine-based dispersant, a polyoxyethylene alkyl ether-based dispersant, a polyoxyethylene glycol diester-based dispersant, a sorbitan aliphatic ester-based dispersant, and an aliphatic modified polyester-based dispersant. Examples of product names of these dispersants include the dispersants described in Japanese Unexamined Patent Application, First Publication No. 2013-119568, as well as EFKA (registered trademark, manufactured by BASF SE), DisperBYK (registered trademark, manufactured by BYK Chemie GmbH), DISPARLON (registered trademark, manufactured by obtained by Nagamoto Chemicals Co., Ltd.), SOLSPERSE (registered trademark, manufactured by The Lubrizol Corporation), KP (manufactured by Shin-Etsu Chemical Co., Ltd.), and Polyflow (manufactured by Kyoeisha Chemical Co., Ltd.).

Among the polymer dispersants, a block copolymer having a functional group including a nitrogen atom is preferable, and an acrylic block copolymer is more preferable from the viewpoints of the dispersibility and the storage stability.

As the block copolymer having a functional group including a nitrogen atom, an A-B block copolymer and/or a B-A-B block copolymer, consisting of an A block having a quaternary ammonium base and/or an amino group in the side chain, and a B block not having a quaternary ammonium base and/or an amino group, is preferable.

Examples of the functional group including a nitrogen atom include primary to tertiary amino groups and quaternary ammonium bases, and from the viewpoints of the dispersibility and the storage stability, it is preferable to have the primary to tertiary amino groups, and it is more preferable to have the tertiary amino group.

The structure of a repeating unit having the tertiary amino group in the block copolymer is not particularly limited, but from the viewpoints of the dispersibility and the storage stability, a repeating unit represented by General Formula (D1) is preferable.

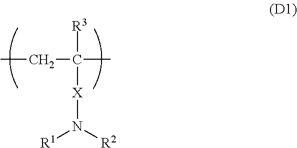

In Formula (D1), R¹ and R² are each independently a hydrogen atom, an alkyl group which may have a substituent, an aryl group which may have a substituent, or an aralkyl group which may have a substituent, and R¹ and R² may be bonded to each other to form a cyclic structure. R³ is a hydrogen atom or a methyl group. X is a divalent linking group.

In Formula (D1), the number of carbon atoms of the alkyl group which may have a substituent is not particularly limited, but is preferably 1 or more. In addition, the number of carbon atoms is preferably 10 or less, more preferably 6 or less, and still more preferably 4 or less. For example, the number of carbon atoms is preferably 1 to 10, more preferably 1 to 6, and still more preferably 1 to 4. Examples of the alkyl group include a methyl group, an ethyl group, a propyl group, a butyl group, a pentyl group, a hexyl group, a heptyl group, and an octyl group. The alkyl group is preferably the methyl group, the ethyl group, the propyl group, the butyl group, the pentyl group, or the hexyl group, and more preferably the methyl group, the ethyl group, the propyl group, or the butyl group. The alkyl group in Formula (D1) may be either linear or branched. The alkyl group in Formula (D1) may include a cyclic structure such as a cyclohexyl group and a cyclohexylmethyl group.

In Formula (D1), the number of carbon atoms of the aryl group which may have a substituent is not particularly limited, but is preferably 6 or more. In addition, the number of carbon atoms is preferably 16 or less, more preferably 12 or less, and still more preferably 8 or less. For example, the number of carbon atoms is preferably 6 to 16, more preferably 6 to 12, and still more preferably 6 to 8. Examples of the aryl group include a phenyl group, a methylphenyl group, an ethylphenyl group, a dimethylphenyl group, a diethylphenyl group, a naphthyl group, and an anthracenyl group. The aryl group is preferably the phenyl group, the methylphenyl group, the ethylphenyl group, the dimethylphenyl group, or the diethylphenyl group, and more preferably the phenyl group, the methylphenyl group, or the ethylphenyl group.

In Formula (D1), the number of carbon atoms of the aralkyl group which may have a substituent is not particularly limited, but is preferably 7 or more. In addition, the number of carbon atoms is preferably 16 or less, more preferably 12 or less, and still more preferably 9 or less. For example, the number of carbon atoms is preferably 7 to 16, more preferably 7 to 12, and still more preferably 7 to 9. Examples of the aralkyl group include a phenylmethyl group, a phenylethyl group, a phenylpropyl group, a phenylbutyl group, and a phenylisopropyl group. The aralkyl group is preferably the phenylmethyl group, the phenylethyl group, the phenylpropyl group, or the phenylbutyl group, and more preferably the phenylmethyl group or the phenylethyl group.

From the viewpoints of the dispersibility, the storage stability, the electrical reliability, and the developability, R¹ and R² are each independently preferably the alkyl group which may have a substituent, and more preferably the methyl group or the ethyl group.

Examples of the substituent that the alkyl group, the aralkyl group, or the aryl group in Formula (D1) may have include a halogen atom, an alkoxy group, a benzoyl group, and a hydroxyl group, and from the viewpoint of an ease in synthesis, no substitution is preferable.

In Formula (D1), examples of the cyclic structure formed by bonding R¹ and R² to each other include nitrogen-containing heterocyclic monocyclic rings with 5- to 7-membered rings, or a fused ring obtained by fusing two of these rings. The nitrogen-containing heterocyclic rings are preferably those having no aromatic property, and more preferably saturated rings. Specifically, examples thereof include nitrogen-containing heterocyclic rings which will be described below.

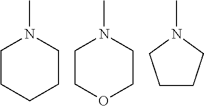

These cyclic structures may further have substituents.

In Formula (D1), examples of the divalent linking group X include an alkylene group having 1 to 10 carbon atoms, an arylene group having 6 to 12 carbon atoms, a —CONH—R¹³— group, and a —COOR¹⁴— group [provided that R¹³ and R¹⁴ are each a single bond, an alkylene group having 1 to 10 carbon atoms, or an ether group having 2 to 10 carbon atoms (alkyloxyalkyl group)]. The divalent linking group X is preferably the —COO—R¹⁴— group.

The content proportion of the repeating unit represented by Formula (D1) in all repeating units of the block copolymer is preferably 1% by mole or more, more preferably 5% by mole or more, still more preferably 10% by mole or more, even still more preferably 15% by mole or more, particularly preferably 20% by mole or more, and most preferably 25% by mole or more. In addition, the content proportion is preferably 90% by mole or less, more preferably 70% by mole or less, still more preferably 50% by mole or less, and particularly preferably 40% by mole or less.

The above-described upper limits and lower limits can be combined in any manner. For example, the content proportion of the repeating unit represented by Formula (D1) in all repeating units of the block copolymer is preferably 1% to 90% by mole, more preferably 5% to 90% by mole, still more preferably 10% to 70% by mole, even still more preferably 15% to 70% by mole, particularly preferably 20% to 50% by mole, and most preferably 25% to 40% by mole. When the content proportion is within the ranges, there is a tendency that both dispersion stability and high luminance can be achieved.

From the viewpoint of increasing the compatibility with binder components such as a solvent and improving the dispersion stability, it is preferable that the block copolymers have a repeating unit represented by Formula (D2).

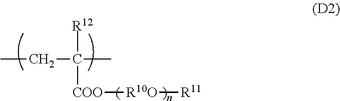

In Formula (D2), R¹⁰ is an ethylene group or a propylene group, R¹¹ is an alkyl group which may have a substituent, and R¹² is a hydrogen atom or a methyl group. n is an integer from 1 to 20.

In R¹¹ of Formula (D2), the number of carbon atoms of the alkyl group which may have a substituent is not particularly limited, but is preferably 1 or more, and more preferably 2 or more. In addition, the number of carbon atoms is preferably 10 or less, more preferably 6 or less, and still more preferably 4 or less.

The above-described upper limits and lower limits can be combined in any manner. For example, the number of carbon atoms of the alkyl group for R¹¹ of Formula (D2) is preferably 1 to 10, more preferably 1 to 6, and still more preferably 2 to 4.

Examples of the alkyl group include a methyl group, an ethyl group, a propyl group, a butyl group, a pentyl group, a hexyl group, a heptyl group, and an octyl group. The alkyl group is preferably the methyl group, the ethyl group, the propyl group, the butyl group, the pentyl group, or the hexyl group, and more preferably the methyl group, the ethyl group, the propyl group, or the butyl group. The alkyl group for R¹¹ of Formula (D2) may be either linear or branched. The alkyl group for R¹¹ of Formula (D2) may include a cyclic structure such as a cyclohexyl group and a cyclohexylmethyl group.

Examples of the substituent that the alkyl group for R¹¹ of Formula (D2) may have include a halogen atom, an alkoxy group, a benzoyl group, and a hydroxyl group, and from the viewpoint of an ease in synthesis, no substitution is preferable.

From the viewpoint of compatibility and dispersibility with binder components such as solvents, n in Formula (D2) is 1 or more and preferably 2 or more. In addition, n is preferably 10 or less, and more preferably 5 or less.

The above-described upper limits and lower limits can be combined in any manner. For example, n is preferably 1 to 10, more preferably 1 to 5, and still more preferably 2 to 5.

The content proportion of the repeating unit represented by Formula (D2) in all repeating units of the block copolymer is preferably 1% by mole or more, more preferably 2% by mole or more, and still more preferably 4% by mole or more. In addition, the content proportion is preferably 30% by mole or less, more preferably 20% by mole or less, and still more preferably 10% by mole or less.

The above-described upper limits and lower limits can be combined in any manner. For example, the content proportion of the repeating unit represented by Formula (D2) in all repeating units of the block copolymer is preferably 1% to 30% by mole, more preferably 2% to 20% by mole, and still more preferably 4% to 10% by mole. When the content proportion is within the ranges, there is a tendency that both the compatibility with a binder component such as a solvent and the dispersion stability can be achieved.

From the viewpoint of increasing the compatibility with binder components such as a solvent and improving the dispersion stability, it is preferable that the block copolymers have a repeating unit represented by Formula (D3).

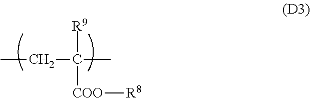

In Formula (D3), R⁸ is an alkyl group which may have a substituent, an aryl group which may have a substituent, or an aralkyl group which may have a substituent. R⁹ is a hydrogen atom or a methyl group.

In R⁸ of Formula (D3), the number of carbon atoms of the alkyl group which may have a substituent is not particularly limited, but is preferably 1 or more. In addition, the number of carbon atoms is preferably 10 or less, and more preferably 6 or less. For example, the number of carbon atoms is preferably 1 to 10, and more preferably 1 to 6. Examples of the alkyl group include a methyl group, an ethyl group, a propyl group, a butyl group, a pentyl group, a hexyl group, a heptyl group, and an octyl group. The alkyl group is preferably the methyl group, the ethyl group, the propyl group, the butyl group, the pentyl group, or the hexyl group, and more preferably the methyl group, the ethyl group, the propyl group, or the butyl group. The alkyl group for R⁸ of Formula (D3) may be either linear or branched. The alkyl group for R⁸ of Formula (D3) may include a cyclic structure such as a cyclohexyl group and a cyclohexylmethyl group.

In R⁸ of Formula (D3), the number of carbon atoms of the aryl group which may have a substituent is not particularly limited, but is preferably 6 or more. In addition, the number of carbon atoms is preferably 16 or less, and more preferably 12 or less. For example, the number of carbon atoms is preferably 6 to 16, and more preferably 6 to 12. Examples of the aryl group include a phenyl group, a methylphenyl group, an ethylphenyl group, a dimethylphenyl group, a diethylphenyl group, a naphthyl group, and an anthracenyl group. The aryl group is preferably the phenyl group, the methylphenyl group, the ethylphenyl group, the dimethylphenyl group, or the diethylphenyl group, and more preferably the phenyl group, the methylphenyl group, or the ethylphenyl group.

In R⁸ of Formula (D3), the number of carbon atoms of the aralkyl group which may have a substituent is not particularly limited, but is preferably 7 or more. In addition, the number of carbon atoms is preferably 16 or less, and more preferably 12 or less. For example, the number of carbon atoms is preferably 7 to 16, and more preferably 7 to 12. Examples of the aralkyl group include a phenylmethyl group, a phenylethyl group, a phenylpropyl group, a phenylbutyl group, and a phenylisopropyl group. The aralkyl group is preferably the phenylmethyl group, the phenylethyl group, the phenylpropyl group, or the phenylbutyl group, and more preferably the phenylmethyl group or the phenylethyl group.

From the viewpoints of the solvent compatibility and the dispersion stability, R⁸ is preferably an alkyl group or an aralkyl group, and more preferably a methyl group, an ethyl group, or a phenylmethyl group.

In R⁸, examples of the substituent that the alkyl group may have include a halogen atom and an alkoxy group. Examples of the substituent that the aryl group or the aralkyl group may have include a chain alkyl group, a halogen atom, and an alkoxy group. The chain alkyl group represented by R⁸ includes either of linear and branched ones.

The content proportion of the repeating unit represented by Formula (D3) in all repeating units of the block copolymer is preferably 30% by mole or more, more preferably 40% by mole or more, and still more preferably 50% by mole or more. In addition, it is preferably 80% by mole or less and more preferably 70% by mole or less.

The above-described upper limits and lower limits can be combined in any manner. For example, the content proportion of the repeating unit represented by Formula (D3) in all repeating units of the block copolymer is preferably 30% to 80% by mole, more preferably 40% to 80% by mole, and still more preferably 50% to 70% by mole. When the content proportion is within the ranges, there is a tendency that both dispersion stability and high luminance can be achieved.

The block copolymer may have a repeating unit other than the repeating unit represented by Formula (D1), the repeating unit represented by Formula (D2), and the repeating unit represented by Formula (D3).

Examples of such a repeating unit include repeating units derived from styrene-based monomers such as styrene and α-methylstyrene; (meth)acrylate-based monomers such as (meth)acrylic acid chloride; (meth)acrylamide-based monomers such as (meth)acrylamide and N-methylolacrylamide; vinyl acetate; acrylonitrile; allyl glycidyl ether and crotonate glycidyl ether; and N-methacryloylmorpholine.

From the viewpoint of further enhancing the dispersibility, the block copolymer is preferably a block copolymer having an A block having the repeating unit represented by Formula (D1) and a B block not having the repeating unit represented by Formula (D1), and more preferably an A-B block copolymer or a B-A-B block copolymer. The B block preferably has a repeating unit represented by Formula (D2) and a repeating unit represented by Formula (D3).

A repeating unit other than the repeating unit represented by Formula (D1) may be contained in the A block. Examples of such a repeating unit include repeating units derived from the (meth)acrylic acid ester-based monomers described above. The content of the repeating unit other than the repeating unit represented by Formula (D1) in the A block is preferably 0% to 50% by mole, and more preferably 0% to 20% by mole. It is most preferable that the repeating unit other than the repeating unit represented by Formula (D1) is not contained in the A block.

A repeating unit other than the repeating unit represented by Formula (D2) and the repeating unit represented by Formula (D3) may be contained in the B block. Examples of such a repeating unit include repeating units derived from styrene-based monomers such as styrene and α-methylstyrene; (meth)acrylate-based monomers such as (meth)acrylic acid chloride; (meth)acrylamide-based monomers such as (meth)acrylamide and N-methylolacrylamide; vinyl acetate; acrylonitrile; allyl glycidyl ether and crotonate glycidyl ether; and N-methacryloylmorpholine. The content of the repeating unit other than the repeating unit represented by Formula (D2) and the repeating unit represented by Formula (D3) in the B block is preferably 0% to 50% by mole, and more preferably 0% to 20% by mole. It is most preferable that the repeating unit other than the repeating unit represented by Formula (D2) and the repeating unit represented by Formula (D3) is not contained in the B block.

From the viewpoint of dispersibility, the acid value of the block copolymer is preferably low, and is particularly preferably 0 mgKOH/g.

From the viewpoint of dispersibility and developability, the amine value of the block copolymer is preferably 30 mgKOH/g or more, more preferably 50 mgKOH/g or more, still more preferably 70 mgKOH/g or more, even still more preferably 90 mgKOH/g or more, particularly preferably 100 mgKOH/g or more, and most preferably 105 mgKOH/g or more. In addition, the amine value is preferably 150 mgKOH/g or less, and more preferably 130 mgKOH/g or less.

The above-described upper limits and lower limits can be combined in any manner. For example, the amine value of the block copolymer is preferably 30 to 150 mgKOH/g, more preferably 50 to 150 mgKOH/g, still more preferably 70 to 150 mgKOH/g, even still more preferably 90 to 130 mgKOH/g, particularly preferably 100 to 130 mgKOH/g, and most preferably 105 to 130 mgKOH/g.

The amine value represents an amine value in terms of active solid contents, and is a value expressed by the mass of KOH equivalent to the amount of base per gram of a solid content.

The molecular weight of the block copolymer is preferably in a range of 1,000 to 30,000 in terms of weight-average molecular weight (Mw). When the molecular weight is within the ranges, there is a tendency that the dispersion stability is improved and dry foreign matters are less likely to be generated at the time of application by a slit nozzle method.

The block copolymer can be produced by a known method. For example, it can be produced by living polymerization of the monomers into which each of the repeating units is introduced. As the living polymerization method, for example, known methods described in Japanese Unexamined Patent Application, First Publication No. H09-62002, Japanese Unexamined Patent Application, First Publication No. 2002-31713, P. Lutz, P. Masson et al, Polym. Bull. 12, 79 (1984), B. C. Anderson, G. D. Andrews et al, Macromolecules, 14, 1601 (1981), K. Hatada, K. Ute, et al, Polym. J. 17,977 (1985), K. Hatada, et al, Polym. J. 18, 1037 (1986), Koichi Miguchi, Koichi Hatada, Polymer Processing, 36, 366 (1987), Toshinobu Higashimura, Mitsuo Sawamoto, Collection of Polymer Papers, 46, 189 (1989), M. Kuroki, T. Aida, J. Am. Chem. Soc, 109, 4737 (1987), Takuzo Aida, Shohei Inoue, Organic Synthetic Chemistry, 43, 300 (1985), and D. Y Sogoh, W. R. Hertler et al., Macromolecules, 20, 1473 (1987) can be employed.

When the colored resin composition of the present invention includes a dispersant, the content proportion of the dispersant is not particularly limited, but is preferably 0.001% by mass or more, more preferably 0.01% by mass or more, still more preferably 0.1% by mass or more, and particularly preferably 1% by mass or more in the total solid content of the colored resin composition. In addition, the content proportion is preferably 25% by mass or less, more preferably 20% by mass or less, still more preferably 15% by mass or less, and particularly preferably 10% by mass or less. By setting the content proportion to the lower limit value or more, there is a tendency that the dispersibility and the storage stability are improved. By setting the number of carbon atoms to the upper limit value or less, there is a tendency that the electrical reliability and the developability are improved.

The above-described upper limits and lower limits can be combined in any manner. For example, when the colored resin composition of the present invention includes a dispersant, the content proportion of the dispersant in the total solid content of the colored resin composition is preferably 0.001% to 25% by mass, more preferably 0.01% to 20% by mass, still more preferably 0.1% to 15% by mass, and particularly preferably 1% to 10% by mass.

When the colored resin composition of the present invention includes a pigment and a dispersant, a content proportion of the dispersant is not particularly limited, but is preferably 0.5 parts by mass or more, more preferably 5 parts by mass or more, still more preferably 10 parts by mass or more, even still more preferably 15 parts by mass or more, and particularly preferably 20 parts by mass or more with respect to 100 parts by mass of the pigment. In addition, the content proportion is preferably 70 parts by mass or less, more preferably 50 parts by mass or less, still more preferably 40 parts by mass or less, and particularly preferably 30 parts by mass or less.

The above-described upper limits and lower limits can be combined in any manner. For example, when the colored resin composition of the present invention includes a pigment and a dispersant, the content proportion of the dispersant with respect to 100 parts by mass of the pigment is preferably 0.5 to 70 parts by mass, more preferably 5 to 70 parts by mass, still more preferably 10 to 50 parts by mass, even still more preferably 15 to 40 parts by mass, and particularly preferably 20 to 30 parts by mass. By setting the content proportion to be within the ranges, there is a tendency that a colored resin composition having an excellent dispersion stability and a high luminance can be obtained.

When the colored resin composition of the present invention includes a pigment, it may include, for example, a pigment derivative as a dispersant for improving the dispersibility of the pigment and improving the dispersion stability. Examples of the pigment derivative include derivatives of azo-based pigments, phthalocyanine-based pigments, quinacridone-based pigments, benzimidazolone-based pigments, quinophthalone-based pigments, isoindolinone-based pigments, isoindoline-based pigments, dioxazine-based pigments, anthraquinone-based pigments, indanthrene-based pigments, perylene-based pigments, perinone-based pigments, diketopyrrolopyrrole-based pigments, and dioxazine-based pigments.

Examples of the substituent of the pigment derivative include a sulfonic acid group, a sulfonamide group, a quaternary salt of a sulfonamide group, a phthalimide methyl group, a dialkylaminoalkyl group, a hydroxyl group, a carboxy group, and an amide group, and the substituent may be bonded through, for example, an alkyl group, an aryl group, or a heterocyclic group to a pigment skeleton, or may be directly bonded to the pigment skeleton. As the substituent, the sulfonamide group, the quaternary salt of a sulfonamide group, and the sulfonic acid group are preferable, and the sulfonic acid group is more preferable.

A plurality of the substituents may be substituted in one pigment skeleton, or may be a mixture of compounds with a different number of substituents.

Examples of the pigment derivative include a sulfonic acid derivative of an azo pigment, a sulfonic acid derivative of a phthalocyanine pigment, a sulfonic acid derivative of a quinophthalone pigment, a sulfonic acid derivative of an isoindoline pigment, a sulfonic acid derivative of an anthraquinone pigment, a sulfonic acid derivative of a quinacridone pigment, a sulfonic acid derivative of a diketopyrrolopyrrole pigment, and a sulfonic acid derivative of a dioxazine pigment.

### 1-4-4 Surfactant

When the colored resin composition of the present invention includes a surfactant, various surfactants such as anionic, cationic, non-ionic, or amphoteric surfactants can be used. From the viewpoint of being less likely to adversely affect various characteristics of the colored resin composition of the present invention, the non-ionic surfactant is preferred.

When the colored resin composition of the present invention includes a surfactant, a content proportion of the surfactant is not particularly limited, but is preferably 0.001% by mass or more, more preferably 0.01% by mass or more, still more preferably 0.05% by mass or more, and particularly preferably 0.1% by mass or more in the total solid content of the colored resin composition. In addition, the content proportion is preferably 10% by mass or less, more preferably 1% by mass or less, still more preferably 0.5% by mass or less, and particularly preferably 0.3% by mass or less.

The above-described upper limits and lower limits can be combined in any manner. For example, the content proportion of the surfactant in the total solid content of the colored resin composition is preferably 0.001% to 10% by mass, more preferably 0.01% to 1% by mass, still more preferably 0.05% to 0.5% by mass, and particularly preferably 0.1% to 0.3% by mass.

### 1-5 Physical Properties of Colored Resin Composition

### 1-5-1 Physical Properties of Colored Resin Composition of First Aspect

The colored resin composition of the first aspect has a maximum transmittance at a wavelength range of 400 to 500 nm in a wavelength range of 400 and 900 nm. By exhibiting such the optical transparency, there is a tendency that a color filter selectively transmitting only blue light from a visible region to a near-infrared region can be obtained.

When a film having a film thickness of 5 μm or less after drying is formed using the colored resin composition of the first aspect, the average transmittance of the film in the wavelength range of 400 to 500 nm is preferably 30% or more, more preferably 50% or more, and still more preferably 70% or more. The upper limit is not particularly limited, and is preferably 100%. For example, the average transmittance in the wavelength range of 400 to 500 nm is preferably 30% to 100%, more preferably 50% to 100%, and still more preferably 70% to 100%.

In addition, when a film having a film thickness of 2.5±0.5 μm after drying is formed using the colored resin composition of the first aspect, the average transmittance of the film in the wavelength range of 400 to 500 nm is preferably within the ranges.

When a film having a film thickness of 5 μm or less after drying is formed using the colored resin composition of the first aspect, the average transmittance of the film in a wavelength range of 700 to 900 nm is preferably 0.1% or less, and more preferably 0.01% or less. The lower limit is not particularly limited and is preferably 0%. For example, the average transmittance in the wavelength range of 700 to 900 nm is preferably 0% to 0.1%, and more preferably 0% to 0.01%.

In addition, when a film having a film thickness of 2.5±0.5 μm after drying is formed using the colored resin composition of the first aspect, the average transmittance of the film in the wavelength range of 700 to 900 nm is preferably within the ranges.

When a film having a film thickness of 5 um or less after drying is formed using the colored resin composition of the first aspect, the average transmittance of the film in a wavelength range of 580 to 650 nm is preferably 0.1% or less, and more preferably 0.01% or less. The lower limit is not particularly limited and is preferably 0%. For example, the average transmittance in the wavelength range of 580 to 650 nm is preferably 0% to 0.1%, and more preferably 0% to 0.01%.

In addition, when a film having a film thickness of 2.5±0.5 μm after drying is formed using the colored resin composition of the first aspect, the average transmittance of the film in the wavelength range of 580 to 650 nm is preferably within the ranges.

### 1-5-2 Physical Properties of Colored Resin Composition of Second Aspect

The colored resin composition of the second aspect has a maximum transmittance at a wavelength range of 500 to 600 nm in a wavelength range of 400 and 900 nm. By exhibiting such the optical transparency, there is a tendency that a color filter selectively transmitting only green light from a visible region to a near-infrared region can be obtained.

When a film having a film thickness of 5 μm or less after drying is formed using the colored resin composition of the second aspect, the average transmittance of the film in the wavelength range of 500 to 600 nm is preferably 30% or more, more preferably 50% or more, and still more preferably 70% or more. The upper limit is not particularly limited, and is preferably 100%. For example, the average transmittance in the wavelength range of 500 to 600 nm is preferably 30% to 100%, more preferably 50% to 100%, and still more preferably 70% to 100%.

In addition, when a film having a film thickness of 2.5±0.5 μm after drying is formed using the colored resin composition of the second aspect, the average transmittance of the film in the wavelength range of 500 to 600 nm is preferably within the ranges.

When a film having a film thickness of 5 μm or less after drying is formed using the colored resin composition of the second aspect, the average transmittance of the film in a wavelength range of 700 to 900 nm is preferably 0.1% or less, and more preferably 0.01% or less. The lower limit is not particularly limited and is preferably 0%. For example, the average transmittance in the wavelength range of 700 to 900 nm is preferably 0% to 0.1%, and more preferably 0% to 0.01%.

In addition, when a film having a film thickness of 2.5±0.5 μm after drying is formed using the colored resin composition of the second aspect, the average transmittance of the film in the wavelength range of 700 to 900 nm is preferably within the ranges.

When a film having a film thickness of 5 μm or less after drying is formed using the colored resin composition of the second aspect, the average transmittance of the film in a wavelength range of 650 to 700 nm is preferably 0.1% or less, and more preferably 0.01% or less. The lower limit is not particularly limited and is preferably 0%. For example, the average transmittance in the wavelength range of 650 to 700 nm is preferably 0% to 0.1%, and more preferably 0% to 0.01%.

In addition, when a film having a film thickness of 2.5±0.5 μm after drying is formed using the colored resin composition of the second aspect, the average transmittance of the film in the wavelength range of 650 to 700 nm is preferably within the ranges.

### 1-5-3 Physical Properties of Colored Resin Composition of Third Aspect

The colored resin composition of the third aspect has a maximum transmittance at a wavelength range of 600 to 700 nm in a wavelength range of 400 and 900 nm. By exhibiting such the optical transparency, there is a tendency that a color filter selectively transmitting only red light from a visible region to a near-infrared region can be obtained.

When a film having a film thickness of 5 μm or less after drying is formed using the colored resin composition of the third aspect, the average transmittance of the film in the wavelength range of 600 to 700 nm is preferably 30% or more, more preferably 50% or more, and still more preferably 70% or more. The upper limit is not particularly limited, and is preferably 100%. For example, the average transmittance in the wavelength range of 600 to 700 nm is preferably 30% to 100%, more preferably 50% to 100%, and still more preferably 70% to 100%.

In addition, when a film having a film thickness of 2.5±0.5 μm after drying is formed using the colored resin composition of the third aspect, the average transmittance of the film in the wavelength range of 600 to 700 nm is preferably within the ranges.

When a film having a film thickness of 5 μm or less after drying is formed using the colored resin composition of the third aspect, the average transmittance of the film in a wavelength range of 700 to 900 nm is preferably 0.1% or less, and more preferably 0.01% or less. The lower limit is not particularly limited and is preferably 0%. For example, the average transmittance in the wavelength range of 700 to 900 nm is preferably 0% to 0.1%, and more preferably 0% to 0.01%.

In addition, when a film having a film thickness of 2.5±0.5 μm after drying is formed using the colored resin composition of the third aspect, the average transmittance of the film in the wavelength range of 700 to 900 nm is preferably within the ranges.

When a film having a film thickness of 5 μm or less after drying is formed using the colored resin composition of the third aspect, the average transmittance of the film in a wavelength range of 430 to 570 nm is preferably 0.1% or less, and more preferably 0.01% or less. The lower limit is not particularly limited and is preferably 0%. For example, the average transmittance in the wavelength range of 430 to 570 nm is preferably 0% to 0.1%, and more preferably 0% to 0.01%.

In addition, when a film having a film thickness of 2.5±0.5 μm after drying is formed using the colored resin composition of the third aspect, the average transmittance of the film in the wavelength range of 430 to 570 nm is preferably within the ranges.

### 1-5-4 Physical Properties of Colored Resin Composition of Fourth Aspect

The colored resin composition of the fourth aspect has a maximum transmittance at a wavelength range of 700 to 800 nm in a wavelength range of 400 and 900 nm. By exhibiting such the optical transparency, there is a tendency that a color filter selectively transmitting only near-infrared rays in a specific wavelength range from a visible region to a near-infrared region can be obtained.

When a film having a film thickness of 5 μm or less after drying is formed using the colored resin composition of the fourth aspect, the average transmittance of the film in the wavelength range of 700 to 800 nm is preferably 30% or more, more preferably 50% or more, and still more preferably 70% or more. The upper limit is not particularly limited, and is preferably 100%. For example, the average transmittance in the wavelength range of 700 to 800 nm is preferably 30% to 100%, more preferably 50% to 100%, and still more preferably 70% to 100%.

In addition, when a film having a film thickness of 2.5±0.5 μm after drying is formed using the colored resin composition of the fourth aspect, the average transmittance of the film in the wavelength range of 700 to 800 nm is preferably within the ranges.

When a film having a film thickness of 5 μm or less after drying is formed using the colored resin composition of the fourth aspect, the average transmittance of the film in a wavelength range of 400 to 600 nm is preferably 0.1% or less, and more preferably 0.01% or less. The lower limit is not particularly limited and is preferably 0%. For example, the average transmittance in the wavelength range of 400 to 600 nm is preferably 0% to 0.1%, and more preferably 0% to 0.01%.

In addition, when a film having a film thickness of 2.5±0.5 μm after drying is formed using the colored resin composition of the fourth aspect, the average transmittance of the film in the wavelength range of 400 to 600 nm is preferably within the ranges.

When a film having a film thickness of 5 μm or less after drying is formed using the colored resin composition of the fourth aspect, the average transmittance of the film in a wavelength range of 830 to 900 nm is preferably 0.1% or less, and more preferably 0.01% or less. The lower limit is not particularly limited and is preferably 0%. For example, the average transmittance in the wavelength range of 830 to 900 nm is preferably 0% to 0.1%, and more preferably 0% to 0.01%.

In addition, when a film having a film thickness of 2.5±0.5 μm after drying is formed using the colored resin composition of the fourth aspect, the average transmittance of the film in the wavelength range of 830 to 900 nm is preferably within the ranges.

### 1-5-5 Physical Properties of Colored Resin Composition of Fifth Aspect

The colored resin composition of the fifth aspect has a maximum transmittance at a wavelength range of 800 to 900 nm in a wavelength range of 400 and 900 nm. By exhibiting such the optical transparency, there is a tendency that a color filter selectively transmitting only near-infrared rays in a specific wavelength range from a visible region to a near-infrared region can be obtained.

When a film having a film thickness of 5 μm or less after drying is formed using the colored resin composition of the fifth aspect, the average transmittance of the film in the wavelength range of 800 to 900 nm is preferably 30% or more, more preferably 50% or more, and still more preferably 70% or more. The upper limit is not particularly limited, and is preferably 100%. For example, the average transmittance in the wavelength range of 800 to 900 nm is preferably 30% to 100%, more preferably 50% to 100%, and still more preferably 70% to 100%.

In addition, when a film having a film thickness of 2.5±0.5 μm after drying is formed using the colored resin composition of the fifth aspect, the average transmittance of the film in the wavelength range of 800 to 900 nm is preferably within the ranges.

When a film having a film thickness of 5 μm or less after drying is formed using the colored resin composition of the fifth aspect, the average transmittance of the film in a wavelength range of 400 to 600 nm is preferably 0.1% or less, and more preferably 0.01% or less. The lower limit is not particularly limited and is preferably 0%. For example, the average transmittance in the wavelength range of 400 to 600 nm is preferably 0% to 0.1%, and more preferably 0% to 0.01%.

In addition, when a film having a film thickness of 2.5±0.5 μm after drying is formed using the colored resin composition of the fifth aspect, the average transmittance of the film in the wavelength range of 400 to 600 nm is preferably within the ranges.

When a film having a film thickness of 5 μm or less after drying is formed using the colored resin composition of the fifth aspect, the average transmittance of the film in a wavelength range of 700 to 780 nm is preferably 0.1% or less, and more preferably 0.01% or less. The lower limit is not particularly limited and is preferably 0%. For example, the average transmittance in the wavelength range of 700 to 780 nm is preferably 0% to 0.1%, and more preferably 0% to 0.01%.

In addition, when a film having a film thickness of 2.5±0.5 μm after drying is formed using the colored resin composition of the fifth aspect, the average transmittance of the film in the wavelength range of 700 to 780 nm is preferably within the ranges.

### 1-6 Preparation of Colored Resin Composition

When a colored resin composition including a pigment as the colorant is prepared, a pigment, a solvent, and a dispersant are weighed in predetermined amounts, and in a dispersing treatment step, the colorant including the pigment is dispersed to prepare a pigment dispersion. As described above, in the dispersing treatment step, for example, it is preferable to use a dispersion aid and/or a dispersion resin in combination.

In the dispersing treatment step, for example, a paint conditioner, a sand grinder, a ball mill, a roll mill, a stone mill, a jet mill, or a homogenizer can be used. By performing a dispersing treatment, the colorant is formed into fine particles. Therefore, the application characteristics of the colored resin composition are improved and the transmittance of pixels in a color filter substrate of a product is improved. When the dispersing treatment is performed using a sand grinder, it is preferable to use glass beads having a diameter of 0.1 to several mm, or zirconia beads.

The temperature at the time of performing the dispersing treatment is set in a range of preferably 0° C. or higher, and more preferably room temperature or higher, and preferably 100° C. or lower, and more preferably 80° C. or lower. The temperature can be set to, for example, 0° C. to 100° C., 0° C. to 80° C., or room temperature to 80° C. Since an appropriate dispersion time varies depending on the formulation of s pigment dispersion, the size of a device of a sand grinder, and the like, the dispersion time may be appropriately adjusted.

The pigment dispersion obtained in the dispersing treatment step is mixed with a solvent, a binder resin, a photopolymerization initiator, and components other than those mentioned above, and the like as necessary to obtain a uniform dispersion solution. Furthermore, since fine waste may be mixed in each of the dispersing treatment step and the mixing step, it is preferable to subject the obtained pigment dispersion to a filtration treatment with a filter or the like.

When a colored resin composition including no pigment as the colorant is prepared, a colorant, a solvent, a binder resin, a photopolymerization initiator, and components other than those mentioned above, and the like as necessary can be mixed to obtain a uniform solution. The obtained solution is preferably filtered with a filter or the like.

### 2 Colored Resin Composition Set

One aspect of a colored resin composition set of the present invention preferably has the colored resin composition of the fourth aspect and the colored resin composition of the fifth aspect. By using the colored resin composition set, a combination of pixels capable of spectrally splitting a near-infrared region can be formed, which can be applied to a color filter of a solid-state imaging device capable of high-level imaging.

Another aspect of the colored resin composition set of the present invention preferably has at least two resin compositions selected from the group consisting of the colored resin composition of the first aspect, the colored resin composition of the second aspect, the colored resin composition of the third aspect, and the colored resin composition of the fourth aspect, and the colored resin composition of the fifth aspect. By using the colored resin composition set, a combination of pixels capable of spectrally splitting light in a specific wavelength range in a visible region and a near-infrared region can be formed, and can be applied to a color filter of a solid-state imaging device capable of high-level imaging.

The colored resin composition set of the present invention of this aspect may be a colored resin composition set including at least one resin composition selected from the group consisting of the colored resin composition of the first aspect, the colored resin composition of the second aspect, and the colored resin composition of the third aspect, and at least one resin composition selected from the group consisting of the colored resin composition of the fourth aspect and the colored resin composition of the fifth aspect.

### 3 Color Filter

The color filter of the present invention has pixels using the colored resin composition of the present invention, specifically, pixels formed using the colored resin composition of the present invention.

### 3-1 Transparent Substrate (Support)

For the transparent substrate of the color filter, a material therefor is not particularly limited as long as the substrate is transparent and has a proper strength. Examples of the transparent substrate include thermoplastic resin-made sheets with polyester-based resins such as polyethylene terephthalate, polyolefin-based resins such as polypropylene and polyethylene, polycarbonates, polymethyl methacrylate, or polysulfone, thermosetting resin sheets with epoxy resins, unsaturated polyester resins, and poly(meth)acryl-based resins and the like, or various types of glass. From the viewpoint of the heat resistance, glass and a heat-resistant resin are preferable.

The transparent substrate and the black matrix-forming substrate may be subjected to, for example, a corona discharge treatment, an ozone treatment, and a thin film-forming treatment using a silane coupling agent and various resins such as a urethane-based resin, as necessary, in order to improve the surface physical properties such as adhesiveness. The thickness of the transparent substrate is in a range of preferably 0.05 mm or more, and more preferably 0.1 mm or more, and preferably 10 mm or less, and more preferably 7 mm or less, and can be, for example, 0.05 to 10 mm, 0.1 to 10 mm, 0.05 to 7 mm, or 0.1 to 7 mm. In addition, when the thin film-forming treatment using various resins is performed, a film thickness thereof is in a range of preferably 0.01 μm or more, and more preferably 0.05 μm or more, and preferably 10 m or less, and more preferably 5 um or less. The film thickness is, for example, 0.01 to 10 m, 0.05 to 10 m, 0.01 to 5 m, or 0.05 to 5 m.

### 3-2 Black Matrix

A color filter of the present invention can be produced by providing a black matrix on the above-mentioned transparent substrate, and more usually forming a red, green, and blue pixel image that spectrally splits light in a visible region into the three colors, and forming a pixel image that spectrally splits infrared rays into two colors. Each of the colored resin compositions of the first to third aspects according to the present invention can be used as a coating solution for forming a blue, green, and red pixel (resist pattern), and each of the colored resin compositions of the fourth and fifth aspects according to the present invention can be used as a coating solution for forming a pixel (resist pattern) that spectrally splits infrared rays into two colors. A pixel image is formed by applying a coating solution for forming a resist pattern including the colored resin composition of the present invention to each treatment of application onto a resin black matrix-forming surface formed on a transparent substrate or on a metal black matrix-forming surface formed by using a light-shielding metal material, followed by drying by heating, image exposure, development, and thermosetting.

A black matrix is formed on a transparent substrate using a light-shielding metal material or a colored resin composition for a black matrix. As the light-shielding metal material, for example, an alloy of a chromium compound such as metal chromium, chromium oxide, and chromium nitride, nickel, and tungsten is used, and a laminate formed by laminating it on a plurality of layers may be used.

The thin light-shielding metal film is generally formed by a sputtering method, and is used to form a desired pattern in a film shape by a positive-type photoresist. Thereafter, etching is performed using an etching solution obtained by mixing ceric ammonium nitrate, perchloric acid, and/or nitric acid for a chromium compound, or an etching solution corresponding to a material for the other materials, and a positive-type photoresist is peeled by a special peeling agent, whereby a black matrix can be formed.

For example, a thin film of the light-shielding metal material is formed on a transparent substrate by a vapor deposition, a sputtering method, or the like. Next, a coating film of a colored resin composition is formed on the thin light-shielding metal film, and then the coating film is exposed and developed using a photomask having a repeating pattern such as a stripe, a mosaic, and a triangle, thereby forming a resist image. Thereafter, the coating film can be subjected to an etching treatment to form a black matrix.

When a photosensitive colored resin composition for a black matrix is used, a colored resin composition containing a black colorant is used to form a black matrix. For example, the black matrix can be formed in the same manner as the following method for forming a red, green, and blue pixel image, using a colored resin composition containing a single or a plurality of black coloring materials such as carbon black, graphite, iron black, aniline black, cyanine black, and titanium black, or containing a black coloring material obtained mixed by a red color, a green color, a blue color, and the like which are appropriately selected from inorganic or organic pigments and dyes.

### 3-3 Formation of Pixels

One of colored resin compositions used for forming a pixel image of a red color, a green color, and a blue color, and a pixel image that spectrally splits infrared rays into two colors is applied on a transparent substrate provided with a black matrix, and dried. Then, a photomask is superposed on the coating film. Through this photomask, image exposure, development, and as necessary, thermosetting or photocuring are performed to form a pixel image. A color filter image can be formed by performing this operation for each of the other colored resin compositions.

The application of the colored resin composition for the color filter can be performed by, for example, a spinner method, a wire bar method, a flow coating method, a die coating method, a roll coating method, or a spray coating method. The die coating method is preferable from an overall viewpoint, such as a significant reduction in amount of a coating solution to be used, no influence of a mist and the like adhered when using a spin coating method, and suppression of generation of foreign matters.

The thickness of the coating film, in terms of a film thickness after drying, is in a range of preferably 0.2 μm or more, more preferably 0.5 μm or more, and still more preferably 0.8 μm or more, and preferably 20 μm or less, more preferably 10 μm or less, and still more preferably 5 μm or less. By setting the thickness to the lower limit value or more, the pigment concentration is likely to be easily increased and a desired color development is likely to be achieved. By setting the thickness to the upper limit value or less, pattern development is likely to easily occur and gap adjustment in a liquid crystal-forming step is likely to be easily performed.

The above-described upper limits and lower limits can be combined in any manner. For example, the thickness of the coating film is preferably 0.2 to 20 m, more preferably 0.5 to 10 m, and still more preferably 0.8 to 5 m.

### 3-4 Drying of Coating Film

For drying (pre-baking) of the coating film after applying the colored resin composition on the transparent substrate, for example, a drying method using a hot plate, an IR oven, a convection oven, or the like, or a reduced-pressure drying method in which drying is performed in a reduced-pressure chamber without raising a temperature can be employed.

For example, in the drying method using a hot plate, an IR oven, or a convection oven, re-drying is performed by re-heating after pre-drying.

The pre-drying conditions can be selected according to the type of a solvent component, the performance of a dryer to be used, and the like.

The drying temperature for the pre-drying is in a range of preferably 40° C. or higher, and more preferably 50° C. or higher, and preferably 80° C. or lower, and more preferably 70° C. or lower. The drying temperature is for example, 40° C. to 80° C., 40° C. to 70° C., 50° C. to 80° C., or 50° C. to 70° C.

The drying time for the pre-drying is preferably 15 seconds or more, and more preferably 30 seconds or more, and preferably 5 minutes or less, and more preferably 3 minutes or less. The drying time is, for example, 15 seconds to 5 minutes, 30 seconds to 5 minutes, 15 seconds to 3 minutes, or 30 seconds to 3 minutes.

The temperature condition for the re-drying is preferably a temperature higher than the pre-drying temperature.

The drying temperature for the re-drying is in a range of preferably 50° C. or higher, and more preferably 70° C. or higher, and preferably 200° C. or lower, more preferably 160° C. or lower, and still more preferably 130° C. or lower. The drying temperature is, for example, 50° C. to 200° C., 50° C. to 160° C., 50° C. to 130° C., 70° C. to 200° C., 70° C. to 160° C., or 70° C. to 130° C.

The drying time for the re-drying depends on the heating temperature, but is in a range of preferably 10 seconds or more, and more preferably 15 seconds or more, and preferably 10 minutes or less, and more preferably 5 minutes or less. The drying time is, for example, 10 seconds to 10 minutes, 15 seconds to 10 minutes, 10 seconds to 5 minutes, or 15 seconds to 5 minutes.

When the drying temperature is the upper limit value or lower, a sufficient adhesiveness to the transparent substrate is obtained; however, thermal polymerization due to the decomposition of a binder resin is less likely to be caused and development failure is less likely to occur.

### 3-5 Exposing Step

The image exposure is performed by superimposing a negative matrix pattern on the coating film of the colored resin composition, and performing irradiation with a light source of ultraviolet rays or visible light through the mask pattern. At this time, in order to prevent a decrease in sensitivity of a photopolymerizable layer due to oxygen, as necessary, exposure may be performed after forming an oxygen barrier layer such as a polyvinyl alcohol layer on the photopolymerizable layer. The light source used for the above-mentioned image exposure is not particularly limited. Examples of the light source include lamp light sources such as a xenon lamp, a halogen lamp, a tungsten lamp, a high-pressure mercury lamp, an ultra-high-pressure mercury lamp, a metal halide lamp, a medium-pressure mercury lamp, a low-pressure mercury lamp, a carbon arc lamp, and a fluorescent lamp; and laser light sources such as an argon ion laser, a YAG laser, an excimer laser, a nitrogen laser, a helium oxide laser, and a semiconductor laser. When irradiation with light having a specific wavelength is used, an optical filter can also be employed.

### 3-6 Developing Step

The color filter of the present invention can be produced by subjecting the coating film using the colored resin composition of the present invention to image exposure using the above-mentioned light source, and then developing the coating film using an aqueous solution including a surfactant and an alkaline compound, thus to form an image on the substrate. The aqueous solution may further include an organic solvent, a buffer, a complexing agent, a dye, or a pigment.

Examples of the alkaline compound include inorganic alkaline compounds such as sodium hydroxide, potassium hydroxide, lithium hydroxide, sodium carbonate, potassium carbonate, sodium hydrogen carbonate, potassium hydrogen carbonate, sodium silicate, potassium silicate, sodium metasilicate, sodium phosphate, potassium phosphate, sodium hydrogen phosphate, potassium hydrogen phosphate, sodium dihydrogen phosphate, potassium dihydrogen phosphate, and ammonium hydroxide; and organic alkaline compounds such as mono-, di- or triethanolamine, mono-, di-, or trimethylamine, mono-, di-, or triethylamine, mono- or diisopropylamine, n-butylamine, mono-, di-, or triisopropanolamine, ethyleneimine, ethylenediimine, tetramethylammonium hydroxide (TMAH), and choline. These alkaline compounds may be used alone or in combination of two or more kinds thereof.

Examples of the surfactant include nonionic surfactants such as polyoxyethylene alkyl ethers, polyoxyethylene alkylaryl ethers, polyoxyethylene alkyl esters, sorbitan alkyl esters, and monoglyceride alkyl esters; anionic surfactants such as alkylbenzene sulfonates, alkylnaphthalene sulfonates, alkyl sulfates, alkyl sulfonates, and sulfosuccinic ester salts; and amphoteric surfactants such as alkyl betaines and amino acids.

Examples of the organic solvent include isopropyl alcohol, benzyl alcohol, ethyl cellosolve, butyl cellosolve, phenyl cellosolve, propylene glycol, and diacetone alcohol. The organic solvent may be used in combination with an aqueous solution.

The conditions for the development treatment are not particularly limited, but the developing temperature is in a range of preferably 10° C. or higher, more preferably 15° C. or higher, and still more preferably 20° C. or higher, and preferably 50° C. or lower, more preferably 45° C. or lower, and still more preferably 40° C. or lower. The developing temperature is, for example, 10° C. to 50° C., 10° C. to 45° C., 10° C. to 40° C., 15° C. to 50° C., 15° C. to 45° C., 15° C. to 40° C., 20° C. to 50° C., 20° C. to 45° C., or 20° C. to 40° C. The development method can be performed according to, for example, a dip development method, a spray development method, a brush development method, or an ultrasonic development method.

### 3-7 Thermosetting Treatment

The color filter after development is subjected to a thermosetting treatment.

The temperature for the thermosetting treatment is in a range of preferably 100° C. or higher, and more preferably 150° C. or higher, and preferably 280° C. or lower, and more preferably 250° C. or lower. The temperature is, for example, 100° C. to 280° C., 100° C. to 250° C., 150° C. to 280° C., or 150° C. to 250° C.

The time for the thermosetting treatment is in a range of 5 minutes or more and 60 minutes or less.

Through these series of steps, the patterning image formation of one color is completed. The steps are sequentially repeated to perform patterning of the black matrix, the pixel image in a red color, a green color, and a blue color, and the pixel image that spectrally splits infrared rays into two colors, thereby forming a color filter. Furthermore, the order of patterning the four colors is not limited to the above-described order.

### 3-8 Formation of Transparent Electrode

The color filter of the present invention is used as a part of components of a color display, a liquid crystal display device, and the like by forming a transparent electrode such as ITO on an image. However, in order to increase the surface smoothness and the durability, a top coat layer such as a polyamide and a polyimide can be provided on the image, as necessary. In addition, some of the transparent electrodes may not be formed in applications in an in-plane switching mode (IPS mode) and the like.

4 Image display device

The color filter of the present invention can be applied to an image display device. Examples of the image display device (panel) include a liquid crystal display device and an organic EL display device.

### 4-1 Liquid Crystal Display Device

The liquid crystal display device can be produced by forming an alignment film on the color filter of the present invention, scattering spacers on the alignment film, then bonding it to a counter substrate to form a liquid crystal cell, injecting liquid crystals into the formed liquid crystal cell, and connecting a wire with a counter electrode. As the alignment film, a resin film such as a polyimide is suitable. For the formation of the alignment film, a gravure printing method and/or a flexographic printing method is usually employed, and the thickness of the alignment film can be several tens nm. The alignment film is subjected to a curing treatment by heat-sintering, and then to a surface treatment through irradiation with ultraviolet rays or a treatment with a rubbed cloth, leading to a surface state where the tilt of the liquid crystal can be adjusted.

As the spacer, a spacer having a size according to a gap between the counter substrates is used, and is usually in a range of 2 to 8 m. A photospacer of a transparent resin film is formed on a color filter substrate by a photolithography method, and can thus be utilized instead of the spacer. As the counter substrate, an array substrate is usually used, and a thin-film transistor substrate is particularly suitable.

The gap of the bonding to the counter substrate varies depending on an application of the liquid crystal display device, but is usually selected within a range of 2 m or more and 8 μm or less. After being bonded to the counter substrate, a portion other than the liquid crystal injection port is sealed by a seal material such as an epoxy resin. The seal material is cured by UV irradiation and/or heating to seal the peripheral of the liquid crystal cell.

After cutting the liquid crystal cell whose periphery is sealed into a panel unit, the pressure is then reduced in a vacuum chamber, a liquid crystal injection port is dipped in the liquid crystal, and the liquid crystal is then injected into the liquid crystal cell by leaking the inside of a chamber.

The degree of pressure reduction within the liquid crystal cell is in a range of preferably 1×10⁻² Pa or less, and more preferably 1×10⁻³ or less, and preferably 1×10⁻⁷ Pa or more, and more preferably 1×10⁻⁶ Pa or more. The degree of pressure reduction is, for example, 1×10⁻⁷ to 1×10⁻² Pa, 1×10⁻⁶ to 1×10⁻² Pa, 1×10⁻⁷ to 1×10⁻³, and 1×10⁻⁶ to 1×10⁻³ Pa.

It is preferable to heat the liquid crystal cell under reduced pressure, and the heating temperature at the time of heating is in a range of preferably 30° C. or higher, and more preferably 50° C. or higher, and preferably 100° C. or lower, and more preferably 90° C. or lower. The heating temperature is, for example, 30° C. to 100° C., 30° C. to 90° C., 50° C. to 100° C., and 50° C. to 90° C.

The heating retention during pressure reduction is preferably in a range of 10 minutes or more and 60 minutes or less, and then dipping into the liquid crystal is performed. A liquid crystal display device (panel) is completed by sealing the liquid crystal injection port of the liquid crystal cell, into which the liquid crystal has been injected, by curing a UV-curable resin.

The type of the liquid crystal is not particularly limited. However, the liquid crystal is a known liquid crystal in the related art, such as an aromatic liquid crystal, an aliphatic liquid crystal, or a polycyclic compound, and may be, for example, either a lyotropic liquid crystal or a thermotropic liquid crystal. As the thermotropic liquid crystal, for example, a nematic liquid crystal, a smectic liquid crystal, and a cholesteric liquid crystal are known, but any of these may be used.

### 4-2 Organic EL Display Device

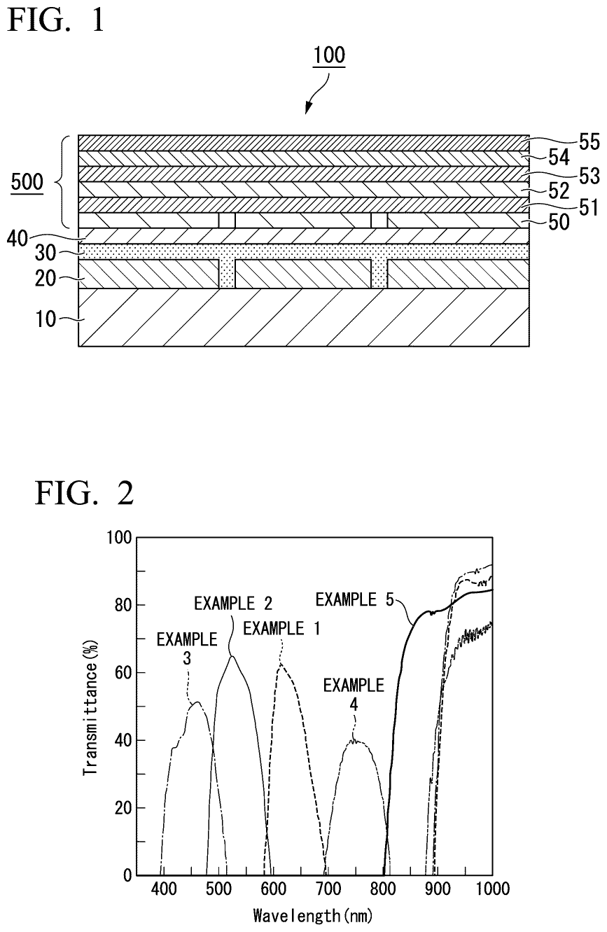

In an organic EL display device having the color filter of the present invention, for example, as shown in FIG. 1, a multicolored organic EL element can be manufactured by laminating an organic light emitting body 500 on a color filter in which pixels 20 are formed using the colored resin composition of the present invention, through an organic protective layer 30 and an inorganic oxide film 40, on a transparent support substrate 10.

Examples of a method for laminating the organic light emitting body 500 include a method in which a transparent anode 50, a hole injection layer 51, a hole transport layer 52, a light emitting layer 53, an electron injection layer 54, and a cathode 55 are sequentially formed on the upper surface of a color filter; and a method in which the organic light emitting body 500 formed on a separate substrate is bonded onto the inorganic oxide film 40.

An organic EL element 100 thus manufactured in this manner can also be applied to either of a passive drive-type organic EL display device and an active drive-type organic EL display device.

### Solid-State Imaging Device

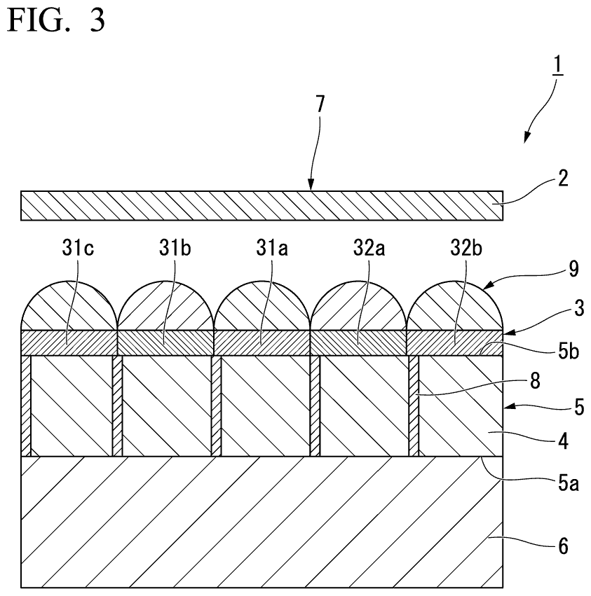

The color filter of the present invention can also be applied to a solid-state imaging device. An example of the configuration of a solid-state imaging device to which the color filter of the present invention has been applied (hereinafter referred to as a solid-state imaging device 1) is shown in FIG. 3.

As shown in FIG. 3, the solid-state imaging device 1 is roughly configured to be provided with an infrared cut filter 2, a plurality of color filters 3 that are the color filters of the present invention, a photoelectric conversion device 4, a readout circuit (not shown), and a signal processing section (not shown)

The solid-state imaging device 1 is a rear surface irradiation-type solid-state imaging device in which a wiring region 6 is formed on one surface (front surface) 5a of a semiconductor substrate 5 such as a silicon substrate, and a light receiving region 7 is formed on the other surface (rear surface) 5b. Hereinafter, the rear surface irradiation-type solid-state imaging device 1 will be described as an example.

The wiring region 6 is a region provided with a wiring for transmitting a signal. The wiring region 6 includes a wiring layer (not shown) that transmits a signal to the photoelectric conversion device 4 formed on the semiconductor substrate 5, and an insulating layer (not shown) that insulates the wiring layer.

The semiconductor substrate 5 is compartmentalized into a plurality of regions by a partition wall 8, and the photoelectric conversion device 4 is formed in each region. The color filters 3 are each provided on a rear surface 5b of the semiconductor substrate on which the photoelectric conversion device 4 has been formed, and each constitute a pixel. That is, a plurality of pixels are arranged in the light receiving region 7.

The color filter 3 includes a blue color filter 31a, a green color filter 31b, a red color filter 31c, a first infrared color filter 32a, and a second infrared color filter 32b, and color filters formed of the colored resin compositions of the first to fifth aspects of the present invention are each applied.

Moreover, in the light receiving region 7, microlenses 9 serving as light condensing means are stacked on a plurality of pixels (on a plurality of color filters 3). In addition, the infrared cut filter 2 is disposed on a side of the microlens 9 opposite to the color filter 3 through an air layer.

By applying the color filter of the present invention, a solid-state imaging device, which cannot only spectrally split light in a visible region into three colors but also spectrally split infrared rays, and is capable of more high-level imaging, can be obtained.

### EXAMPLES

Although the present invention will be described in more detail with reference to Examples, it is not limited to the following Examples as long as a gist thereof is maintained.

### Green Colorant A

A phthalocyanine compound A having a chemical structure represented by General Formula (Z1), which had been synthesized based on Example 30 of Japanese Unexamined Patent Application, First Publication No. H05-345861, was used.

A green colorant A has a light absorption maximum at a wavelength of 664 nm in ethyl cellosolve in a wavelength range of 400 to 900 nm.

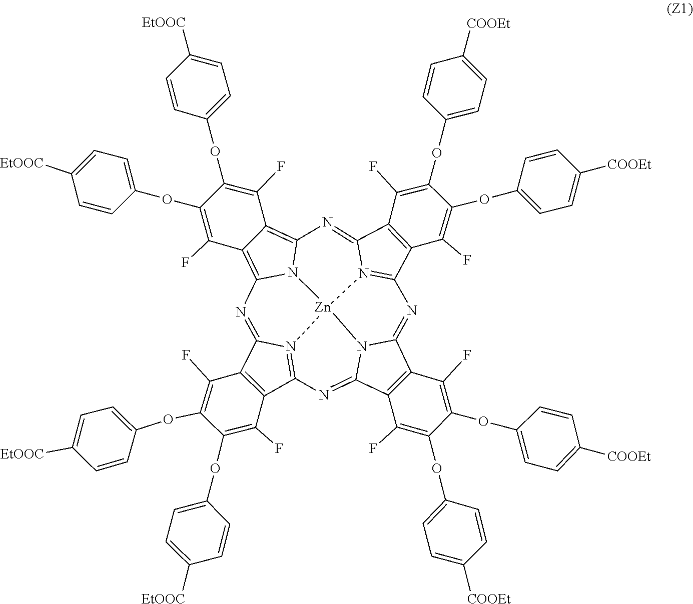

In the formula, COOEt represents an ethoxycarbonyl group.

### Blue Colorant A

A blue colorant A having a chemical structure represented by General Formula (Z2), which had been synthesized based on PCT International Publication No. WO2015/080217, was used.

The blue colorant A has a light absorption maximum in the vicinity of a wavelength of 635 nm in a mixed solvent of propylene glycol monomethyl ether acetate/propylene glycol monomethyl ether=35/65 (volume ratio) in a wavelength range of 400 to 900 nm.

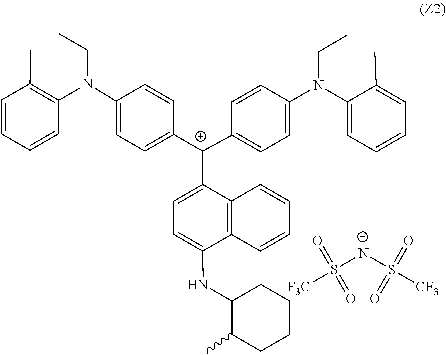 [SMILES: CCN(c1ccc([C+](c2ccc(N(CC)c3ccccc3C)cc2)c2ccc(NC3CCCCC3C)c3ccccc23)cc1)c1ccccc1C ; O=S(=O)([N-]S(=O)(=O)C(F)(F)F)C(F)(F)F]

### Red Colorant A

A red colorant A having a chemical structure represented by General Formula (Z3), which had been synthesized based on Japanese Patent No. 6846739, was used. The red colorant A has a light absorption maximum at a wavelength of 543 nm in sulfuric acid in a wavelength range of 400 to 900 nm.

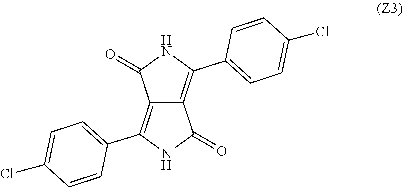

### Black Colorant A

Irgaphor (registered trademark) Black S 0100 CF (having a chemical structure represented by Formula (Z4)) manufactured by BASF SE was used.

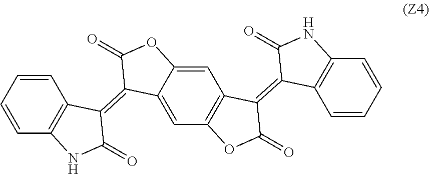 [SMILES: O=C1Nc2ccccc2/C1=C1\C(=O)Oc2cc3c(cc21)OC(=O)/C3=C1/C(=O)Nc2ccccc21]

### Dispersant A

A methacrylic A-B block copolymer consisting of an A block having a nitrogen atom-containing functional group and a B block having a solvophilic group was used. The dispersant A has a repeating unit represented by Formula (1a), a repeating unit represented by Formula (2a), a repeating unit represented by Formula (3a), a repeating unit represented by Formula (4a), and a repeating unit represented by Formula (5a). The amine value is 120 mgKOH/g and the acid value is less than 1 mgKOH/g.

The content proportions of the repeating units represented by Formulae (1a), (2a), (3a), (4a), and (5a) in all repeating units are each less than 1% by mole, 34.5% by mole, 6.9% by mole, 13.8% by mole, and 6.9% by mole.

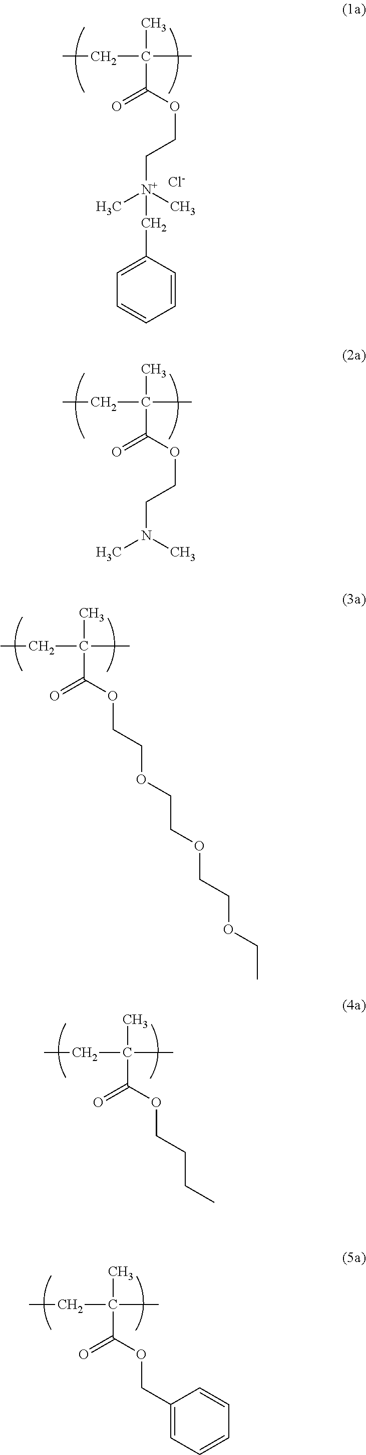

### Dispersant B

An acrylic A-B block copolymer consisting of an A block having a quaternary ammonium base and a tertiary amino group in a side chain and a B block not having a quaternary ammonium base and a tertiary amino group in a side chain was used. The A block of the dispersant B includes the repeating units of Formulae (1a) and (2a), and the B block includes the repeating unit of Formula (3a). The amine value is 70 mgKOH/g and the acid value is 1 mgKOH/g or less.

The content proportions of the repeating units of Formulae (1a), (2a), and (3a) in all repeating units are each 11.1% by mole, 22.2% by mole, and 6.7% by mole.

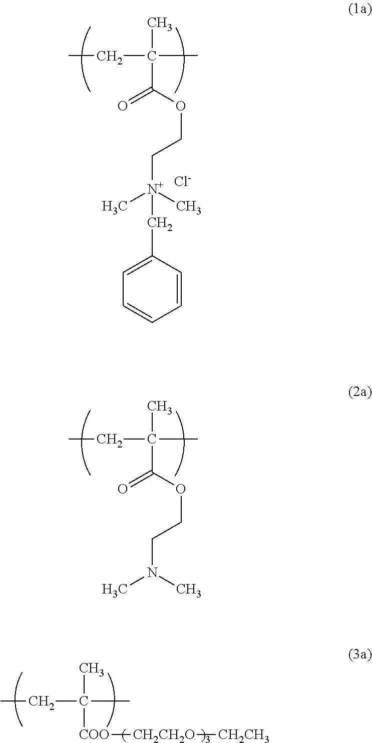

### Binder Resin A

A separable flask equipped with a cooling tube as a reaction tank was prepared, 400 parts by mass of propylene glycol monomethyl ether acetate was charged therein, and after replacing with nitrogen, the reaction tank was heated with an oil bath while stirring to raise the temperature to 90° C.

On the other hand, 30 parts by mass of dimethyl-2,2′-[oxybis(methylene)]bis-2-propenoate, 60 parts by mass of methacrylic acid, 110 parts by mass of cyclohexyl methacrylate, 5.2 parts by mass of t-butylperoxy-2-ethylhexanoate, and 40 parts by mass of propylene glycol monomethyl ether acetate were charged into a monomer tank, and 5.2 parts by mass of n-dodecyl mercaptan and 27 parts by mass of propylene glycol monomethyl ether acetate were charged into a chain transfer agent tank. When the temperature of the reaction tank was stabilized at 90° C., dropwise addition of the contents from the monomer tank and the chain transfer agent tank was initiated to initiate polymerization. The dropwise addition was each performed over 135 minutes while maintaining the temperature at 90° C., and after 60 minutes from completion of the dropwise addition, the reaction tank was set to 110° C. by starting raising the temperature.

After maintaining the temperature at 110° C. for 3 hours, a gas inlet tube was attached to a separable flask and bubbling of a mixed gas of oxygen/nitrogen=5/95 (v/v) was started. Next, 39.6 parts by mass of glycidyl methacrylate, 0.4 parts by mass of 2,2′-methylenebis(4-methyl-6-t-butylphenol), and 0.8 parts by mass of triethylamine were charged into the reaction tank, and the mixture was reacted at 110° C. for 9 hours as it was.

The mixture was cooled to room temperature to obtain a binder resin A having a polystyrene-equivalent weight-average molecular weight Mw, as measured by GPC, of 9,000, an acid value of 101 mgKOH/g, and a double bond equivalent of 550 g/mol.

### Binder Resin B

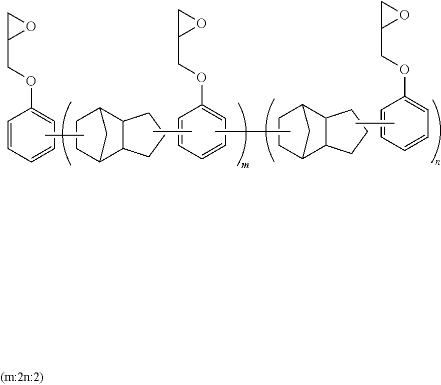

155 parts by mass of the epoxy compound represented by the structural formula (EPICLON HP7200HH manufactured by DIC Corporation, polyglycidyl ether of a dicyclopentadiene/phenol polymer, a weight-average molecular weight of 1,000, and an epoxy equivalent of 270), 41 parts by mass of acrylic acid, 0.1 parts by mass of p-methoxyphenol, 2.5 parts by mass of triphenylphosphine, and 130 parts by mass of propylene glycol monomethyl ether acetate were charged into a reaction vessel, and the mixture was heated and stirred at 100° C. until the acid value reached 3.0 mgKOH/g or less. It took 9 hours for the acid value to reach a target (acid value: 2.9 mgKOH/g). Next, 74 parts by mass of tetrahydrophthalic anhydride was further added thereto and reacted at 120° C. for 4 hours to obtain a binder resin B solution having an acid value of 98 mgKOH/g and a weight-average molecular weight (Mw) of 3,500.

### Binder Resin C

145 parts by mass of propylene glycol monomethyl ether acetate was stirred while replacing with nitrogen, and the temperature was raised to 120° C. 10.4 parts by mass of styrene, 85.2 parts by mass of glycidyl methacrylate, and 66.0 parts by mass of monomethacrylate (FA-513M manufactured by Hitachi Chemical Co., Ltd.) having a tricyclodecane skeleton were added dropwise thereto, and a mixed solution of 8.47 parts by mass of 2.2′-azobis-2-methylbutyronitrile was added dropwise to the mixture over 3 hours. Stirring was further continued at 90° C. for 2 hours.

Next, the inside of the reaction vessel was changed to air replacement, 0.3 parts by mass of trisdimethylaminomethylphenol and 0.06 parts by mass of hydroquinone were put into 15.1 parts by mass of acrylic acid, and the reaction was continued at 120° C. for 6 hours. Thereafter, 59.3 parts by mass of tetrahydrophthalic anhydride (THPA) and 1.4 parts by mass of triethylamine were added thereto, and the mixture was reacted at 120° C. for 3.5 hours.

The polystyrene-equivalent weight-average molecular weight Mw, as measured by GPC, of the binder resin C obtained in this manner was approximately 9,000, the acid value was 80 mgKOH/g, and the double bond equivalent was 480 g/mol. Propylene glycol monomethyl ether acetate was added to this resin solution so that the solid content reached 40% by mass, and the mixture was used as the binder resin C.

### Binder Resin D

145 parts by mass of propylene glycol monomethyl ether acetate was stirred while replacing with nitrogen, and the temperature was raised to 120° C. 10 parts by mass of styrene, 85.2 parts by mass of glycidyl methacrylate, and 66 parts by mass of monomethacrylate (FA-513M manufactured by Hitachi Chemical Co., Ltd.) having a tricyclodecane skeleton were added dropwise thereto, and 8.47 parts by mass of 2,2′-azobis-2-methylbutyronitrile was added dropwise to the mixture over 3 hours. Stirring was further continued at 90° C. for 2 hours. Next, the inside of the reaction vessel was changed to air replacement, 0.7 parts by mass of trisdimethylaminomethylphenol and 0.12 parts by mass of hydroquinone were added to 43.2 parts by mass of acrylic acid, and the reaction was continued at 100° C. for 12 hours. Thereafter, 56.2 parts by mass of tetrahydrophthalic anhydride (THPA) and 0.7 parts by mass of triethylamine were added thereto, and the mixture was reacted at 100° C. for 3.5 hours.

The weight-average molecular weight (Mw) of the binder resin D obtained in this manner was approximately 8,400, the acid value was 80 mgKOH/g, and the double bond equivalent was 480 g/mol.

### Near-Infrared Absorbing Colorant A

A compound having the following chemical structure, synthesized based on Kousik Kundu, Sarah F. Knight, Seungjun Lee, W. Robert Taylor, and Niren Murthy, Angew. Chem. Int. Ed., 2010, 49, 6134-6138, was used.

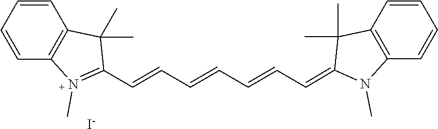

### Near-Infrared Absorbing Colorant B

A compound having the following chemical structure, synthesized based on I. G. Davidenko, Yu. L. Slominskii, A. D. Kachkovskii, and A. I. Tolmachev, Ukrainskii Khimicheskii Zhurnal (Russian Edition) 2008, 74 (3-4), 105-113, was used.

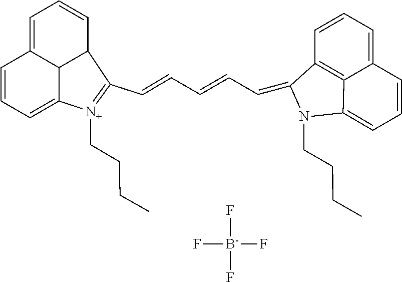 [SMILES: CCCCn1/c(=C/C=C/C=C/C2=[N+](CCCC)C3=CC=CC4=CC=CC2C43)c2cccc3cccc1c32 ; F[B-](F)(F)F]

### Near-Infrared Absorbing Colorant C

A compound having the following chemical structure, synthesized based on Yukinori Nagao, Toshifumi Sakai, Kozo Kozawa, Toshiyuki Urano, Dyes and Pigments, 2006, 73 (3), 344-352, was used.

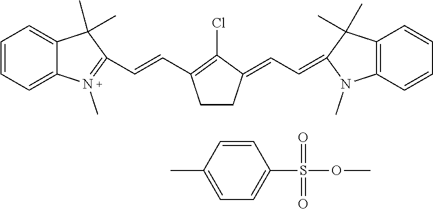

### Near-Infrared Absorbing Colorant D

A compound having the following chemical structure, synthesized based on Hui Zhang, Gaetan Wicht, Christina Gretener, Matthias Nagel, Frank Nuesch, Yaroslav Romanyuk, Jean-Nicolas Tisserant, Roland Hany, Solar Energy Materials & Solar Cells, 2013, 118, 157-164, was used.

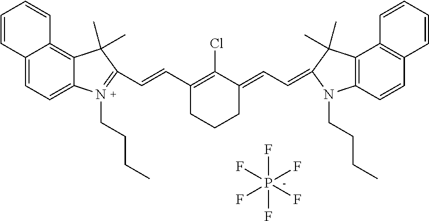

### Solvent

PGMEA: Propylene glycol monomethyl ether acetate
PGME: Propylene glycol monomethyl ether
MB: 3-Methoxy-1-butanol

### Preparation of Red Colorant Dispersion A

As described in Table 2, 12.6 parts by mass of the red colorant A, 3.2 parts by mass in terms of a solid content of the dispersant A as a dispersant, 4.2 parts by mass in terms of a solid content of the binder resin A as a dispersion resin, 76.0 parts by mass of propylene glycol monomethyl ether acetate (including a solvent derived from the dispersant and the dispersion resin) as a solvent, 4.0 parts by mass of propylene glycol monomethyl ether, and 225 parts by mass of zirconia beads with a diameter of 0.5 mm were charged into a stainless steel container, and the mixture was subjected to a dispersing treatment for 6 hours by a paint shaker. After the completion of dispersion, the beads and the dispersion were separated by a filter to prepare a red colorant dispersion A.

### Preparation of Red Colorant Dispersion B

As described in Table 2, 15.0 parts by mass of the red colorant B (C. I. Pigment Red 177), 2.0 parts by mass in terms of a solid content of the dispersant A as a dispersant, 6.0 parts by mass in terms of a solid content of the binder resin A as a dispersion resin, 77.0 parts by mass of propylene glycol monomethyl ether acetate (including a solvent derived from the dispersant and the dispersion resin) as a solvent, and 225 parts by mass of zirconia beads with a diameter of 0.5 mm were charged into a stainless steel container, and the mixture was subjected to a dispersing treatment for 6 hours by a paint shaker. After the completion of dispersion, the beads and the dispersion were separated by a filter to prepare a red colorant dispersion B.

### Preparation of Yellow Colorant Dispersion A

As described in Table 2, 11.4 parts by mass of the yellow colorant A (E4GN-TG (hereinafter abbreviated as “NiAzo-Y”)) manufactured by LANXESS, 2.9 parts by mass in terms of a solid content of the dispersant A as a dispersant, 5.7 parts by mass in terms of a solid content of the binder resin A as a dispersion resin, 80.0 parts by mass of propylene glycol monomethyl ether acetate (including a solvent derived from the dispersant and the dispersion resin) as a solvent, and 225 parts by mass of zirconia beads with a diameter of 0.5 mm were charged into a stainless steel container, and the mixture was subjected to a dispersing treatment for 6 hours by a paint shaker. After the completion of dispersion, the beads and the dispersion were separated by a filter to prepare a yellow colorant dispersion A.

### Preparation of Yellow Colorant Dispersion B

As described in Table 2, 11.4 parts by mass of the yellow colorant B (C. I. pigment yellow 138), 2.9 parts by mass in terms of a solid content of the dispersant A as a dispersant, 5.7 parts by mass in terms of a solid content of the binder resin A as a dispersion resin, 76.0 parts by mass of propylene glycol monomethyl ether acetate (including a solvent derived from the dispersant and the dispersion resin) as a solvent, 4.0 parts by mass of propylene glycol monomethyl ether, and 225 parts by mass of zirconia beads with a diameter of 0.5 mm were charged into a stainless steel container, and the mixture was subjected to a dispersing treatment for 6 hours by a paint shaker. After the completion of dispersion, the beads and the dispersion were separated by a filter to prepare a yellow colorant dispersion B.

### Preparation of Green Colorant Dispersion A

As described in Table 2, 9.9 parts by mass of the green colorant A, 0.1 parts by mass in terms of a solid content of the dispersant A as a dispersant, 72.0 parts by mass of propylene glycol monomethyl ether acetate (including a solvent derived from the dispersant) as a solvent, 18.0 parts by mass of propylene glycol monomethyl ether, and 225 parts by mass of zirconia beads having a diameter of 0.5 mm were charged into a stainless steel container, and the mixture was subjected to a dispersing treatment for 6 hours by a paint shaker. After the completion of dispersion, the beads and the dispersion were separated by a filter to prepare a green colorant dispersion A.

### Preparation of Black Colorant Dispersion A

As described in Table 2, 5.6 parts by mass of the black colorant A, 1.1 parts by mass in terms of a solid content of the dispersant B as a dispersant, 2.8 parts by mass in terms of a solid content of the binder resin B as a dispersion resin, 72.4 parts by mass of propylene glycol monomethyl ether acetate (including a solvent derived from the dispersant) as a solvent, 18.1 parts by mass of 3-methoxy-1-butanol, and 225 parts by mass of zirconia beads having a diameter of 0.5 mm were charged into a stainless steel container, and the mixture was subjected to a dispersing treatment for 6 hours by a paint shaker. After the completion of dispersion, the beads and the dispersion were separated by a filter to prepare a black colorant dispersion A.

TABLE 2

| | | Red | Red | Yellow | Yellow | Green | Black |
|---|---|---|---|---|---|---|---|
| | | colorant | colorant | colorant | colorant | colorant | colorant |
| | | dispersion A | dispersion B | dispersion A | dispersion B | dispersion A | dispersion A |
| Blend | Red colorant A | 12.6 | — | — | — | — | — |
| proportion | Red colorant B | — | 15.0 | — | — | — | — |
| [parts | Yellow colorant A | — | — | 11.4 | — | — | — |
| by | Yellow colorant B | — | — | — | 11.4 | — | — |
| mass] | Green colorant A | — | — | — | — | 9.9 | — |
| (in | Black colorant A | — | — | — | — | — | 5.6 |
| terms | Dispersant A | 3.2 | 2.0 | 2.9 | 2.9 | 0.1 | |
| of | Dispersant B | — | — | — | — | — | 1.1 |
| solid | Binder resin A | 4.2 | 6.0 | 5.7 | 5.7 | — | — |
| content | Binder resin B | — | — | — | — | — | 2.8 |
| excluding | PGMEA | 76.0 | 77.0 | 80.0 | 76.0 | 72.0 | 72.4 |
| solvent) | PGME | 4.0 | — | — | 4.0 | 18.0 | — |
| | MB | — | — | — | — | — | 18.1 |

### Photopolymerizable Monomer A

A mixture of dipentaerythritol hexaacrylate and dipentaerythritol pentaacrylate (A-9550 manufactured by Shin-Nakamura Chemical Co., Ltd.) was used.

### Photopolymerizable Monomer B

Trimethyloipropane triacrylate (Light Acrylate TMIP-A manufactured by Kyoeisha Chemical Co., Ltd.) was used.

### Photopolymerizable Monomer C

A monomer having a urethane skeleton in which hexamethylene diisocyanate was bonded to dipentaerythritol pentaacrylate (DPHA-40H manufactured by Nippon Kayaku Co., Ltd.) was used.

### Photopolymerization Initiator A

An oxime ester-based compound having the following chemical structure (methyl 4-acetoxyimino-5-[9-ethyl-6-(2-methylbenzoyl)-9H-carbazol-3-yl]-5-oxopentanoate) was used.

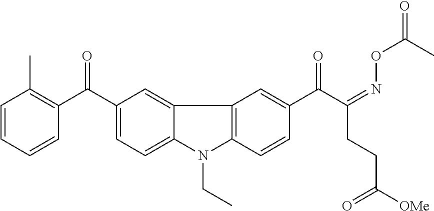 [SMILES: CCn1c2ccc(C(=O)/C(CCC(=O)OC)=N\OC(C)=O)cc2c2cc(C(=O)c3ccccc3C)ccc21]

In the formula, OMe represents a methoxy group.

### Photopolymerization Initiator B

An oxime ester-based compound having the following chemical structure was used.

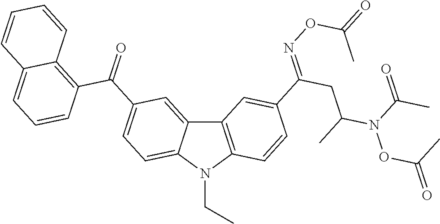 [SMILES: CCn1c2ccc(C(=O)c3cccc4ccccc34)cc2c2cc(/C(CC(C)N(OC(C)=O)C(C)=O)=N/OC(C)=O)ccc21]

### Surfactant A

MEGAFACE F-554 (manufactured by DIC Corporation) was used.

### Additive A

BYK-330 (manufactured by BYK Chemie GmbH) was used.

### Preparation of Colored Resin Composition

Each of the components described in Table 3 was mixed at the described solid content ratio to prepare colored resin compositions of Examples 1 to 5.

TABLE 3

| | | Example | | | | |
|---|---|---|---|---|---|---|
| | | 1 | 2 | 3 | 4 | 5 |
| Blend | Red colorant | 33.5 | — | — | — | — |
| proportion | dispersion A | | | | | |
| [parts | Red colorant | 12.7 | — | — | — | — |
| by | dispersion B | | | | | |
| mass] | Yellow colorant | 14.3 | 4.1 | — | — | — |
| (in | dispersion A | | | | | |
| terms | Yellow colorant | — | 45.5 | — | — | — |
| of | dispersion B | | | | | |
| solid | Green colorant | — | 14.3 | — | — | — |
| content) | dispersion A | | | | | |
| | Blue colorant A | — | — | 17.4 | — | — |
| | Black colorant | — | — | — | 88.1 | 91.2 |
| | dispersion A | | | | | |
| | Near-infrared | — | 0.5 | 0.5 | — | 0.5 |
| | absorbing | | | | | |
| | colorant A | | | | | |
| | Near-infrared | 0.9 | 0.9 | 0.9 | — | — |
| | absorbing | | | | | |
| | colorant B | | | | | |
| | Near-infrared | 1.9 | — | — | — | — |
| | absorbing | | | | | |
| | colorant C | | | | | |
| | Near-infrared | — | — | — | 3.8 | — |
| | absorbing | | | | | |
| | colorant D | | | | | |
| | Binder resin C | 22.2 | 16.8 | 57.5 | — | — |
| | Binder resin D | — | — | — | 5.3 | 5.5 |
| | Photopolymerizable | 12.2 | 15.5 | 21.3 | | — |
| | monomer A | | | | | |
| | Photopolymerizable | — | — | — | 1.0 | 1.1 |
| | monomer B | | | | | |
| | Photopolymerizable | — | — | — | 1.0 | 1.1 |
| | monomer C | | | | | |
| | Photopolymerization | 2.3 | 2.4 | 2.4 | — | — |
| | initiator A | | | | | |
| | Photopolymerization | — | — | — | 0.7 | 0.7 |
| | initiator B | | | | | |
| | Surfactant A | 0.1 | 0.1 | 0.1 | — | — |
| | Additive A | — | — | — | 0.01 | 0.01 |

| | | | | | |
|---|---|---|---|---|---|
| Wavelength (nm) exhibiting | 619 | 529 | 466 | 757 | 887 |
| maximum transmittance | | | | | |
| in wavelength range | | | | | |
| of 400 to 900 nm | | | | | |

### Measurement of Color Characteristics

The colored resin composition obtained in each Example was applied onto a glass substrate (AN100 manufactured by AGC Inc.) with a size of 50 mm square and a thickness of 0.7 mm by a spin coating method, dried under reduced pressure, and then pre-baked on a hot plate at 90° C. for 90 seconds. Next, an entire-surface exposure treatment was performed at an exposure amount of 40 mJ/cm² and an illuminance of 30 mW/cm², using a 2-kW high-pressure mercury lamp. Thereafter, a development treatment was performed at a developer temperature of 23° C. for 60 seconds, using a 0.04% by mass aqueous solution of potassium hydroxide. Next, a spray water rinsing treatment was performed at a water pressure of 1 kg/cm² for 10 seconds. Thereafter, a thermosetting treatment was performed at 230° C. for 20 minutes in a clean oven to create a colored substrate having a film thickness of 2 to 3 m.

The transmission spectrum of the obtained colored substrate was measured with a spectrophotometer U-3310 manufactured by Hitachi, Ltd. The results are shown in FIG. 2.

### INDUSTRIAL AVAILABILITY

According to the present invention, it is possible to provide a colored resin composition which can be applied as a color filter of a solid-state imaging device capable of performing high-level imaging by not only spectrally splitting light in a visible region into three colors but also spectrally splitting infrared rays.

### REFERENCE SIGNS LIST

10 transparent support substrate
20 pixel
30 organic protective Layer
40 inorganic oxide film
50 transparent anode
51 hole injection layer
52 hole transport layer
53 light emitting layer
54 electron injection layer
55 cathode
100 organic EL element
500 organic light emitting body
1 solid-state imaging device
2 infrared cut filter
3 color filter
4 photoelectric conversion device
5. semiconductor substrate
31 infrared shielding and visible transmitting filter
31a blue color filter
31b green color filter
31c red color filter
32 visible shielding and infrared transmitting filter
32a first infrared color filter
32b second infrared color filter

1. A colored resin composition, comprising:
a colorant (A);
a solvent (B); and
a binder resin (C),
wherein the colored resin composition has a maximum transmittance at a wavelength range of 400 to 500 nm in a wavelength range of 400 and 900 nm, and
wherein the colorant (A) comprises:
a colorant (a1) having a light absorption maximum at a wavelength range of 580 to 650 nm in a wavelength range of 400 and 900 nm, and
a near-infrared absorbing compound.

2. The colored resin composition according to claim 1,
wherein when a film having a film thickness of 5 μm or less after drying is formed using the colored resin composition, an average transmittance of the film in a wavelength range of 400 to 500 nm is 30% or more.

3. The colored resin composition according to claim 1,
wherein the colorant (a1) is a triarylmethane compound of Formula (1), 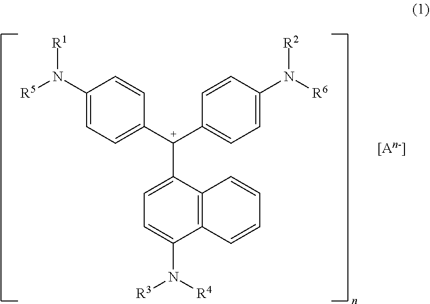
wherein [Aⁿ⁻] is an n-valent halogenoalkylsulfonylimide anion which may have a substituent or an n-valent halogenoalkylsulfonylmethide anion which may have a substituent,
R¹ to R⁴ are each independently a hydrogen atom, an alkyl group which may have a substituent, or an aromatic ring group which may have a substituent,
R⁵ and R⁶ are each independently an aromatic ring group which may have a substituent, and
n is an integer of 1 to 4, and when n is 2 to 4, a plurality of cations of Formula (2), which are included in one molecule, may each independently have the same structure or may have different structures

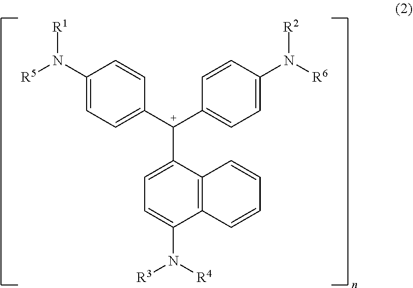

4. A colored resin composition, comprising:
a colorant (A);
a solvent (B); and
a binder resin (C),
wherein the colored resin composition has a maximum transmittance at a wavelength range of 500 to 600 nm in a wavelength range of 400 and 900 nm, and
the colorant (A) comprises:
a colorant (a2) having a light absorption maximum at a wavelength range of 650 to 700 nm in a wavelength range of 400 and 900 nm, and
a near-infrared absorbing compound.

5. The colored resin composition according to claim 4,
wherein when a film having a film thickness of 5 μm or less after drying is formed using the colored resin composition, an average transmittance of the film in a wavelength range of 500 to 600 nm is 30% or more.

6. The colored resin composition according to claim 4, wherein the colorant (a2) is a phthalocyanine compound of Formula (3), 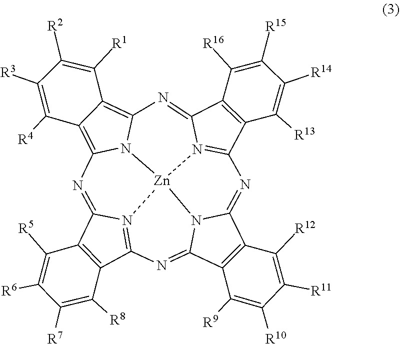
wherein R¹ to R¹⁶ are each independently a hydrogen atom, a halogen atom, or a group Formula (4), provided that one or more of R¹ to R¹⁶ is a halogen atom, and one or more of R¹ to R¹⁶ is a group of Formula (4), 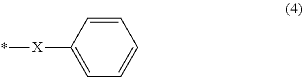
wherein X is a divalent linking group, a benzene ring in Formula (4) may have any substituent, and * represents a binding site.

7. A colored resin composition, comprising:
a colorant (A);
a solvent (B); and
a binder resin (C),
wherein the colored resin composition has a maximum transmittance at a wavelength range of 600 to 700 nm in a wavelength range of 400 and 900 nm, and
wherein the colorant (A) comprises:
a colorant (a3) having a light absorption maximum at a wavelength range of 430 to 570 nm in a wavelength range of 400 and 900 nm, and
a near-infrared absorbing compound.

8. The colored resin composition according to claim 7,
wherein when a film having a film thickness of 5 μm or less after drying is formed using the colored resin composition, an average transmittance of the film in a wavelength range of 600 to 700 nm is 30% or more.

9. The colored resin composition according to claim 7,
wherein the colorant (a3) is a dihydropyrrolopyrrole dione compound of Formula (5), 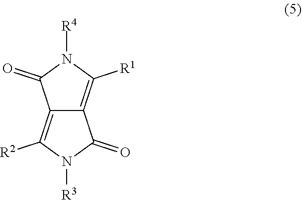
wherein R¹ to R⁴ are each independently a hydrogen atom, an alkyl group which may have a substituent, or an aryl group which may have a substituent.

10. A colored resin composition, comprising:
a colorant (A);
a solvent (B); and
a binder resin (C),
wherein the colored resin composition has a maximum transmittance at a wavelength range of 700 to 800 nm in a wavelength range of 400 and 900 nm,
wherein the colorant (A) comprises;
a compound of Formula (8), and
a near-infrared absorbing compound, and
wherein the near-infrared absorbing compound has a light absorption maximum value in a wavelength range of 790 to 830 nm in a wavelength range of 400 and 900 nm, 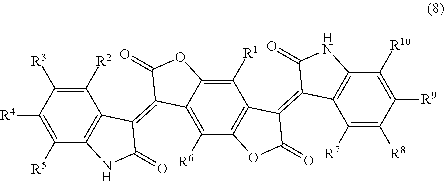
wherein R¹ and R⁶ are each independently a hydrogen atom, CH₃, CF₃, a fluorine atom, or a chlorine atom,
wherein R², R³, R⁴, R⁵, R⁷, R⁸, R⁹, and R¹⁰ are each independently a hydrogen atom, a halogen atom, R¹¹, COOH, COOR¹¹, COO⁻, CONH₂, CONHR¹¹, CONR¹¹R¹², CN, OH, OR¹¹, COCR¹¹, OOCNH₂, OOCNHR¹¹, OOCNR¹¹R¹², NO₂, NH₂, NHR¹¹, NR¹¹R¹², NHCOR¹², NR¹¹COR¹², N═CH₂, N═CHR¹¹, N═CR¹¹R¹², SH, SR¹¹, SOR¹¹, SO₂R¹¹, SO₃R¹¹, SO₃H, SO₃⁻, SO₂NH₂, SO₂NHR¹¹, or SO₂NR¹¹R¹²,
wherein at least one combination selected from the group consisting of R² and R³, R³ and R⁴, R⁴ and R⁵, R⁷ and R⁸, R⁸ and R⁹, and R⁹ and R¹⁰ is directly bonded to each other or is bonded to each other through an oxygen atom, a sulfur atom, NH, or an NR¹¹ bridge, and
wherein R¹¹ and R¹² are each independently an alkyl group having 1 to 12 carbon atoms, a cycloalkyl group having 3 to 12 carbon atoms, an alkenyl group having 2 to 12 carbon atoms, a cycloalkenyl group having 3 to 12 carbon atoms, or an alkynyl group having 2 to 12 carbon atoms.

11. The colored resin composition according to claim 10,
wherein when a film having a film thickness of 5 μm or less after drying is formed using the colored resin composition, an average transmittance of the film in a wavelength range of 700 to 800 nm is 30% or more.

12. A colored resin composition, comprising:
a colorant (A);
a solvent (B); and
a binder resin (C),
wherein the colored resin composition has a maximum transmittance at a wavelength range of 800 to 900 nm in a wavelength range of 400 and 900 nm,
wherein the colorant (A) comprises;
a compound of Formula (8), and
a near-infrared absorbing compound, and
wherein the near-infrared absorbing compound has a light absorption maximum value in a wavelength range of 720 to 780 nm in a wavelength range of 400 and 900 nm, 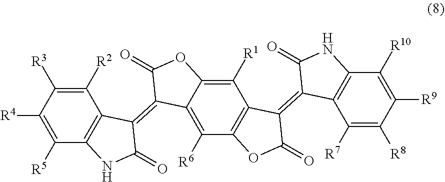
wherein R¹ and R⁶ are each independently a hydrogen atom, CH₃, CF₃, a fluorine atom, or a chlorine atom,
wherein R², R³, R⁴, R⁵, R⁷, R⁸, R⁹, and R¹⁰ are each independently a hydrogen atom, a halogen atom, R¹¹, COOH, COOR¹¹, COO⁻, CONH₂, CONHR¹¹, CONR¹¹R¹², CN, OH, OR¹¹, COCR¹¹, OOCNH₂, OOCNHR¹¹, OOCNR¹¹R¹², NO₂, NH₂, NHR¹¹, NR¹¹R¹², NHCOR¹², NR¹¹COR¹², N═CH₂, N═CHR¹¹, N═CR¹¹R¹², SH, SR¹¹, SOR¹¹, SO₂R¹¹, SO₃R¹¹, SO₃H, SO₃⁻, SO₂NH₂, SO₂NHR¹¹, or SO₂NR¹¹R¹²,
wherein at least one combination selected from the group consisting of R² and R³, R³ and R⁴, R⁴ and R⁵, R⁷ and R⁸, R⁸ and R⁹, and R⁹ and R¹⁰ is directly bonded to each other or is bonded to each other through an oxygen atom, a sulfur atom, NH, or an NR¹¹ bridge, and
wherein R¹¹ and R¹² are each independently an alkyl group having 1 to 12 carbon atoms, a cycloalkyl group having 3 to 12 carbon atoms, an alkenyl group having 2 to 12 carbon atoms, a cycloalkenyl group having 3 to 12 carbon atoms, or an alkynyl group having 2 to 12 carbon atoms.

13. The colored resin composition according to claim 12,
wherein when a film having a film thickness of 5 μm or less after drying is formed using the colored resin composition, an average transmittance of the film in a wavelength range of 800 to 900 nm is 30% or more.

14. The colored resin composition according to claim 1,
wherein the near-infrared absorbing compound comprises at least one compound selected from the group consisting of a cyanine-based compound, a merocyanine-based compound, a squarylium-based compound, a phthalocyanine-based compound, a diimmonium-based compound, and a diketopyrrolopyrrole-based compound.

15. The colored resin composition according to claim 1, further comprising:
a photopolymerizable monomer having a partial structure of Formula (9), 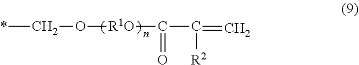
wherein R¹ is an alkylene group having 2 or more carbon atoms,
R² is a hydrogen atom or a methyl group,
n is an integer of 1 or more, and
* is a binding site.

16. The colored resin composition according to claim 14, further comprising:
a photopolymerizable monomer having a partial structure of Formula (10), 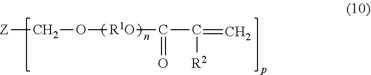
wherein R¹ is an alkylene group having 2 or more carbon atoms,
R² i a hydrogen atom or a methyl group,
n an integer of 1 or more,
Z is a direct bond, an oxygen atom, a sulfur atom, a divalent to tetravalent aliphatic hydrocarbon group, a tetravalent carbon atom, a divalent to tetravalent non-aromatic heterocyclic group, a divalent to tetravalent aromatic ring group, or a partial structure of Formula (12),
p is an integer of 2 to 6, and a plurality of structures of Formula (11), which are included in one molecule, may each independently have the same structure or may be different structures, and
* is a binding site

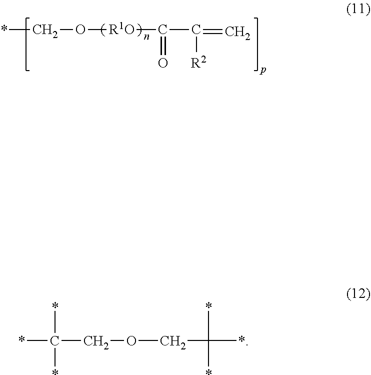

17. The colored resin composition according to claim 1,
wherein a content of the colorant (A) is 10% by mass or more relative to a total solid content of the colored resin composition.

18. The colored resin composition according to claim 15,
wherein a content of the photopolymerizable monomer is 1% by mass or more relative to a total solid content of the colored resin composition.

19. A colored resin composition set, comprising:
a first colored resin composition, which is the colored resin composition according to claim 10; and
a second colored resin composition, comprising:
a colorant (Ai);
a solvent (Bi); and
a binder resin (Ci),
wherein the second colored resin composition has a maximum transmittance at a wavelength range of 800 to 900 nm in a wavelength range of 400 and 900 nm,
wherein the colorant (Ai) comprises:
the compound of Formula (8), and
a second near-infrared absorbing compound, and
wherein the second near-infrared absorbing compound has a light absorption maximum value in a wavelength range of 720 to 780 nm in a wavelength range of 400 and 900 nm.

20. A colored resin composition set, comprising:
at least two resin compositions selected from the group consisting of a colored resin composition (I), a colored resin composition (II), a colored resin composition (III), a colored resin composition (IV), and a colored resin composition (V), wherein:
the colored resin composition (I) is the colored resin composition according to claim 1;
the colored resin composition (II) comprises:
a colorant (A2);
a solvent (B2); and
a binder resin (C2),
wherein the colored resin composition (II) has a maximum transmittance at a wavelength range of 500 to 600 nm in a wavelength range of 400 and 900 nm, and
the colorant (A2) comprises:
a colorant (a2) having a light absorption maximum at a wavelength range of 650 to 700 nm in a wavelength range of 400 and 900 nm, and
a second near-infrared absorbing compound;
the colored resin composition (III) comprises:
a colorant (A3);
a solvent (B3); and
a binder resin (C3),
wherein the colored resin composition (III) has a maximum transmittance at a wavelength range of 600 to 700 nm in a wavelength range of 400 and 900 nm, and
wherein the colorant (A3) comprises:
a colorant (a3) having a light absorption maximum at a wavelength range of 430 to 570 nm in a wavelength range of 400 and 900 nm, and
a third near-infrared absorbing compound;
the colored resin composition (IV) comprises:
a colorant (A4);
a solvent (B4); and
a binder resin (C4),
wherein the colored resin composition (IV) has a maximum transmittance at a wavelength range of 700 to 800 nm in a wavelength range of 400 and 900 nm,
wherein the colorant (A4) comprises:
a compound of Formula (8), and
a fourth near-infrared absorbing compound, and
wherein the fourth near-infrared absorbing compound has a light absorption maximum value in a wavelength range of 790 to 830 nm in a wavelength range of 400 and 900 nm, 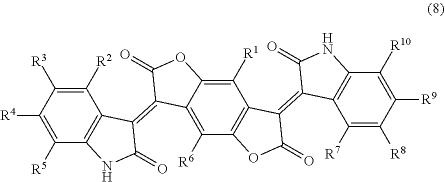
wherein R¹ and R⁶ are each independently a hydrogen atom, CH₃, CF₃, a fluorine atom, or a chlorine atom,
wherein R², R³, R⁴, R⁵, R⁷, R⁸, R⁹, and R¹⁰ are each independently a hydrogen atom, a halogen atom, R¹¹, COOH, COOR¹¹, COO⁻, CONH₂, CONHR¹¹, CONR¹¹R¹², CN, OH, OR¹¹, COCR¹¹, OOCNH₂, OOCNHR¹¹, OOCNR¹¹R¹², NO₂, NH₂, NHR¹¹, NR¹¹R¹², NHCOR¹², NR¹¹COR¹², N═CH₂, N═CHR¹¹, N═CR¹¹R¹², SH, SR¹¹, SOR¹¹, SO₂R¹¹, SO₃R¹¹, SO₃H, SO₃⁻, SO₂NH₂, SO₂NHR¹¹, or SO₂NR¹¹R¹²,
wherein at least one combination selected from the group consisting of R² and R³, R³ and R⁴, R⁴ and R⁵, R⁷ and R⁸, R⁸ and R⁹, and R⁹ and R¹⁰ is directly bonded to each other or is bonded to each other through an oxygen atom, a sulfur atom, NH, or an NR¹¹ bridge, and
wherein R¹¹ and R¹² are each independently an alkyl group having 1 to 12 carbon atoms, a cycloalkyl group having 3 to 12 carbon atoms, an alkenyl group having 2 to 12 carbon atoms, a cycloalkenyl group having 3 to 12 carbon atoms, or an alkynyl group having 2 to 12 carbon atoms; and
the colored resin composition (V) comprises:
a colorant (A5);
a solvent (B5); and
a binder resin (C5),
wherein the colored resin composition (V) has a maximum transmittance at a wavelength range of 800 to 900 nm in a wavelength range of 400 and 900 nm,
wherein the colorant (A5) comprises:
the compound of Formula (8), and
a fifth near-infrared absorbing compound, and
wherein the fifth near-infrared absorbing compound has a light absorption maximum value in a wavelength range of 720 to 780 nm in a wavelength range of 400 and 900 nm.

21. A color filter, comprising:
a pixel formed of the colored resin composition of claim 1.
